(19) United States
(12) Patent Application Publication
(10) Pub. No.: US 2009/0063070 A1
(43) Pub. Date: Mar. 5, 2009

(54) Circuit and Method for Fitting the Output of a Sensor to a Predetermined Linear Relationship

(76) Inventor: Carl Peter Renneberg, New South Wales (AU)

Correspondence Address: HESLIN ROTHENBERG FARLEY & MESITI PC, 5 COLUMBIA CIRCLE, ALBANY, NY, 12203, US

(21) Appl. No.: 11/993,836

(22) PCT Filed: Jun. 23, 2006
(86) PCT No.: PCT/AU2006/000879

§ 371 Date: Oct. 15, 2008

(30) Foreign Application Priority Data
Jun. 24, 2005 (AU) 2005903367
May 1, 2006 (AU) 2006902243

(51) Int. Cl. G06F 15/00; G01R 13/00; G01D 3/02

(52) U.S. Cl. 702/66; 702/189

(57) ABSTRACT

A circuit employing a plurality of n sensors, the circuit being arranged such that one of a transfer function or output function of the circuit approximates a desired mathematical relationship between a physical property measured by the sensors and the output of the circuit, the one of the transfer function or output function equalling the desired relationship at least 2*n+1 points.

### FIELD OF THE INVENTION

The present invention relates to circuits and methods for generating an output with a predetermined characteristic, from one or more sensors, such as temperature sensors. The present invention may also find application in the compensation of circuits such as, but not limited to, temperature compensation.

### BACKGROUND OF THE INVENTION

Electronic sensors are devices whose electrical properties change in a significant, repeatable manner under the influence of a physical property, such as ambient temperature. A great variety of sensors known in the art are nonlinear.

In many applications, one desires the sensor, or a circuit employing the sensor, to generate an output signal that varies in a linear manner with respect to the physical property. Circuits that perform this role are referred to as linearization circuits.

In many applications, it is more practical and effective to use a non-linear sensor in conjunction with a linearization circuit, than it is to devise, obtain, and use a suitable sensor that is inherently linear. Hence, sensor linearization circuits and methods are of great practical importance.

### SUMMARY OF THE INVENTION

In a first aspect, the present invention provides a circuit employing a plurality of n sensors, the circuit being arranged such that a transfer or output function of the circuit approximates a desired mathematical relationship between a physical property measured by the sensors and the output of the circuit, the transfer or output function equaling the desired relationship at least 2*n+1 points.

At least one of non-sensor parameters of the circuit, including an output scale factor and an output offset value may be selectable to provide at least 2*n+1 degrees of freedom in determining the points of equality.

All of the at least 2*n+1 points may occur within a defined range of values of the physical property measured by the sensors.

At least two of the plurality of n sensors may have substantially identical characteristics. The transfer or output function may be a rational function defined by circuit parameters.

The output of the circuit may be a function of a weighted sum of signal measurements measurable at one or more given locations in the circuit.

The signal measurements may be of signal amplitudes or of signal phases.

The desired mathematical relationship may be a linear function between the output of the circuit and the sensed property.

In at least some embodiments, the sensors are one-port devices that sense temperature and are resistive devices.

In some embodiments, the sensors are thermistors. In some alternate embodiments, the sensors are capacitive sensors.

The sensors may be devices with one of 3-wire and 4-wire Kelvin connections.

In a second aspect, the present invention provides a circuit employing a sensor, the circuit being arranged such that a transfer or output function of the circuit approximates a desired mathematical relationship between a physical property measured by the sensor and the output of the circuit, the transfer or output function equaling the desired relationship at least 2*n+1 points, n being an integer greater than 1, wherein the arrangement of the circuit provides at least 2*n+1 degrees of freedom in determining the points of equality.

For each of the signals used by the circuit to form the output value, the circuit may establish one of a bias and an excitation condition at the sensor, the points of equality being determined by the set of bias and excitation conditions established at the sensor.

The circuit may employ analog-to-digital converter means, the output of the circuit being a function of measurements derived from the analog to digital converter means, wherein for each measurement of a first signal one of a second signal and the sum of the first and second signals and the difference of the first and second signals is provided to the analog reference input of the analog to digital converter means in order to provide the predetermined transfer function or output function.

The output of the circuit may be a function of a weighted sum of signal measurements measurable at one or more given locations in the circuit.

The output of the circuit may also be a function of a weighted sum of the square of signal measurements measurable at one or more given locations in the circuit.

The measurements may be of signal amplitudes or signal phases. The circuit may modify the bias or excitation of the sensor by modifying one or more effective impedances used to bias or excite the sensor.

The one or more effective impedances in the circuit may be modified by changing the gain or gains of amplifying elements used in the circuit to synthesize the effective impedances.

In some embodiments, one or more effective impedances in the circuit are modified by changing the frequency content of a signal that passes through the effective impedances.

All of the at least 2*n+1 points may occur within a defined range of values of the physical property measured by the sensor.

The one or more effective impedances may be implemented by digital means.

In a third aspect of the invention, there is provided a first circuit in accordance with any one of the preceding aspects of the invention, wherein the first circuit is capable of compensating the output of a second circuit for the effect of a physical property influencing the output of the second circuit.

The physical property may be temperature.

The second circuit may be an oscillator circuit. In some alternative embodiments, the second circuit may be a voltage reference circuit.

In a fourth aspect, the present invention provides a circuit capable of connection to m sensors, m being an integer not less than 1, the circuit, when connected to the m sensors, being arranged such that one of a transfer function or output function of the circuit approximates a desired mathematical relationship between a physical property measured by the m sensors and the output of the circuit, the one of the transfer function or output function equaling the desired relationship at least 2*n+1 points, n being an integer both greater than 1 and not less than m, wherein the arrangement of the circuit provides at least 2*n+1 degrees of freedom in determining the points of equality.

All of the at least 2*n+1 points may occur within a defined range of values of the physical property measured by the m sensors.

In a fifth aspect, the present invention provides an integrated circuit incorporating a circuit in accordance with a fourth aspect of the invention.

In a sixth aspect the present invention provides a plurality of interrelated electrical components, wherein the interrelated components form a circuit in accordance with any one of a first, second, third or fourth aspect of the invention, when energized by a source of power.

In a seventh aspect, the present invention provides an integrated circuit comprising the plurality of interrelated components in accordance with a sixth aspect of the invention.

### DETAILED DESCRIPTION OF THE DRAWINGS

Features and advantages of the present invention will now be described by reference to the accompanying drawings, in which:

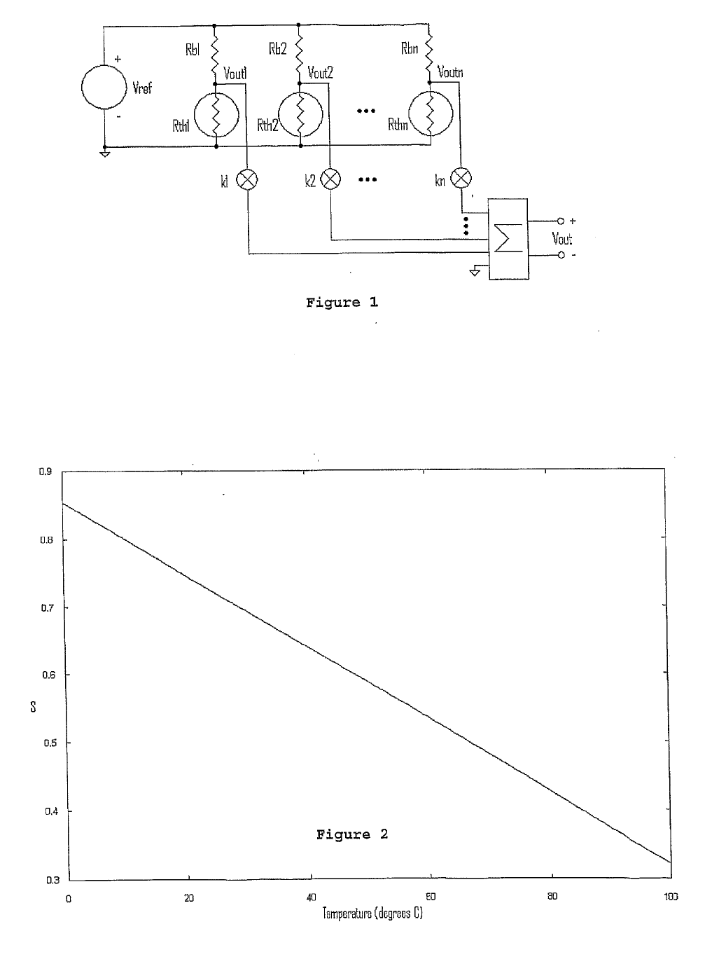

FIG. 1 is a diagram of a circuit in accordance with an embodiment of the present invention.

FIG. 2 is a graph of the ratio S (where S=Vout/Vref) against thermistor temperature T, for an embodiment based on FIG. 1.

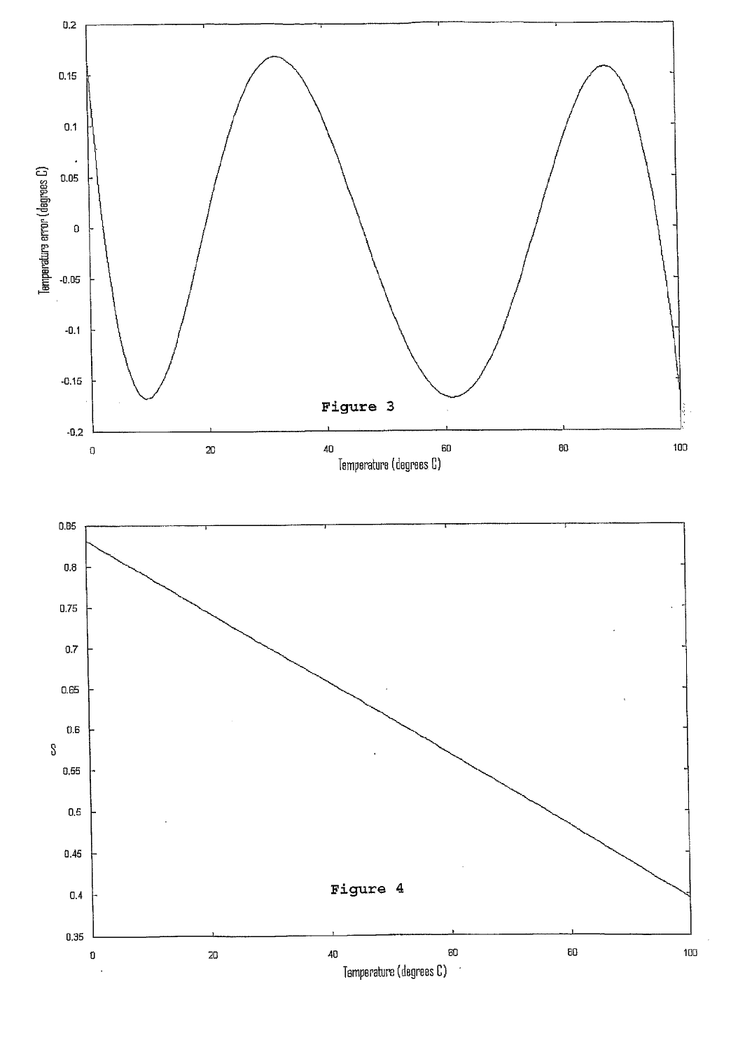

FIG. 3 is a graph of the temperature error versus temperature T for an embodiment based on FIG. 1.

FIG. 4 is a graph of S (S=Vout/Vref versus thermistor temperature T for a second embodiment, comprising three thermistors, based on FIG. 1.

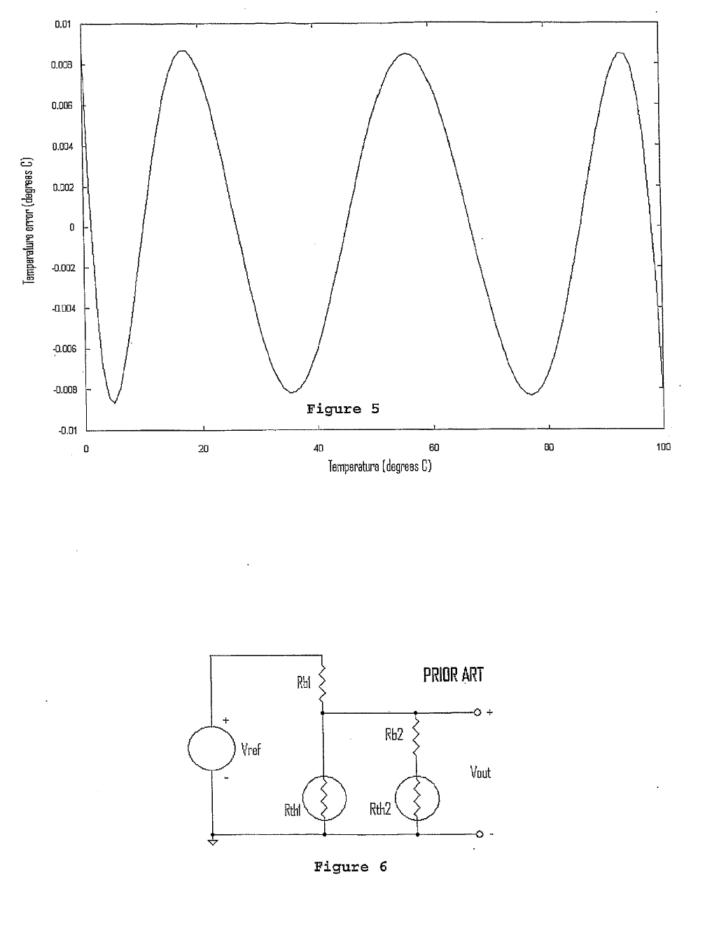

FIG. 5 is a graph of the temperature error versus temperature T of the second embodiment.

FIG. 6 is a diagram of a prior art circuit.

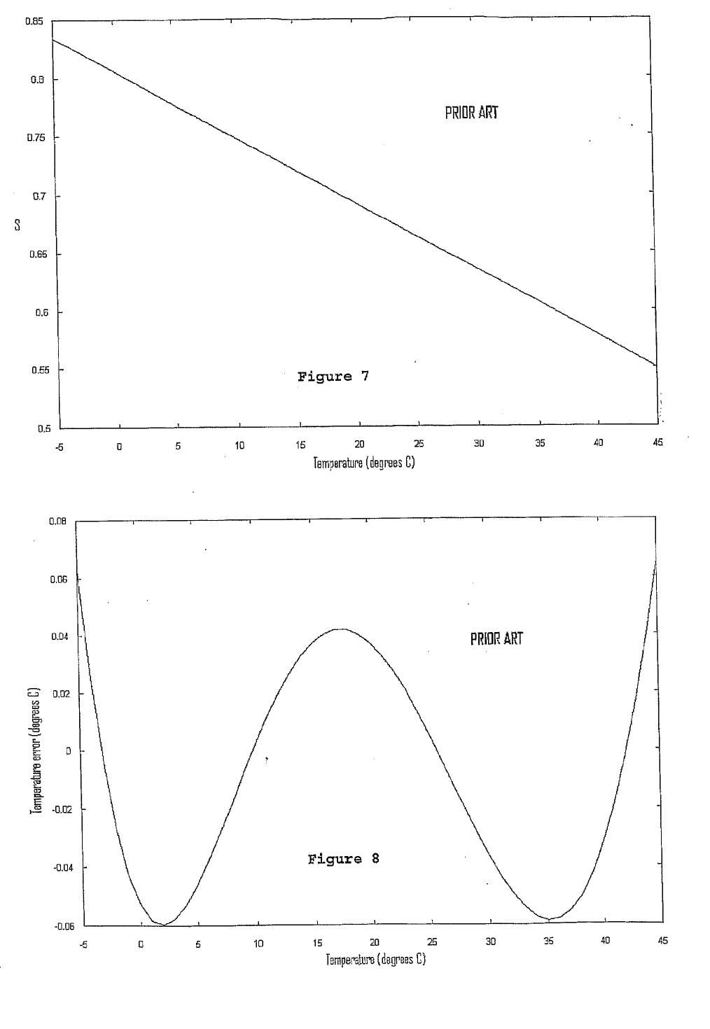

FIG. 7 is a graph of S (S=Vout/Vref) versus T for the prior art circuit of FIG. 6.

FIG. 8 is a graph of the temperature error against temperature T of the prior art circuit of FIG. 6.

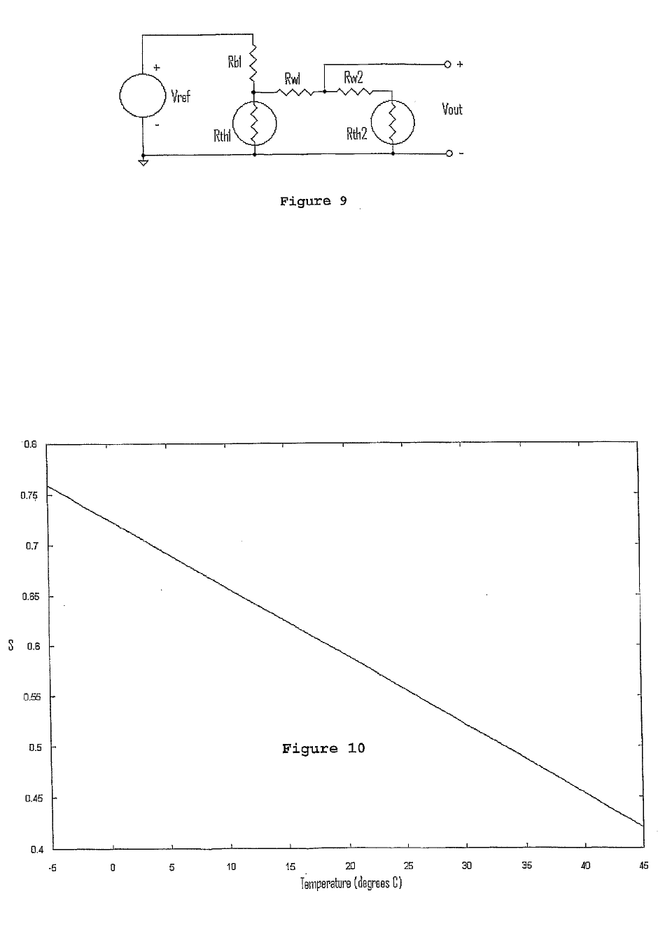

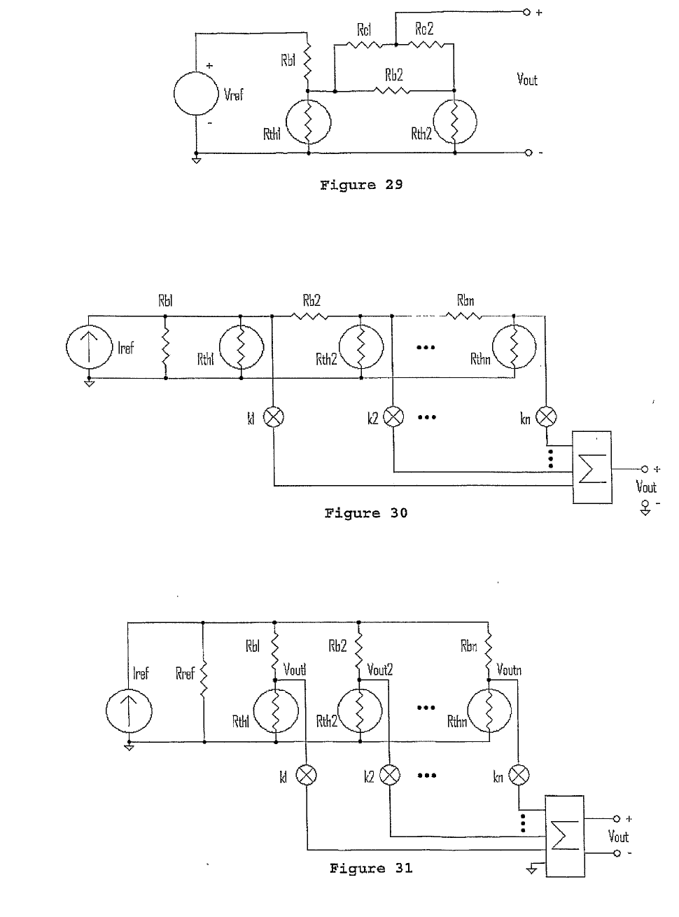

FIG. 9 depicts an embodiment similar to FIG. 6, but based on an embodiment shown in FIG. 29.

FIG. 10 is a graph of S (S=Vout/Vref) versus temperature T for the circuit of FIG. 9.

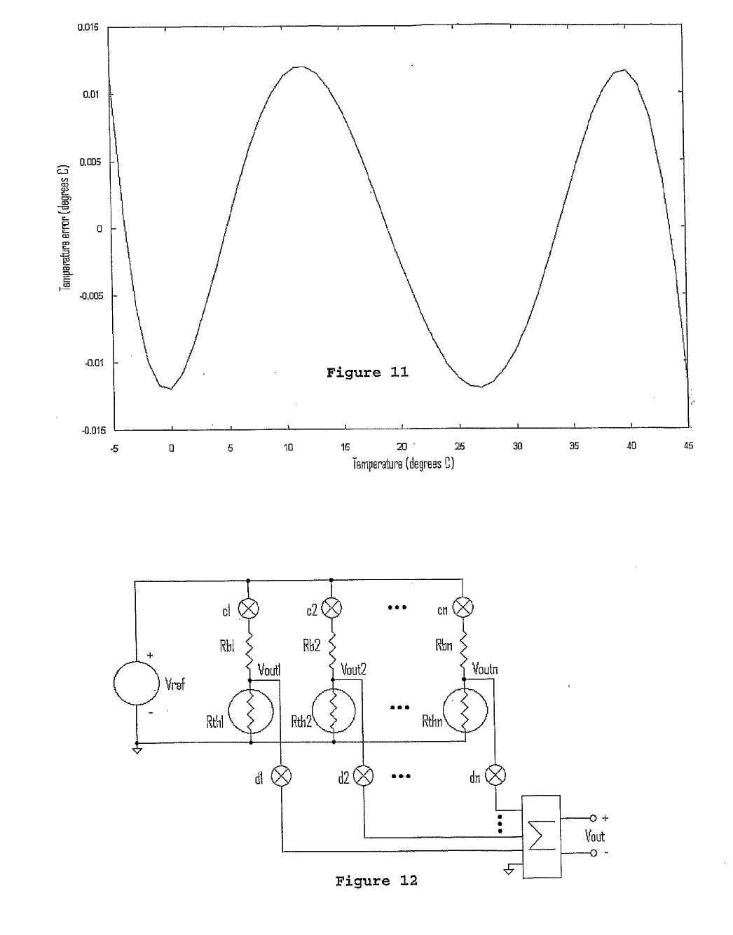

FIG. 11 is a graph of the temperature error against temperature T for the circuit of FIG. 9.

FIG. 12 depicts an embodiment that uses input weighting.

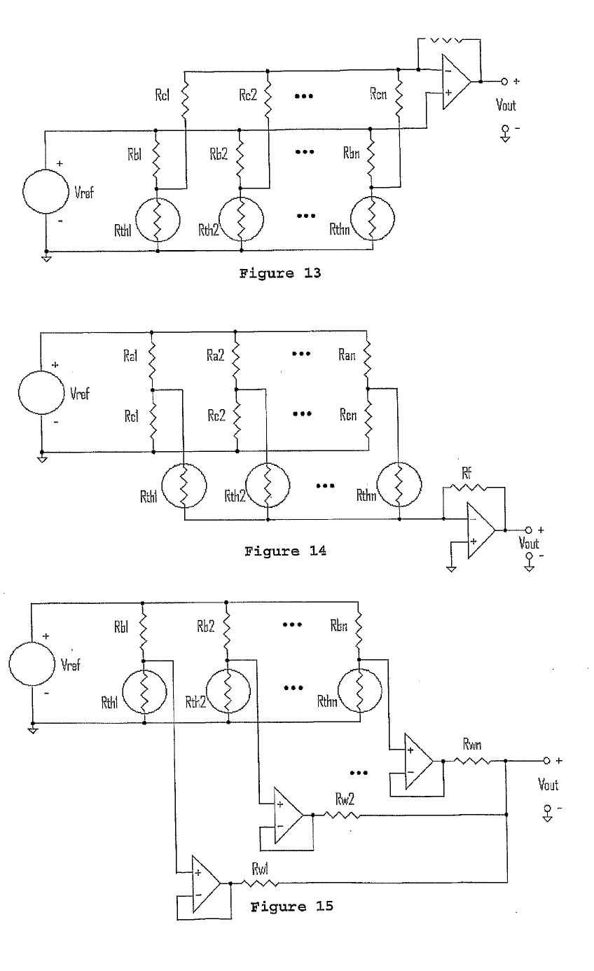

FIG. 13 depicts an embodiment that uses an op-amp as a summing point.

FIG. 14 depicts an alternative embodiment that uses an op-amp as a summing point.

FIG. 15 depicts an embodiment in which the summing point is at the junction of resistors Rw1 . . . Rwn.

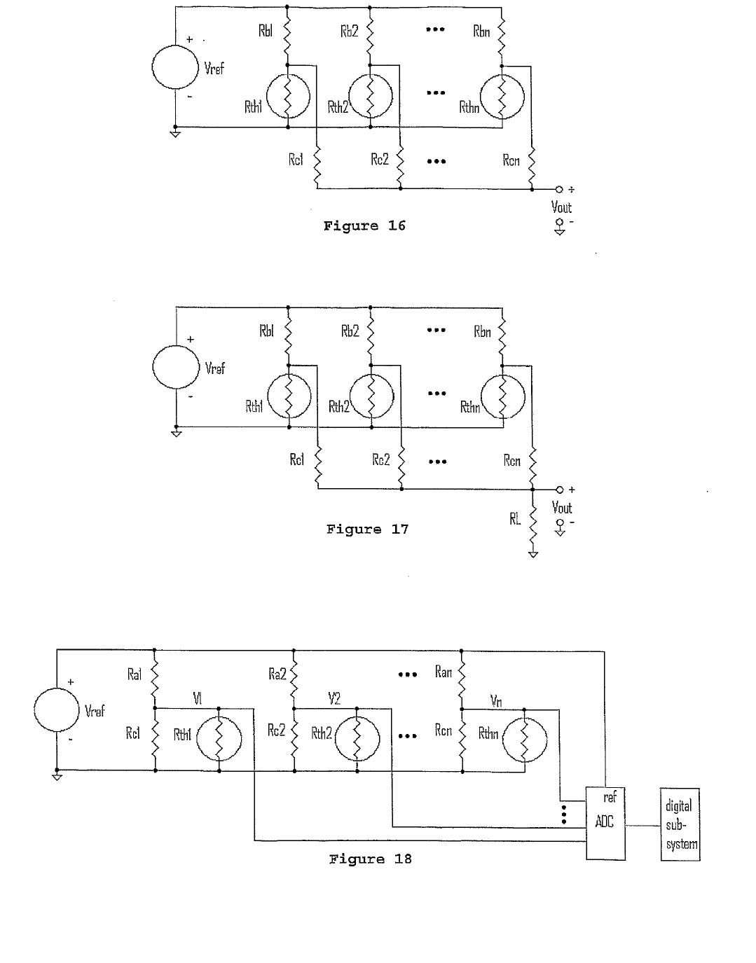

FIG. 16 depicts a preferred embodiment in which the summing point is at the junction of resistors Rc1 . . . . Rcn.

FIG. 17 depicts a preferred embodiment where the summing point may have a load resistance.

FIG. 18 depicts a circuit where the summing function is performed by digital means,

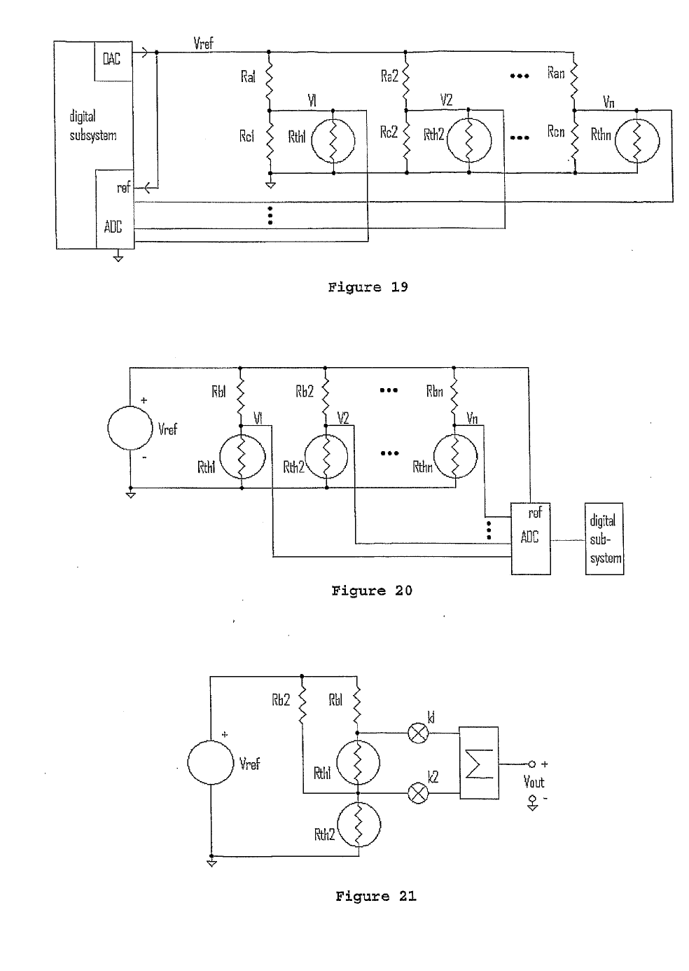

FIG. 19 shows an embodiment that employs a digital subsystem that incorporates an ADC subsystem and a voltage reference Vref.

FIG. 20 shows a preferred embodiment based on FIG. 1, where digital means performs the summing function.

FIG. 21 shows a preferred two-thermistor embodiment.

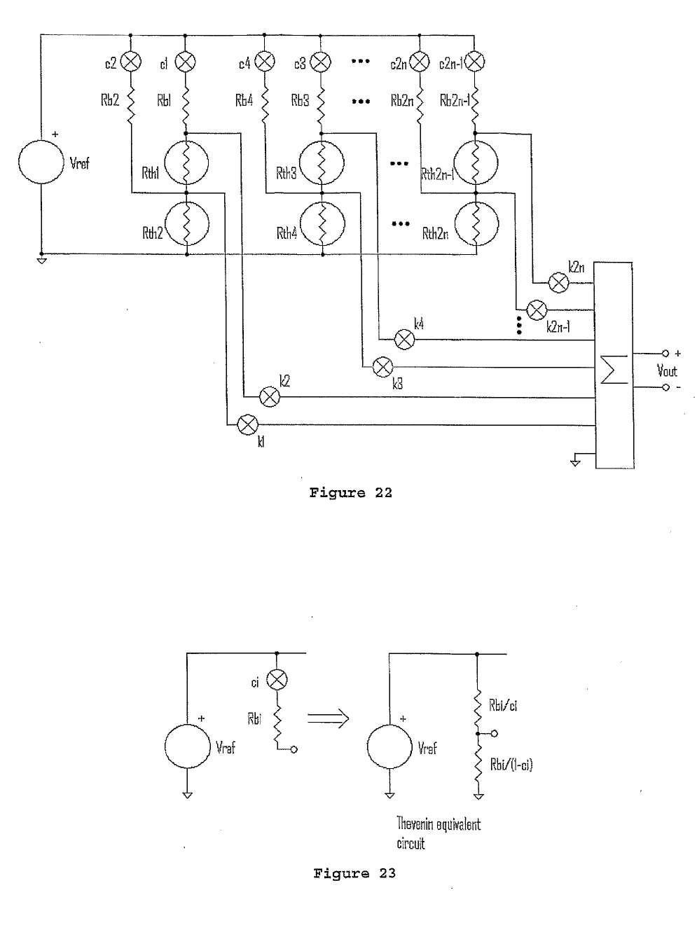

FIG. 22 shows an embodiment based on FIG. 21.

FIG. 23 shows a preferred method of implementing input weighting sub-circuits shown in FIG. 22.

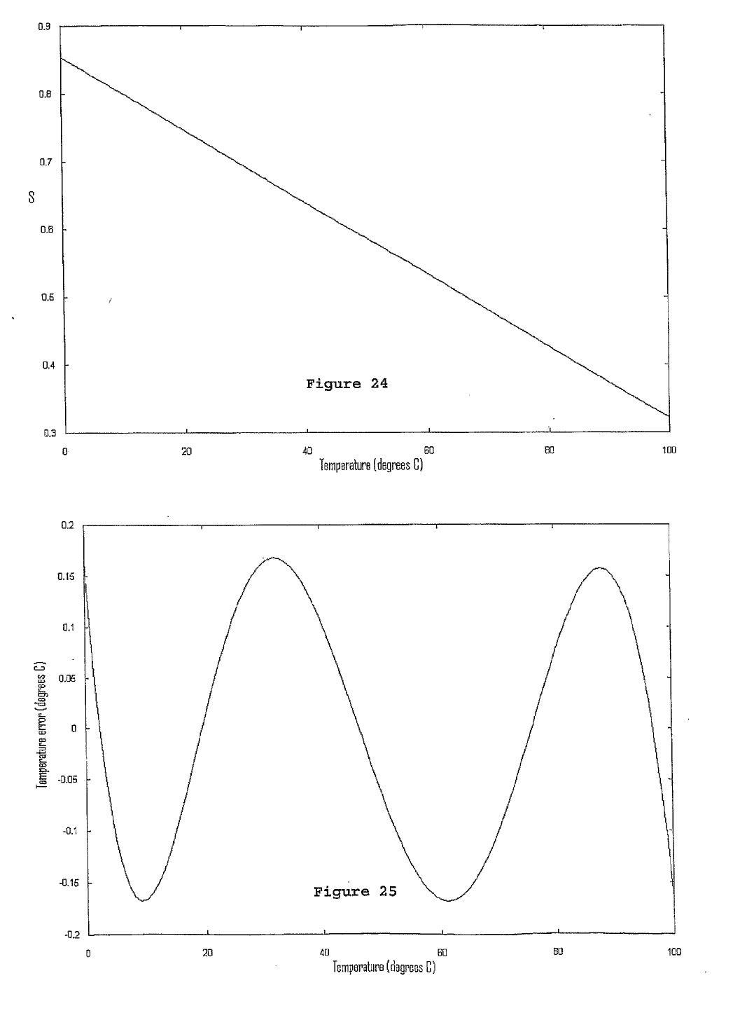

FIG. 24 shows a plot of S (S=Vout/Vref) versus thermistor temperature T for the circuit of FIG. 21.

FIG. 25 graphs the error Test-T versus temperature T for the circuit of FIG. 21.

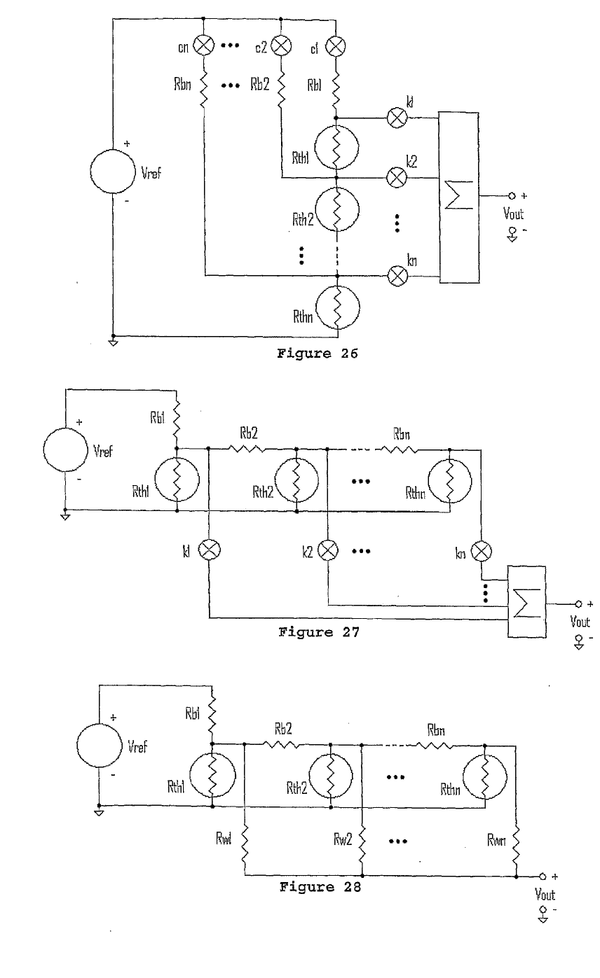

FIG. 26 shows an embodiment using n thermistors based on the two-thermistor embodiment of FIG. 21.

FIG. 27 shows an embodiment using n thermistors.

FIG. 28 shows an embodiment using n thermistors based on FIG. 27, where the junction of Rw1 . . . Rwn forms a summing point.

FIG. 29 shows a two-thermistor embodiment based on FIG. 28.

FIG. 30 shows an n-thermistor embodiment with current source input and a voltage output.

FIG. 31 shows another n-thermistor embodiment with current source input and a voltage output.

FIG. 32 shows an embodiment based on FIG. 31, where the input current source has been replaced by a Thevenin equivalent voltage source.

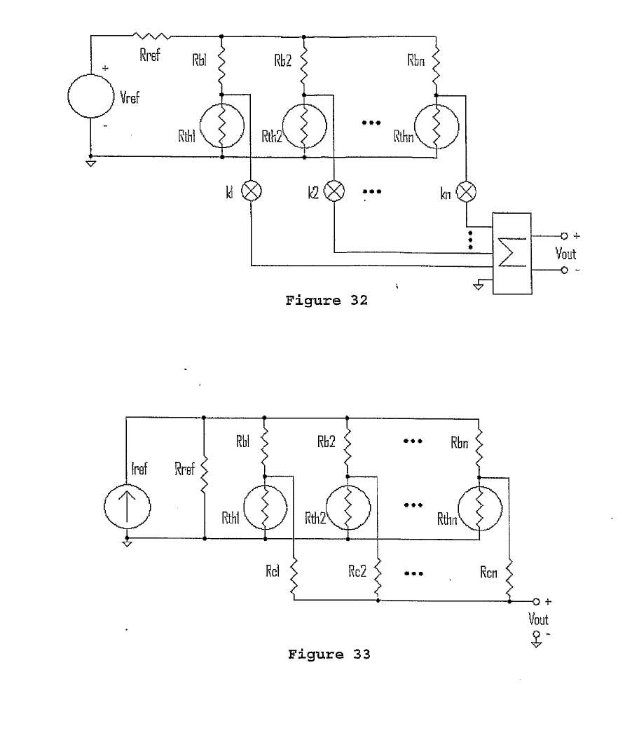

FIG. 33 shows an embodiment based on FIG. 31, where the junction of resistors Rc1 . . . Rcn forms a summing point.

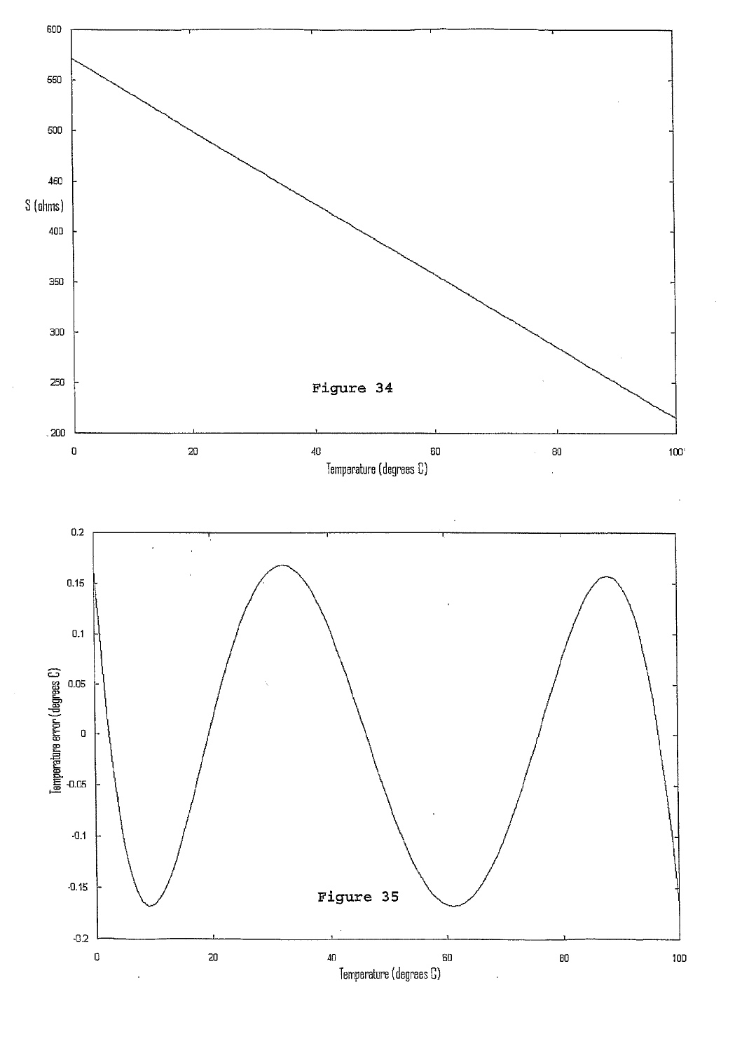

FIG. 34 shows a plot of S (where S=Vout/Iref) versus thermistor temperature T for an embodiment based on FIG. 31.

FIG. 35 graphs the error in the estimate, Test-T, versus temperature T for an embodiment based on FIG. 31.

FIG. 36 shows an embodiment where the weighting and summing functions are performed by an op-amp's feedback network.

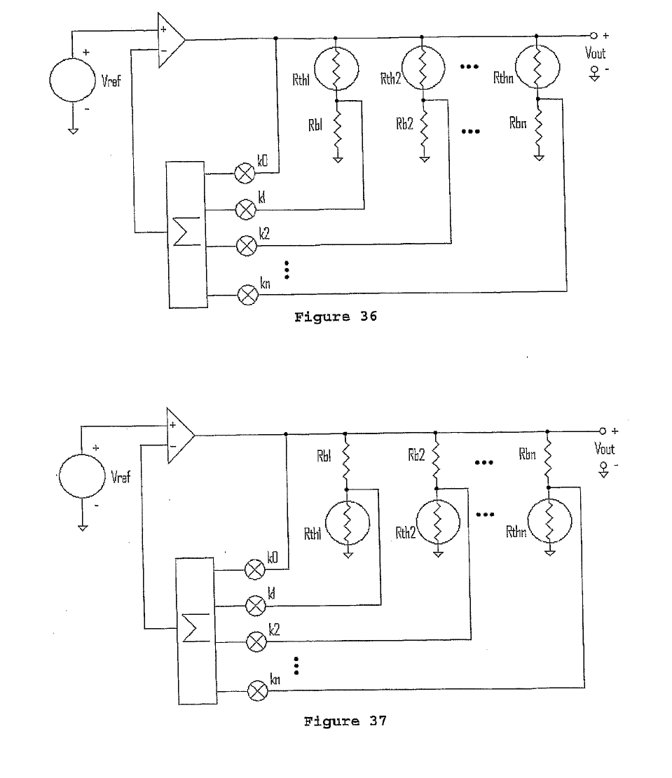

FIG. 37 shows a circuit similar to FIG. 36.

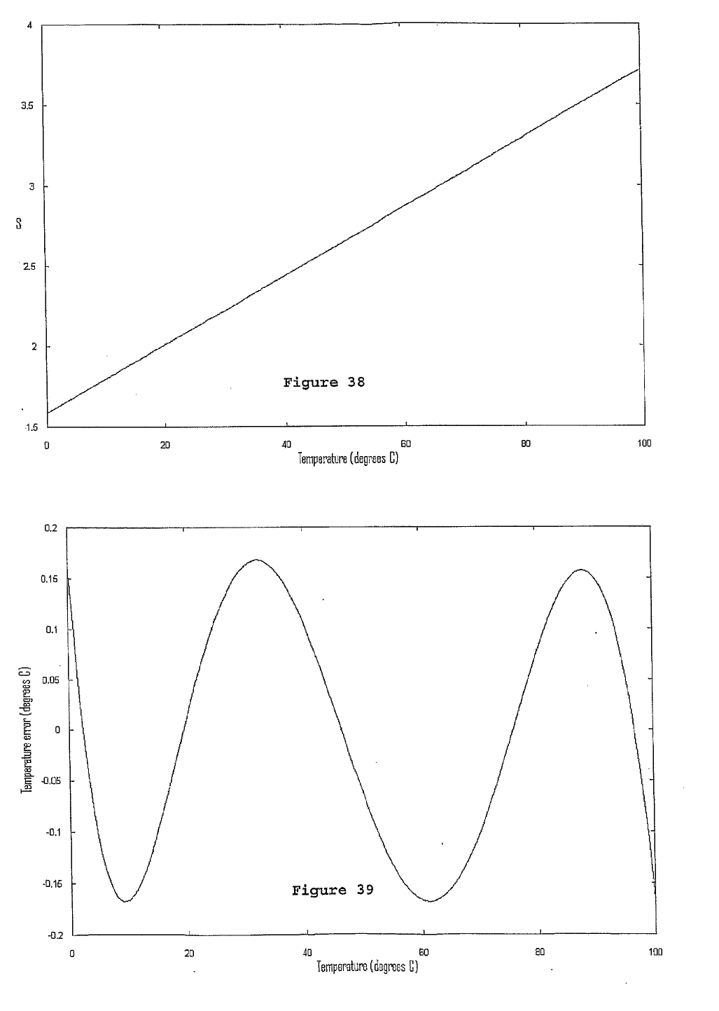

FIG. 38 shows a plot of S (S=Vout/Vref) versus thermistor temperature T for an embodiment based on FIG. 37.

FIG. 39 graphs the error in the estimate, Test-T, versus temperature T for an embodiment based on FIG. 37.

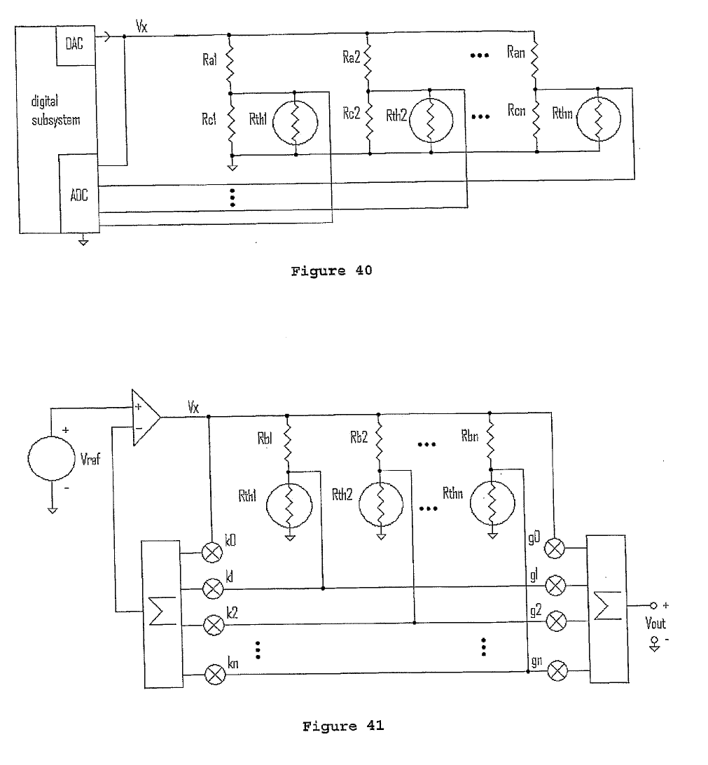

FIG. 40 shows an embodiment, based on FIG. 19, in which a digital subsystem implements the error amplifier function and the weighted summing function.

FIG. 41 shows an embodiment that employs more than one weighted summing network.

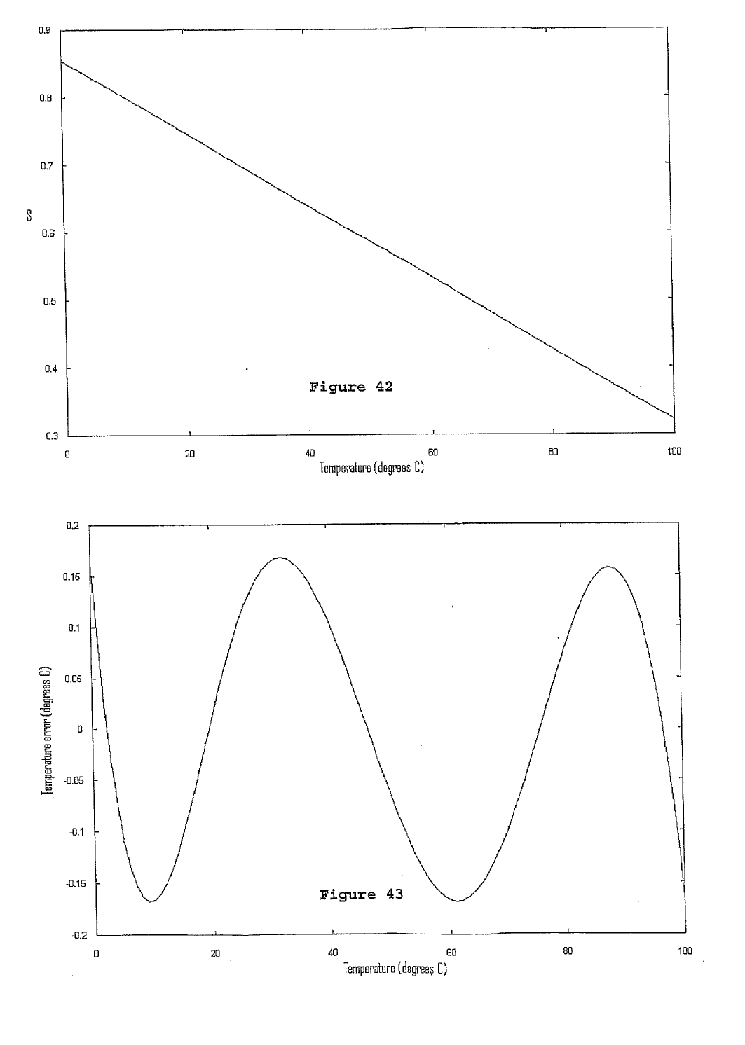

FIG. 42 shows a plot of S (S=Vout/Vref) versus thermistor temperature T for an embodiment based on FIG. 41.

FIG. 43 graphs the error in the estimate, Test-T, versus temperature T for an embodiment based on FIG. 41.

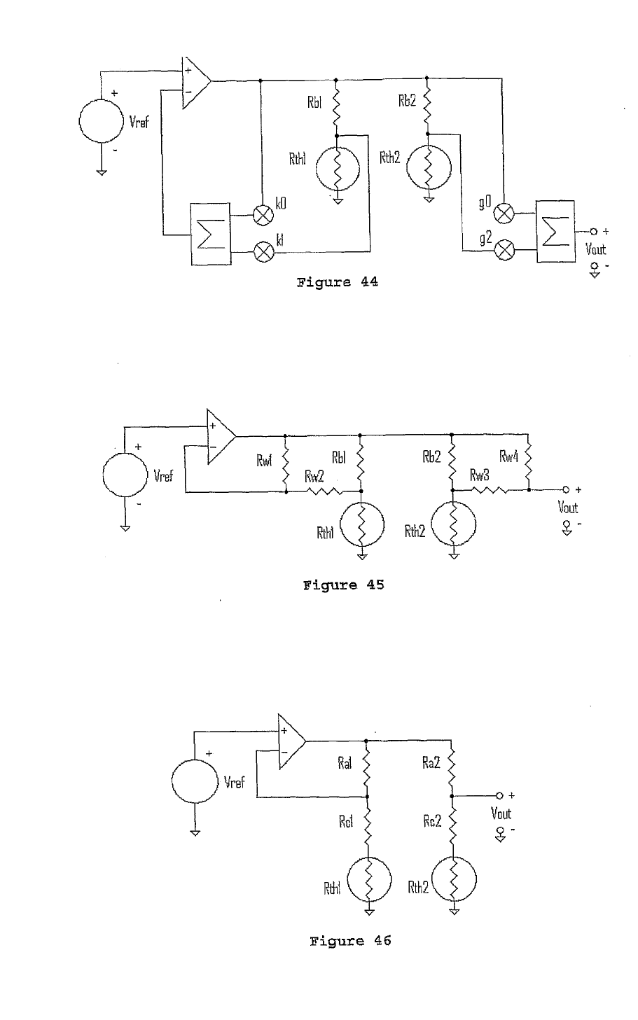

FIG. 44 shows a two-thermistor circuit derived from FIG. 41.

FIG. 45 shows an embodiment based on FIG. 44.

FIG. 46 is a preferred embodiment which is based on the circuit shown in FIG. 45.

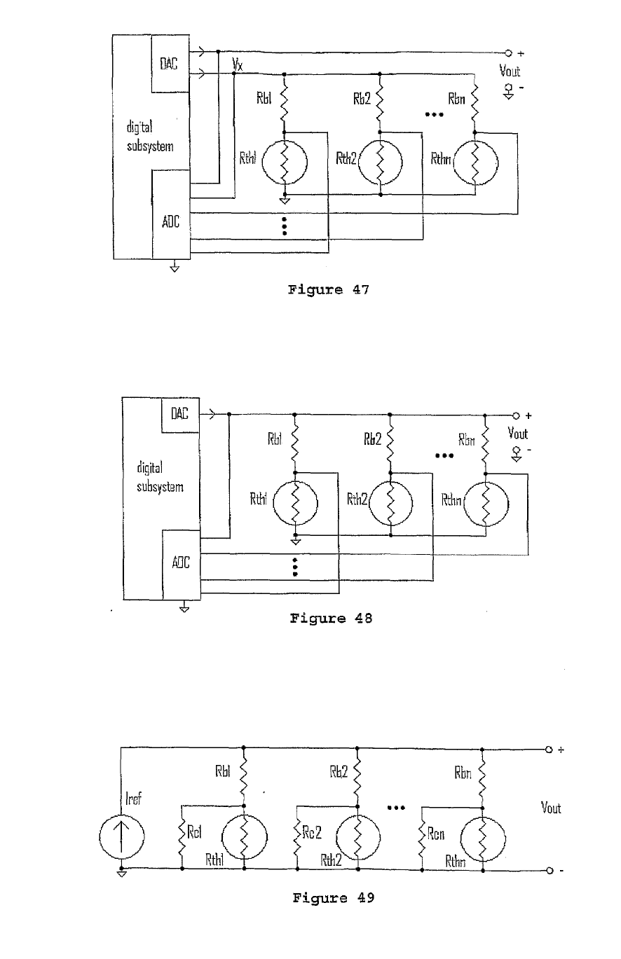

FIG. 47 shows an embodiment derived from FIG. 41.

FIG. 48 shows an embodiment derived from FIG. 37.

FIG. 49 shows an embodiment with an input current source and voltage output.

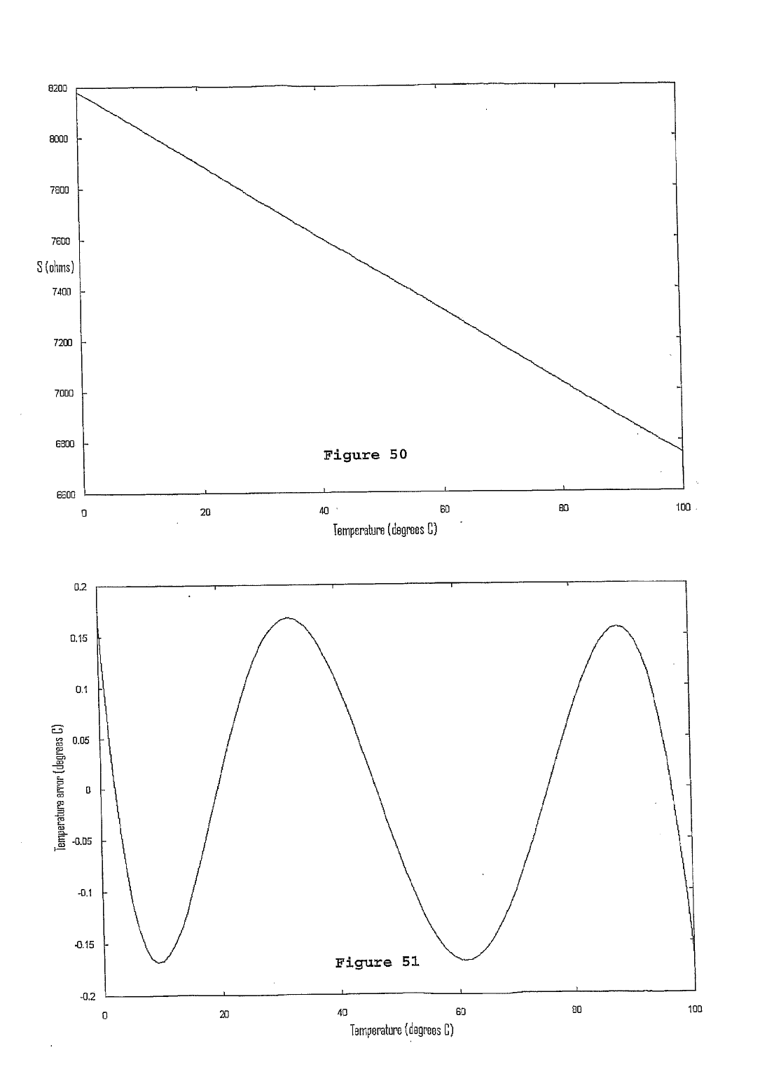

FIG. 50 shows a plot of S (S=Vout/Iref) versus temperature T for an embodiment based on FIG. 49.

FIG. 51 graphs the temperature error versus temperature T for an embodiment based on FIG. 49.

FIG. 52 shows a preferred embodiment derived from FIG. 49.

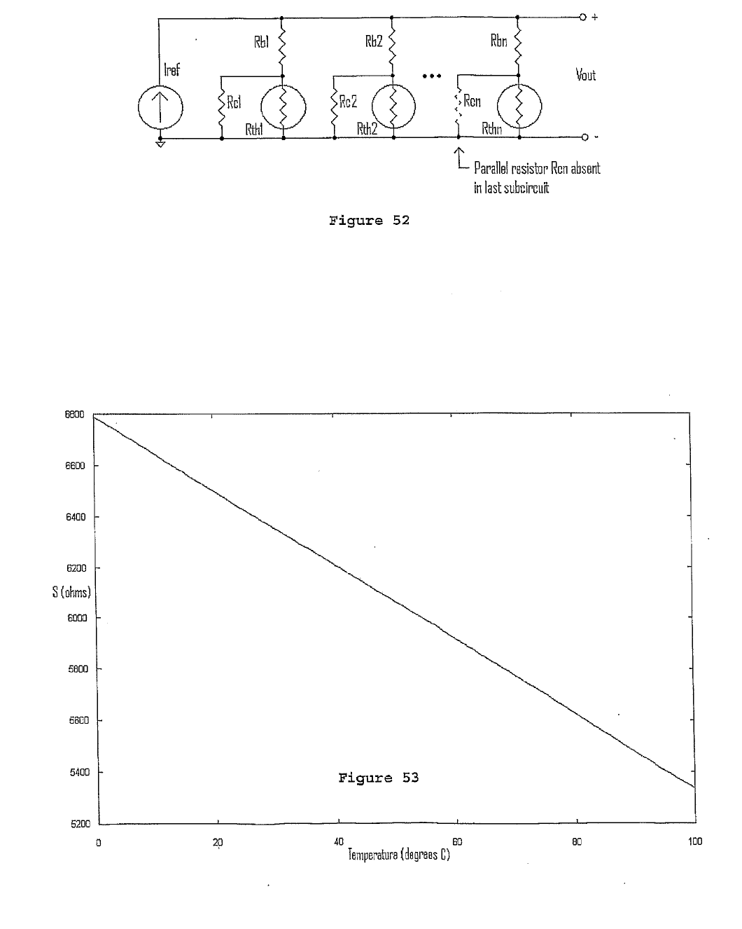

FIG. 53 shows a plot of S (S=Vout/Iref) versus temperature T for an embodiment based on FIG. 52.

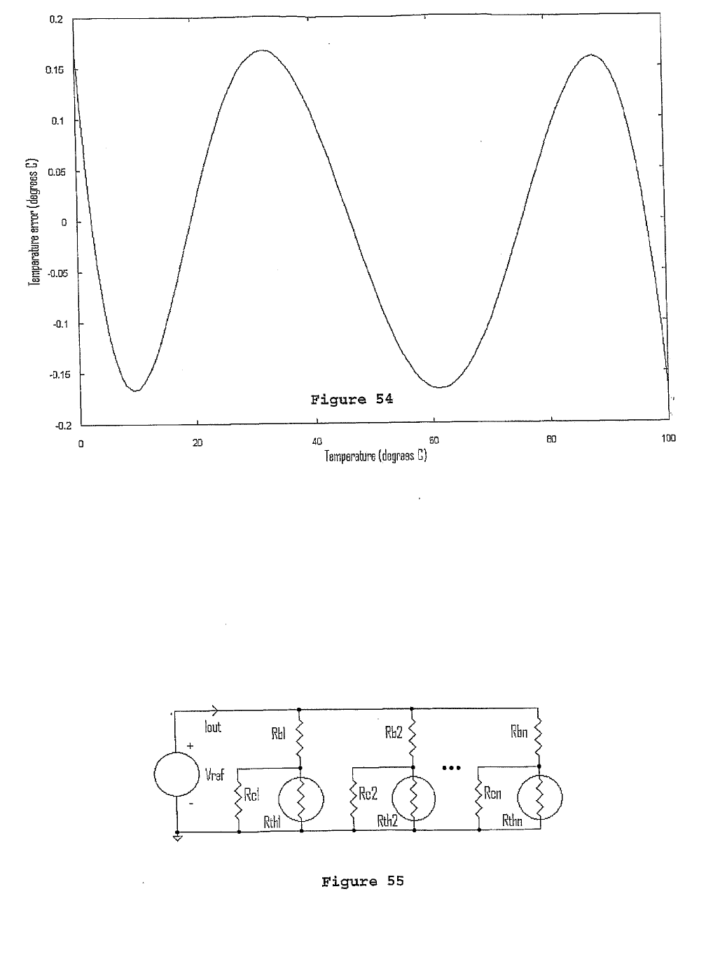

FIG. 54 graphs the temperature error versus temperature T for an embodiment based on FIG. 52.

FIG. 55 shows an embodiment where the output is the current Iout drawn from the input voltage source Vref.

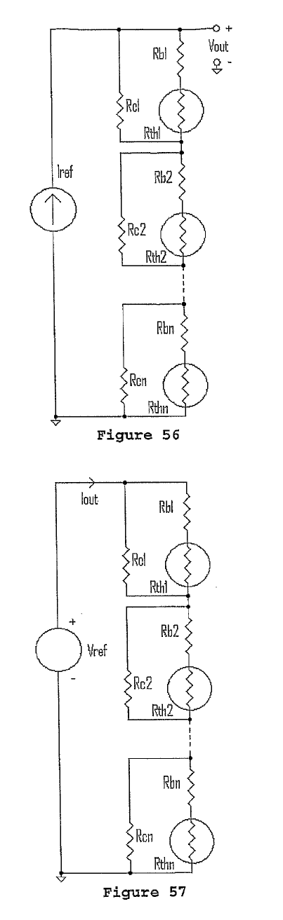

FIG. 56 shows an embodiment where the output is the voltage Vout across the input current source Iref.

FIG. 57 shows an embodiment where the output is the current Iout drawn from the input voltage source Vref.

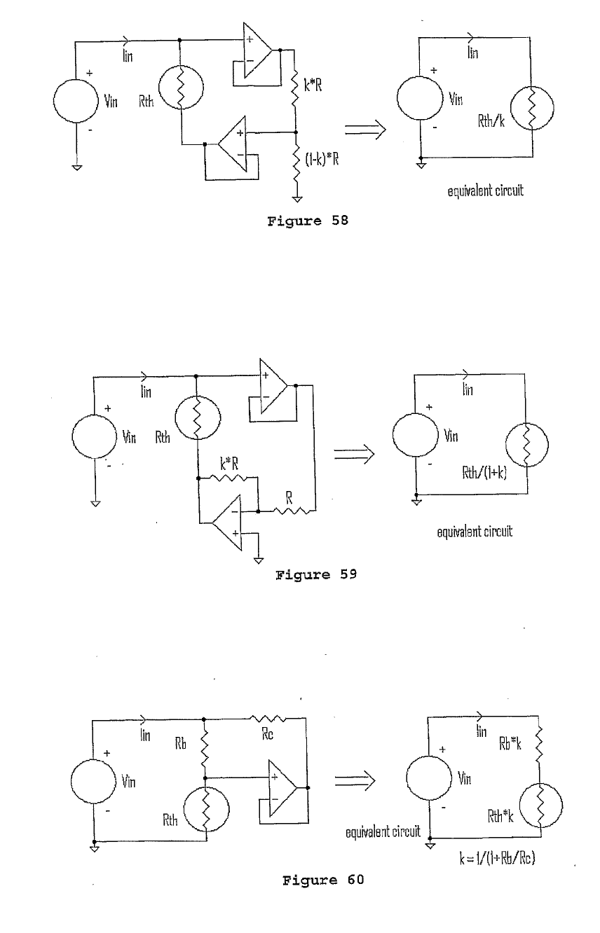

FIG. 58 shows a circuit for scaling up a thermistor.

FIG. 59 shows a circuit for scaling down a thermistor.

FIG. 60 shows a circuit for providing a scaled down thermistor plus series resistor.

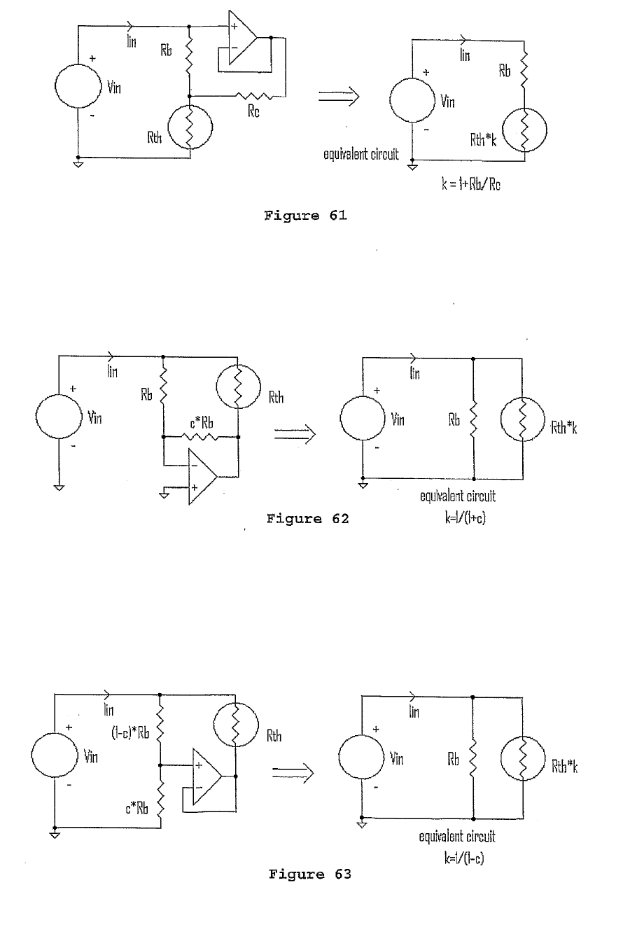

FIG. 61 shows a circuit for providing a scaled up thermistor plus series resistor.

FIG. 62 shows a circuit for providing a scaled down thermistor plus parallel resistor.

FIG. 63 shows a circuit for providing a parallel resistor plus scaled up thermistor.

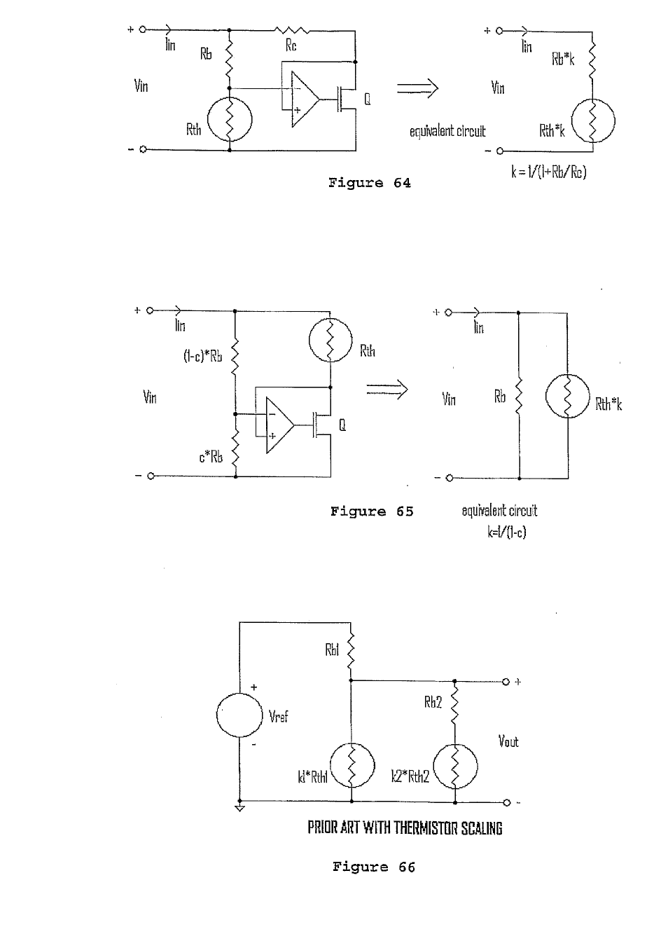

FIGS. 64 and 65 depict circuits that implement floating scaled thermistors.

FIG. 66 shows an embodiment where scaling factors k1 and k2 are applied to thermistors Rth1 and Rth2 respectively.

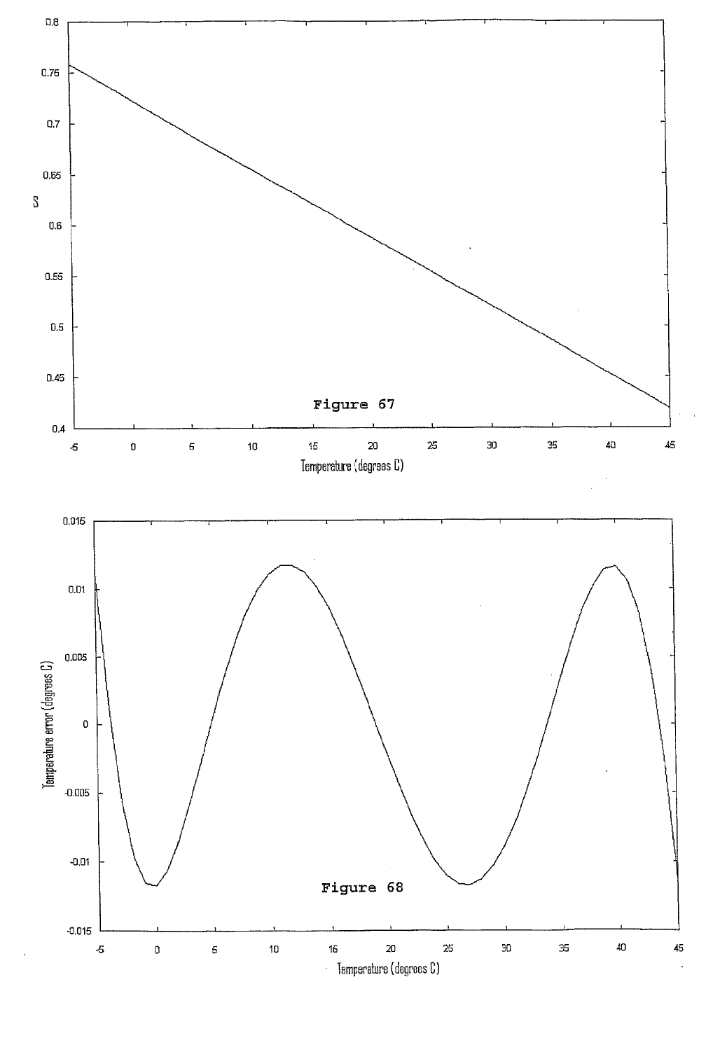

FIG. 67 shows a plot of S (S=Vout/Vref) versus temperature T for the circuit of FIG. 66.

FIG. 68 graphs the temperature error versus temperature T for the circuit of FIG. 66.

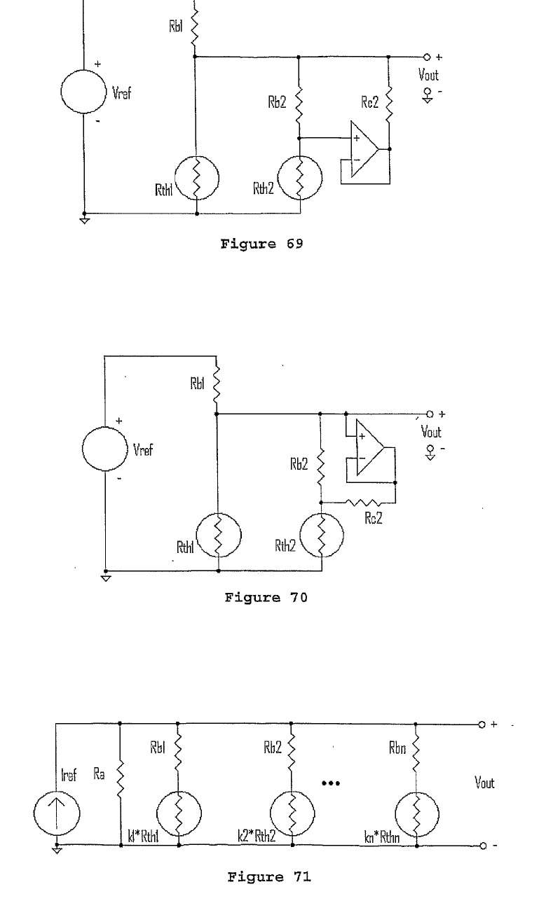

FIG. 69 shows an embodiment of the invention that is a transformation of FIG. 66.

FIG. 70 shows a variation on FIG. 69, in which thermistor Rth2 is scaled up instead of down.

FIG. 71 depicts an embodiment in which each thermistor Rthi, i=1 . . . n, has a scaling factor ki.

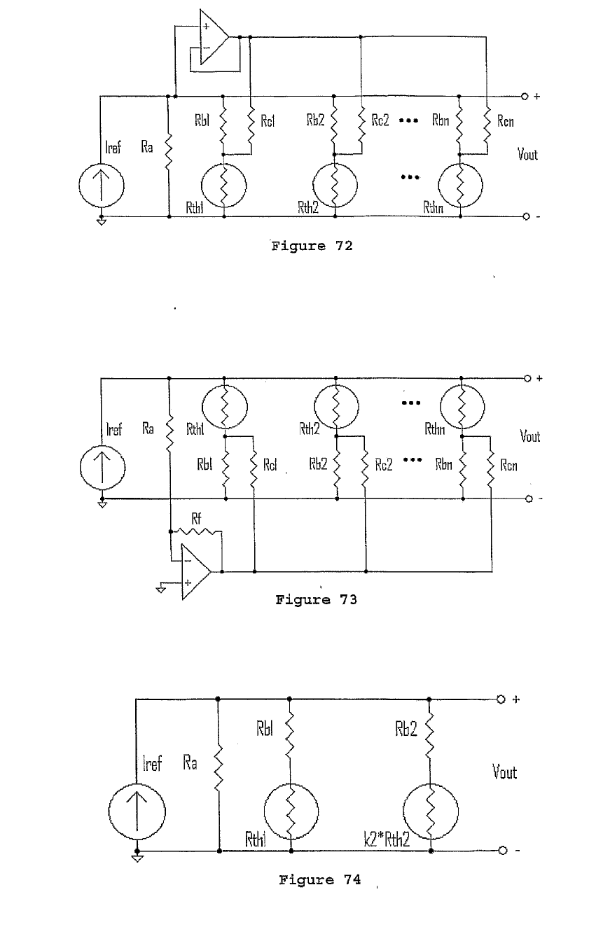

FIG. 72 shows a one possible transformation of FIG. 71, according to the present invention.

FIG. 73 shows another possible transformation of FIG. 71.

FIG. 74 shows a two-thermistor circuit based on FIG. 71.

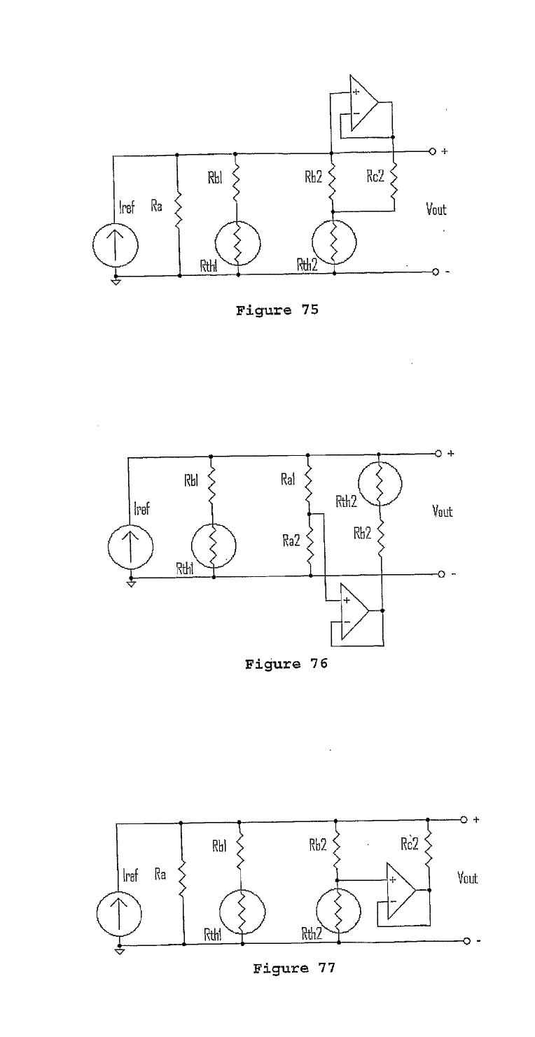

FIGS. 75 and 76 show possible transformations of FIG. 74 when k2>1.

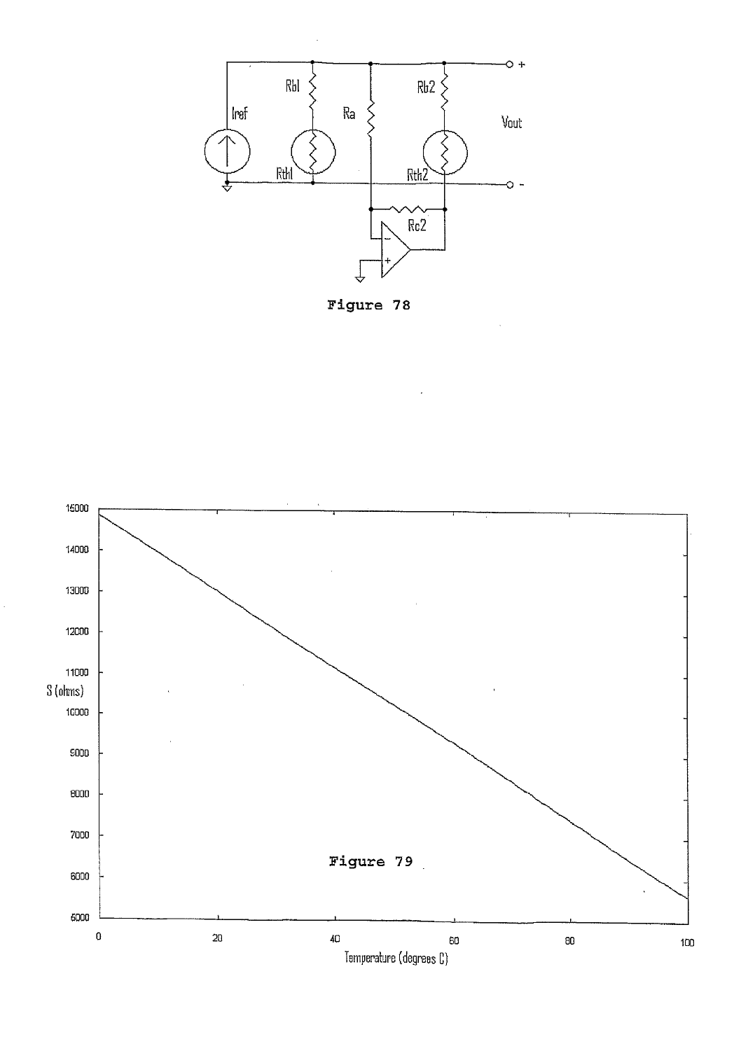

FIGS. 77 and 78 show possible transformations of FIG. 74 when k2<1.

FIG. 79 shows a plot of S (S=Vout/Iref) versus temperature T for an embodiment based on FIG. 71.

FIG. 80 graphs the temperature error versus temperature T for an embodiment based on FIG. 71.

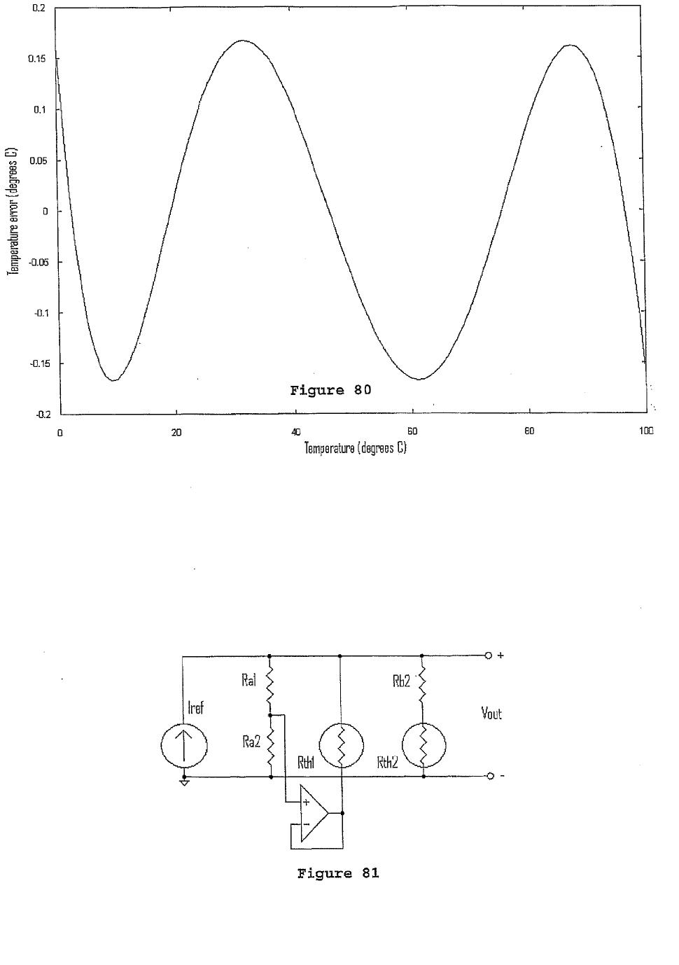

FIG. 81 shows an embodiment based on FIG. 71.

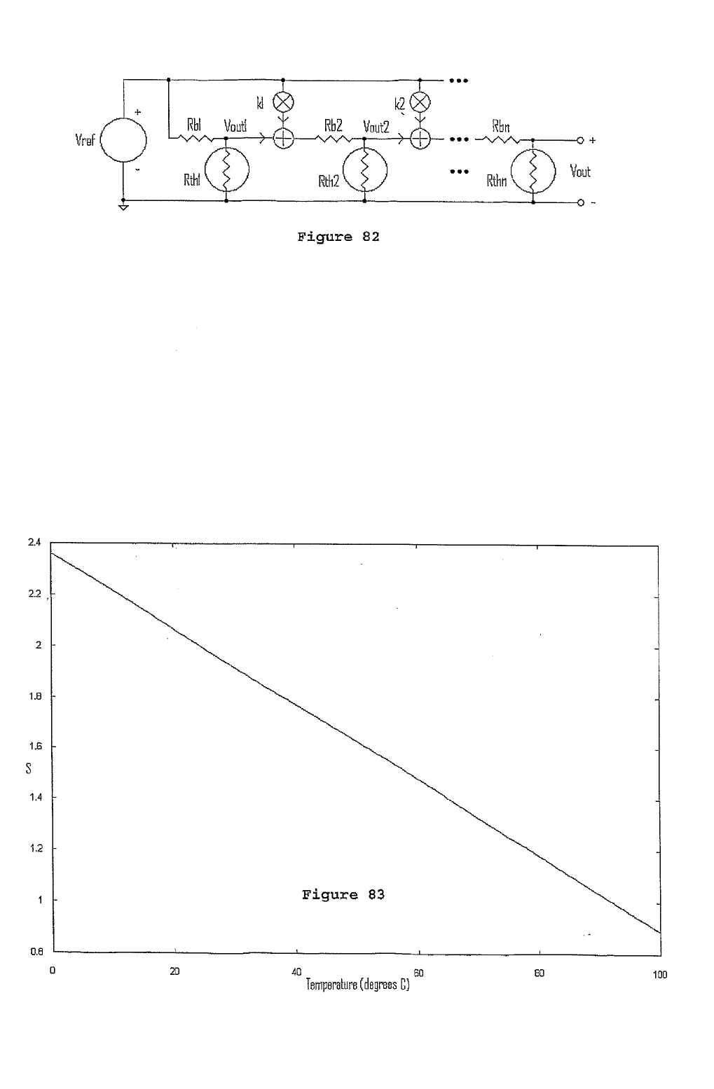

FIG. 82 shows an embodiment of the invention that uses the product technique.

FIG. 83 shows a plot of S (S=Vout/Vref) versus temperature T for an embodiment based on FIG. 82.

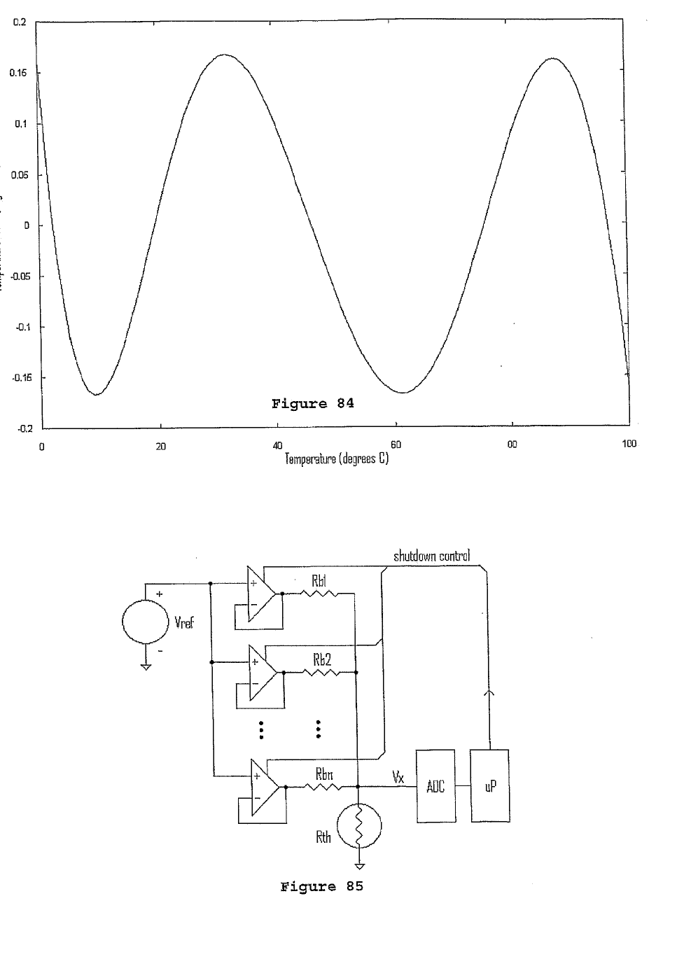

FIG. 84 graphs the temperature error versus temperature T for an embodiment based on FIG. 82.

FIG. 85 shows an embodiment derived from FIG. 1 that uses a single thermistor.

FIG. 86 shows an embodiment based on FIG. 85 where the weighting function is performed outside the uP, at the input of each amplifier.

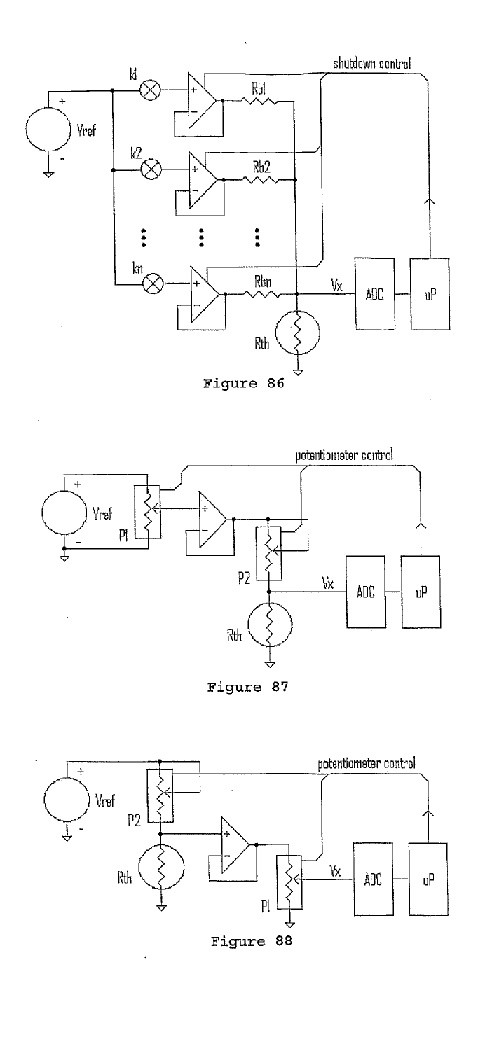

FIG. 87 shows an embodiment that uses two digitally controlled potentiometers or resistance networks.

FIG. 88 shows an embodiment derived from FIG. 87.

FIG. 89 shows an embodiment based on FIG. 85 where the weighting function is performed partly or wholly by a Digital to Analog Converter (DAC).

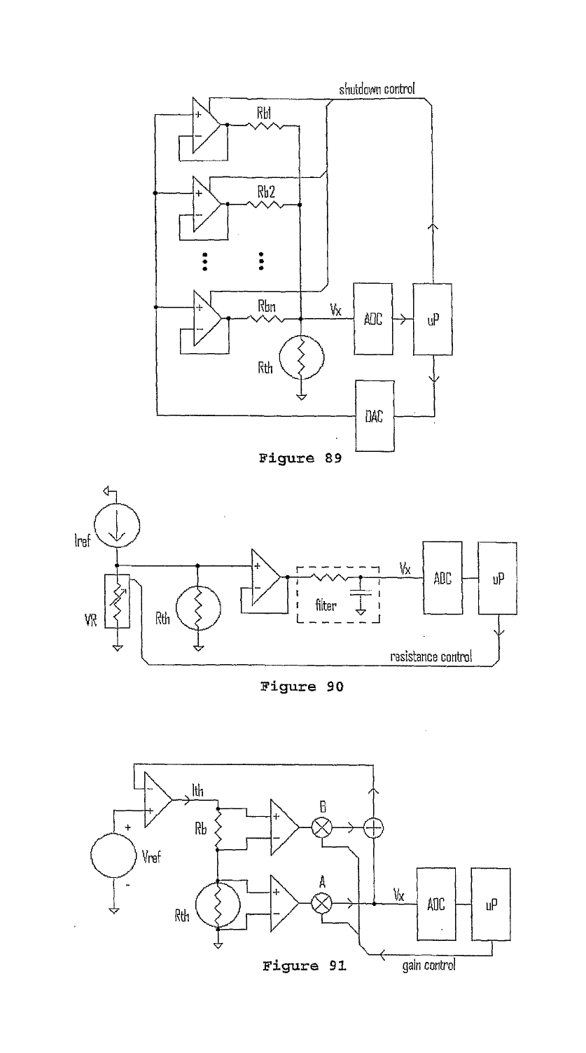

FIG. 90 shows an embodiment where each of the summing and weighting functions are performed partly or wholly outside the uP.

FIG. 91 shows on embodiment where the effective bias resistance Rbias is controlled by the ratio of the two amplifier gains.

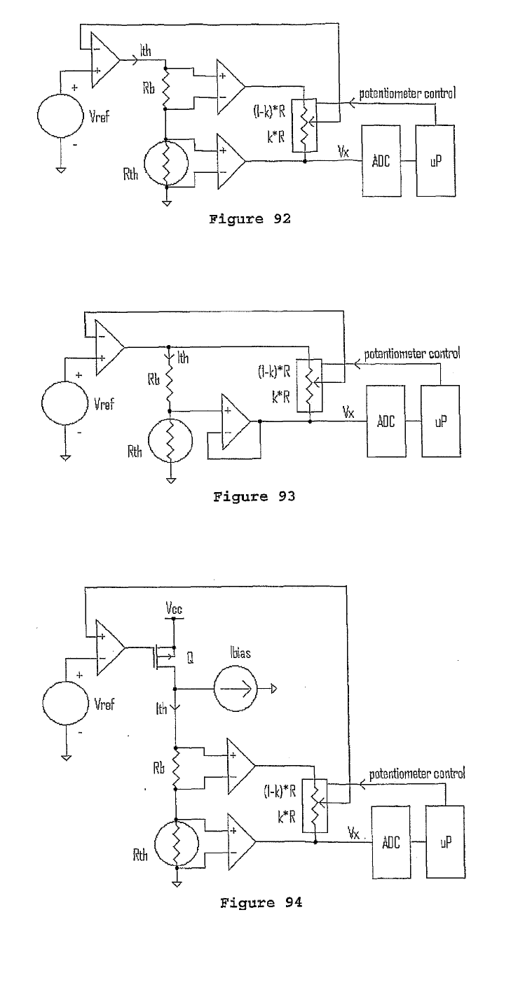

FIG. 92 shows an embodiment that has two instrumentation amplifiers with fixed gains.

FIG. 93 shows an embodiment derived from FIG. 92 that uses a single operational amplifier (“op-amp”).

FIG. 94 shows an embodiment derived from FIG. 92.

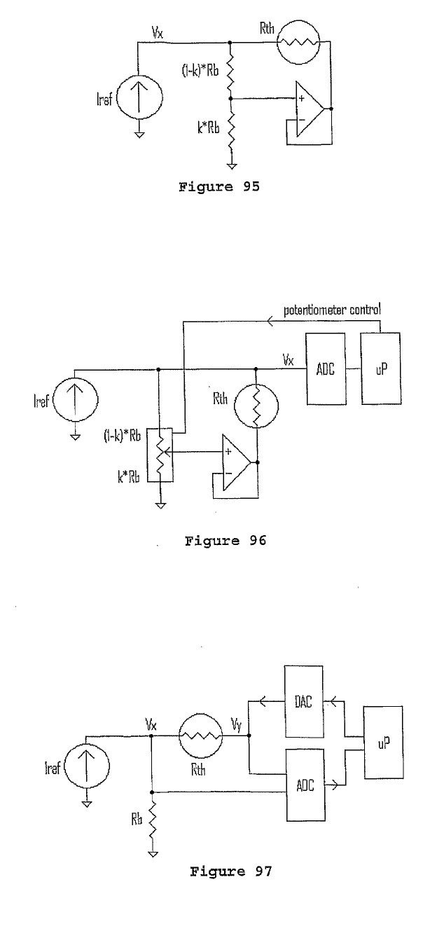

FIG. 95 shows a circuit similar to FIG. 63.

FIG. 96 shows an embodiment of the invention derived from FIG. 95.

FIG. 97 shows an embodiment of the invention derived from FIG. 96.

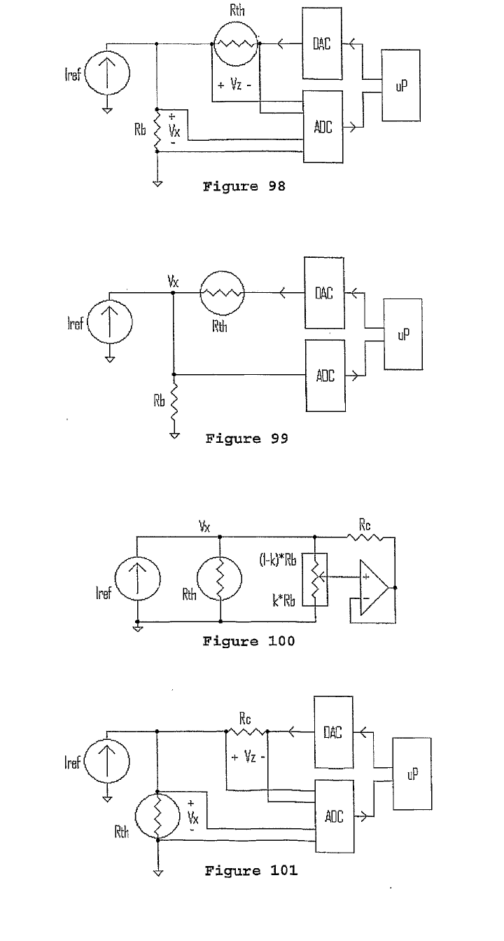

FIG. 98 shows an embodiment derived from FIG. 97.

FIG. 99 shows an embodiment derived from FIG. 97.

FIG. 100 shows a circuit that is related to FIG. 95.

FIG. 101 shows an embodiment derived from FIG. 100.

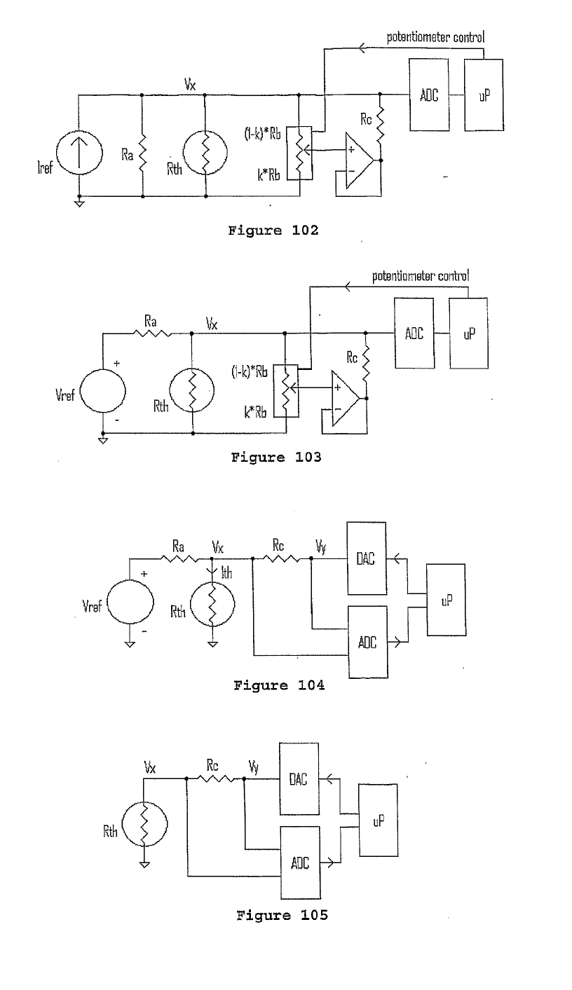

FIG. 102 shows an embodiment derived from FIG. 100.

FIG. 103 is an embodiment similar to FIG. 102, that employs the Thevenin equivalent circuit of the input source in FIG. 102.

FIG. 104 shows an embodiment derived from FIG. 103.

FIG. 105 shows an embodiment derived from FIG. 104.

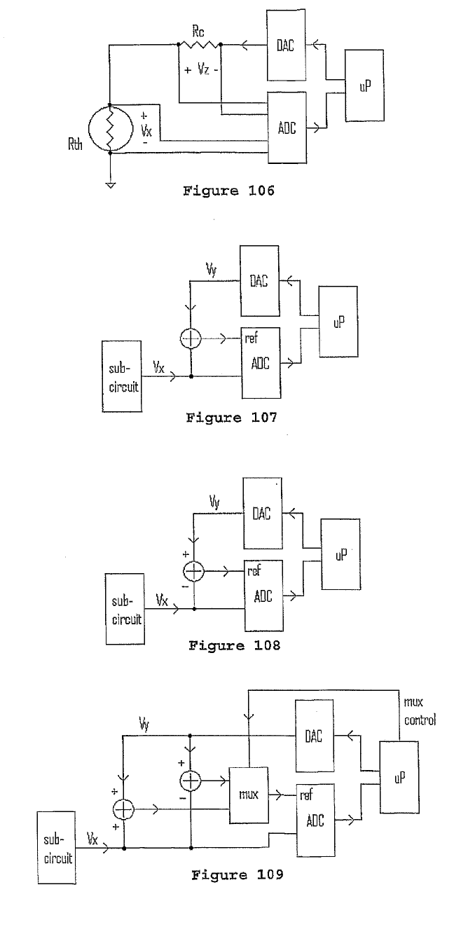

FIG. 106 shows an embodiment, derived from FIG. 105, that has 4-wire connections to the thermistor and to resistor Rc.

FIG. 107 shows an embodiment that has a sensor sub-circuit connected to an Analog-to-Digital Converter (ADC), which operates under the control of a microprocessor (uP).

FIGS. 108 and 109 show variations on the circuit shown in FIG. 107.

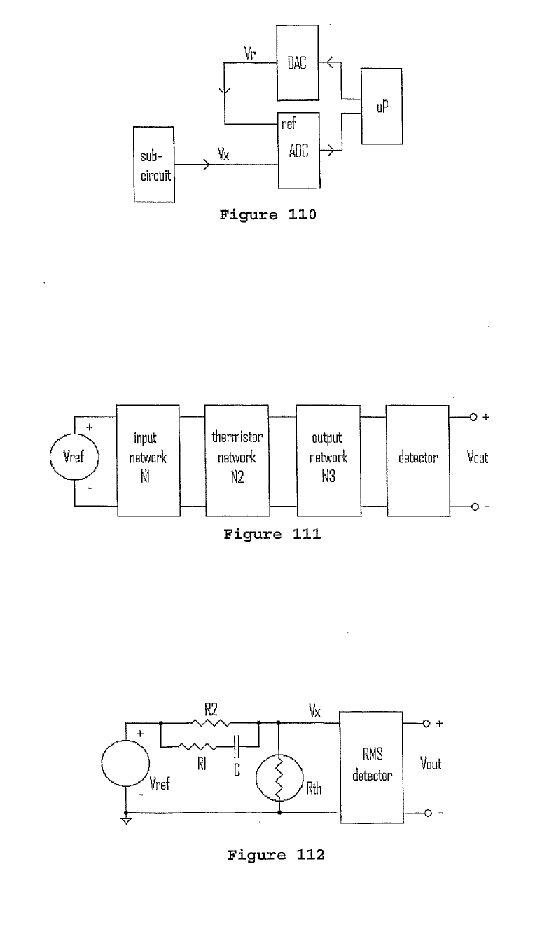

FIG. 110 shows an embodiment based on the embodiment of FIG. 107.

FIG. 111 depicts an embodiment in which a reference signal source Vref comprises one or more frequencies.

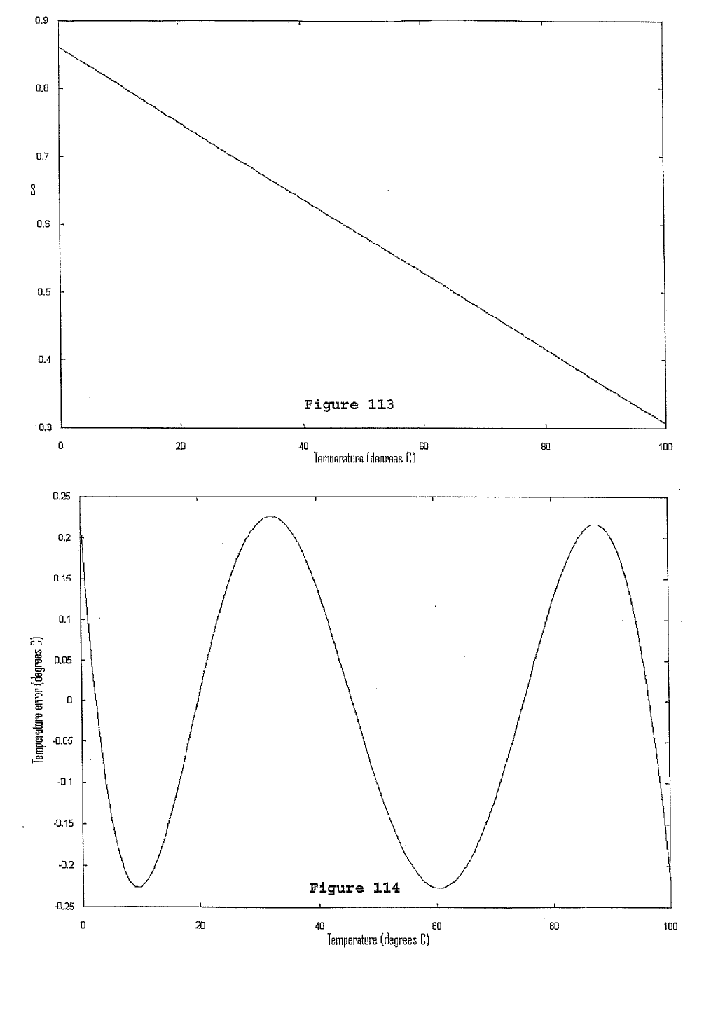

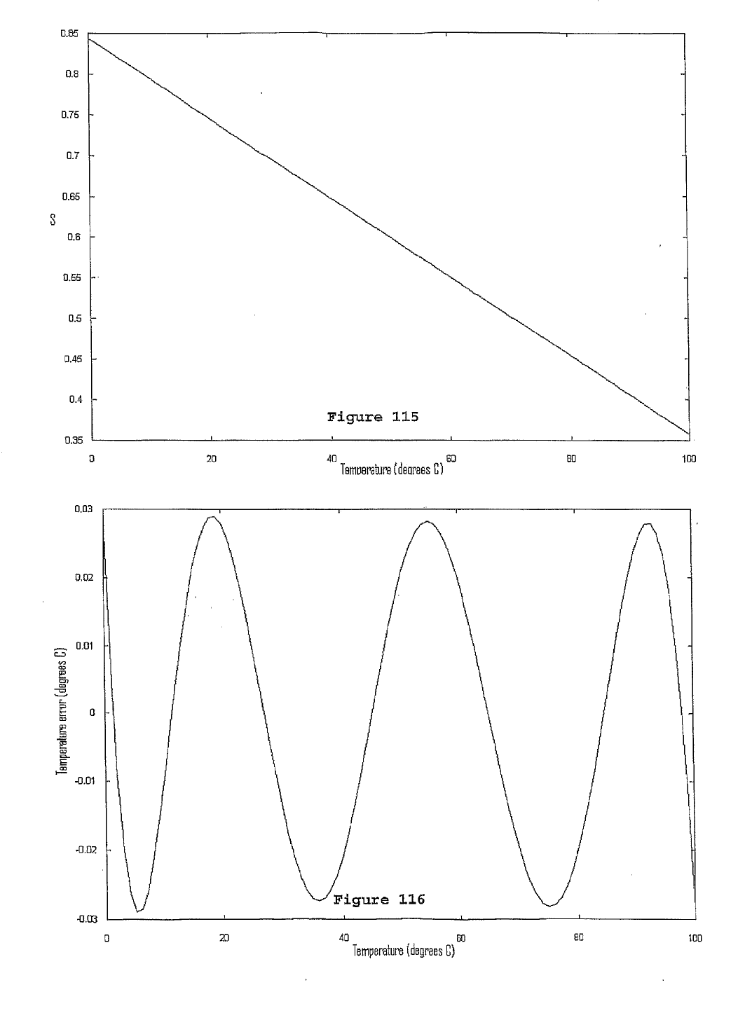

FIG. 112 shows an embodiment based on FIG. 111.

FIG. 113 shows a plot of S (S=Vout/|Vref|) versus thermistor temperature T for an embodiment based on FIG. 112. The input source has two frequency components.

FIG. 114 graphs the temperature error versus temperature T, corresponding to FIG. 113.

FIG. 115 shows a plot of S (S=Vout/|Vref|) versus thermistor temperature T for an embodiment based on FIG. 112. The input source has three frequency components.

FIG. 116 graphs the temperature error versus temperature T, corresponding to FIG. 115.

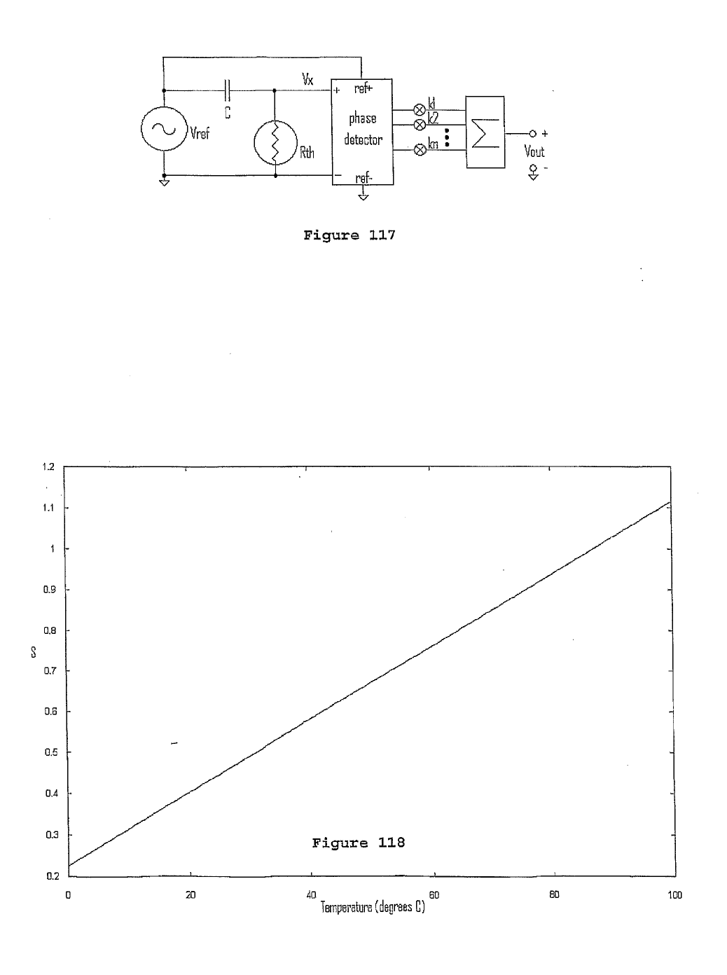

FIG. 117 shows an embodiment based on FIG. 111.

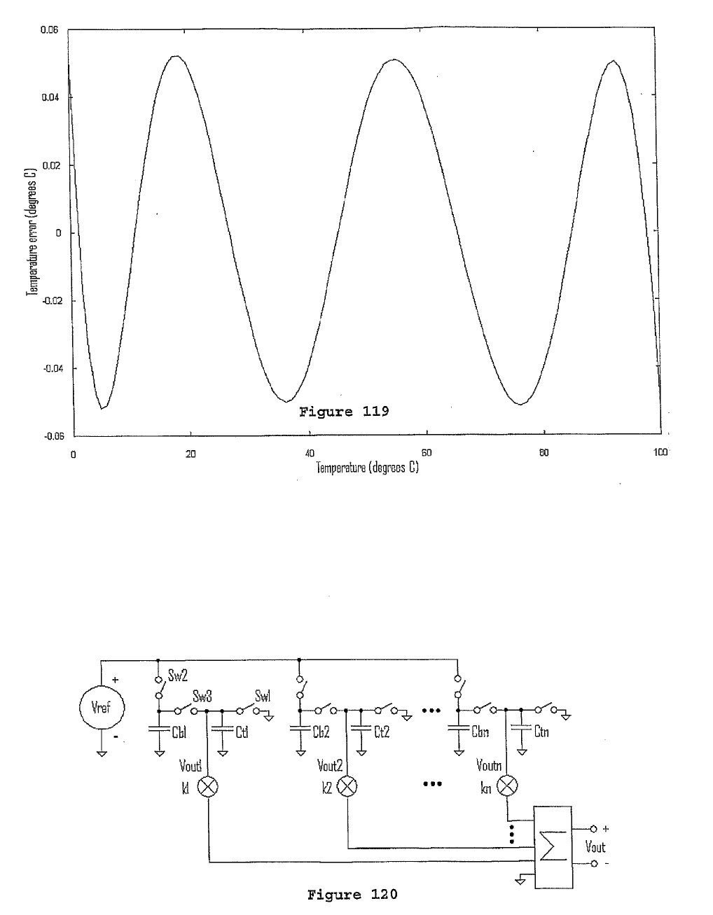

FIG. 118 shows a plot of S (S=Vout) versus thermistor temperature T for an embodiment based on FIG. 117. The input source has three frequency components.

FIG. 119 graphs the temperature error versus temperature T, for an embodiment based on FIG. 117.

FIG. 120 shows an embodiment, based on FIG. 1, that uses multiple capacitive sensors.

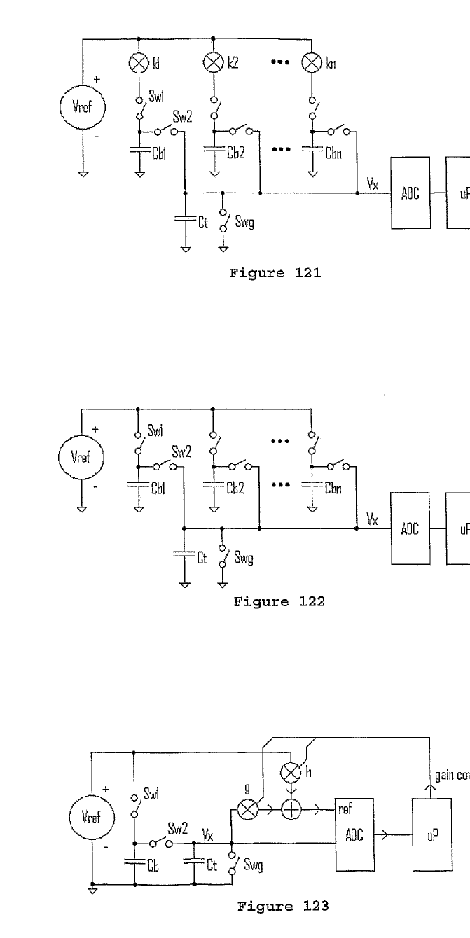

FIG. 121 shows an embodiment derived from FIG. 120 that uses a single capacitive sensor Ct.

FIG. 122 depicts an embodiment derived from FIG. 121 where the uP performs both weighting and summing functions.

FIG. 123 shows an embodiment derived from FIG. 107 that uses a capacitive sensor.

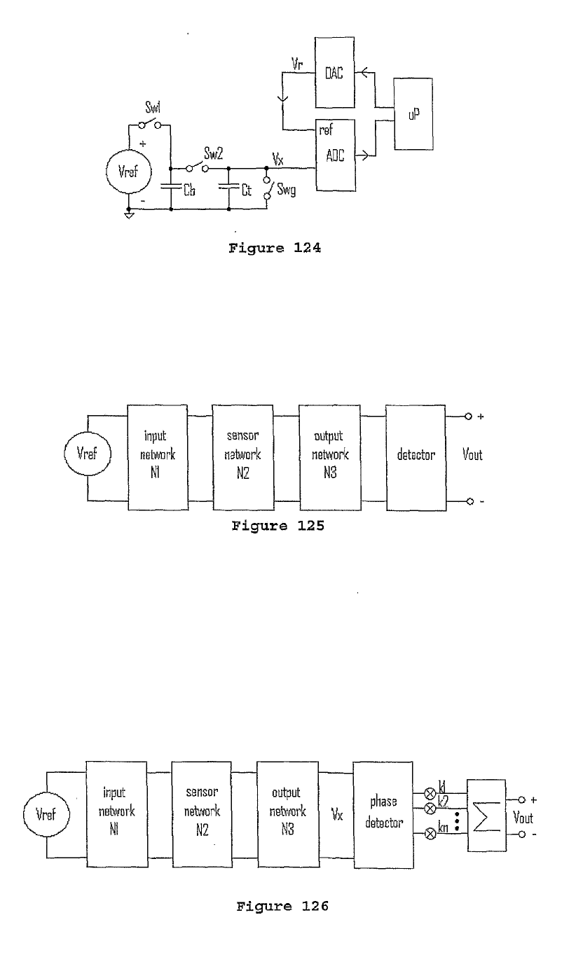

FIG. 124 shows an embodiment based on FIG. 123.

FIG. 125 shows a general scheme for linearizing one or more sensors.

FIG. 126 shows a further scheme derived from FIG. 125.

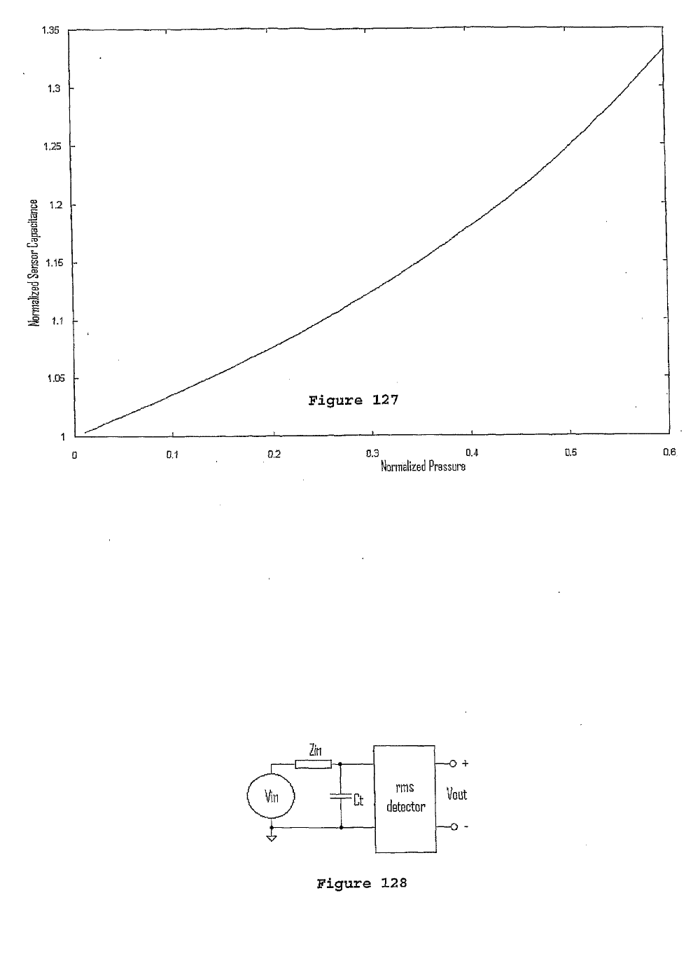

FIG. 127 shows a plot of normalised capacitance Ct/C0 versus normalised pressure P/Pm for a capacitive pressure sensor known in the art.

FIG. 128 show an embodiment, derived from FIG. 125, that uses a capacitive sensor.

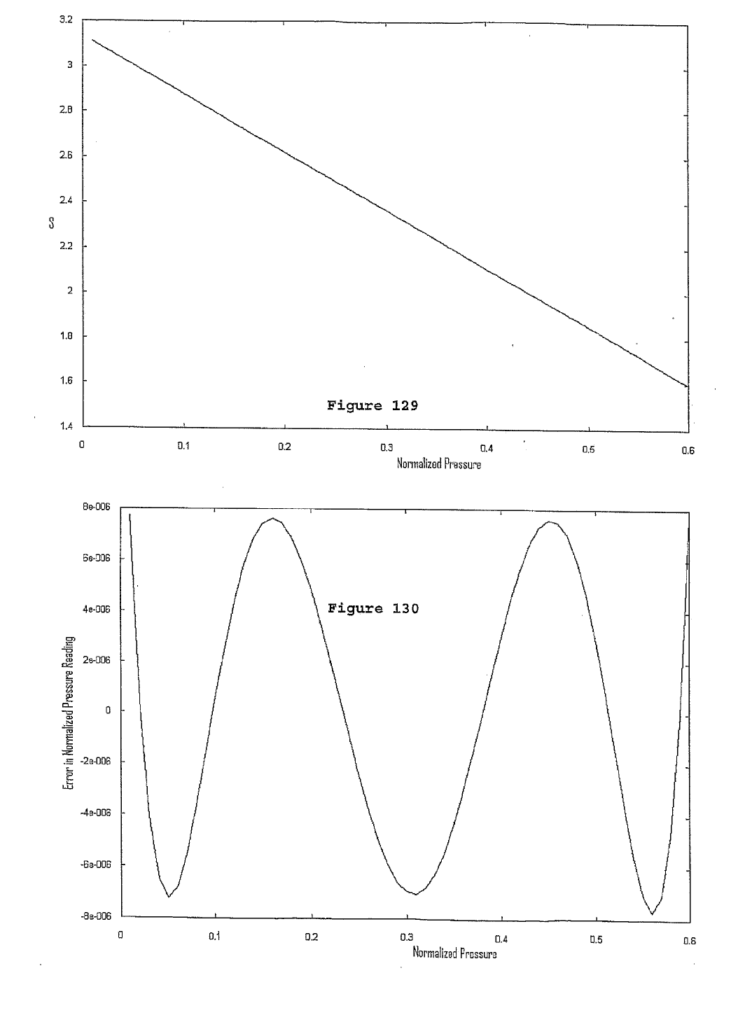

FIG. 129 shows a plot of S (S=Vout/|Vin|) versus normalised pressure x for an embodiment based on FIG. 128.

FIG. 130 graphs the error, xest-x, versus normalized pressure x, for an embodiment based on FIG. 128.

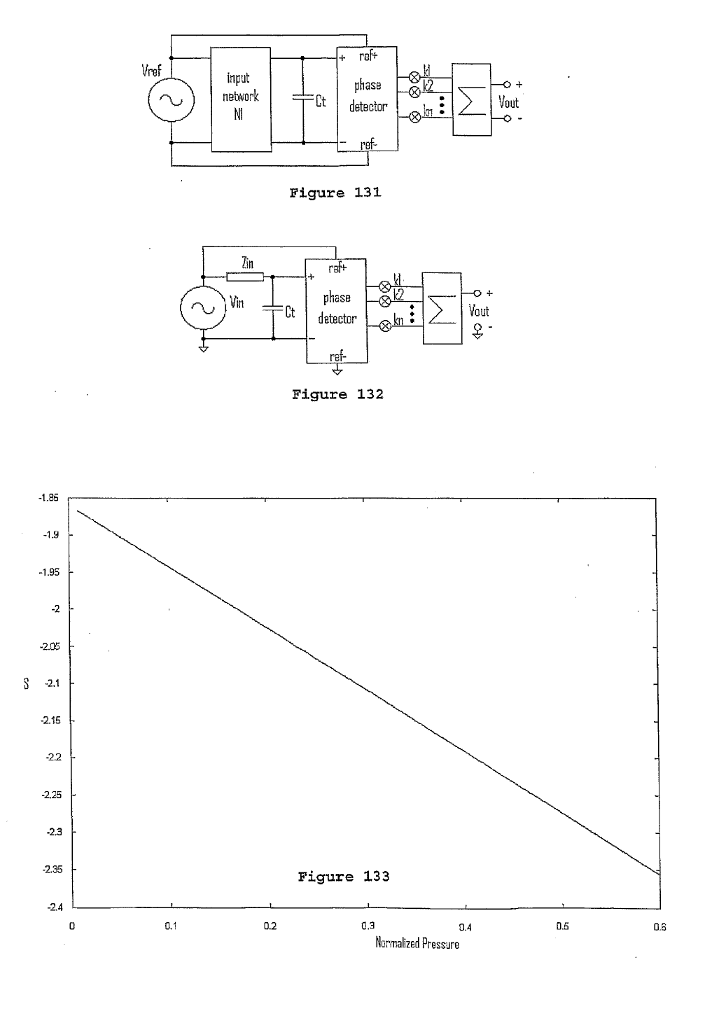

FIGS. 131 and 132 show variations of the embodiment of the invention shown in FIG. 126.

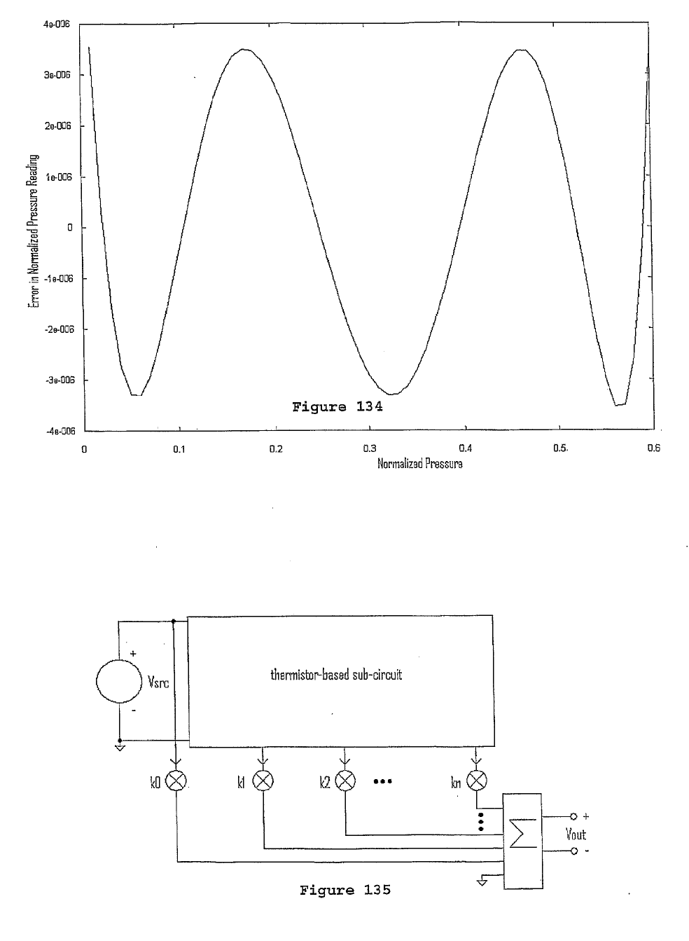

FIG. 133 shows a plot of S (S=Vout) versus normalised pressure x for an embodiment based on FIG. 132.

FIG. 134 graphs the error, xest-x, versus normalized pressure x, for an embodiment based on FIG. 132.

FIG. 135 shows a general method according to the invention for temperature compensating a voltage source.

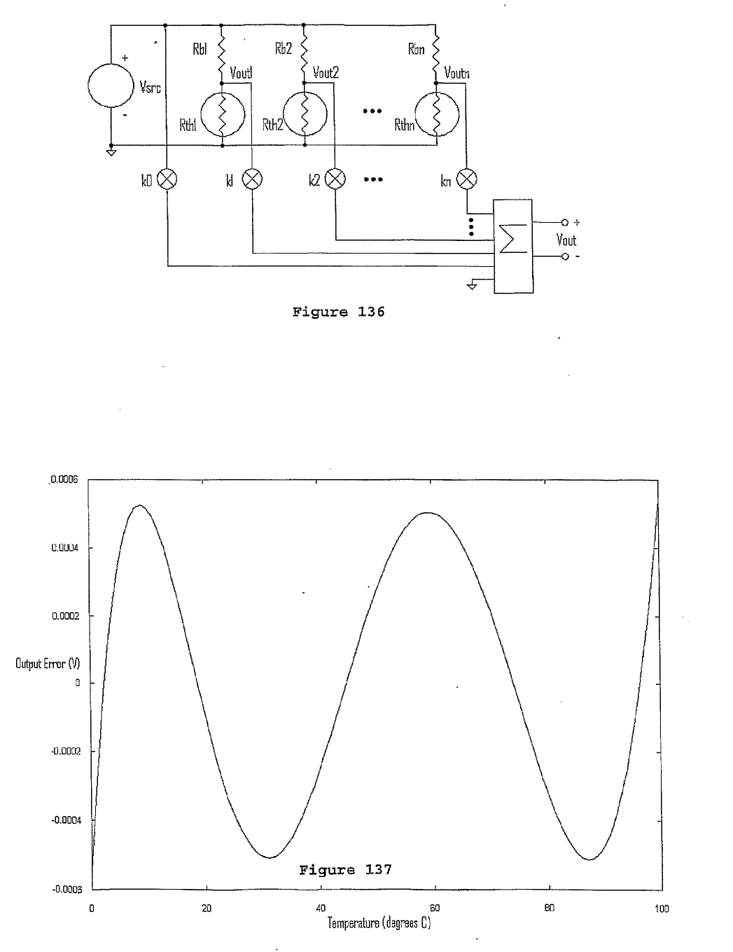

FIG. 136 shows an embodiment derived from FIG. 135. In FIG. 136, signal Vsrc is applied to a thermistor sub-circuit.

FIG. 137 shows a plot of the error in Vout versus temperature, for an embodiment based on FIG. 136.

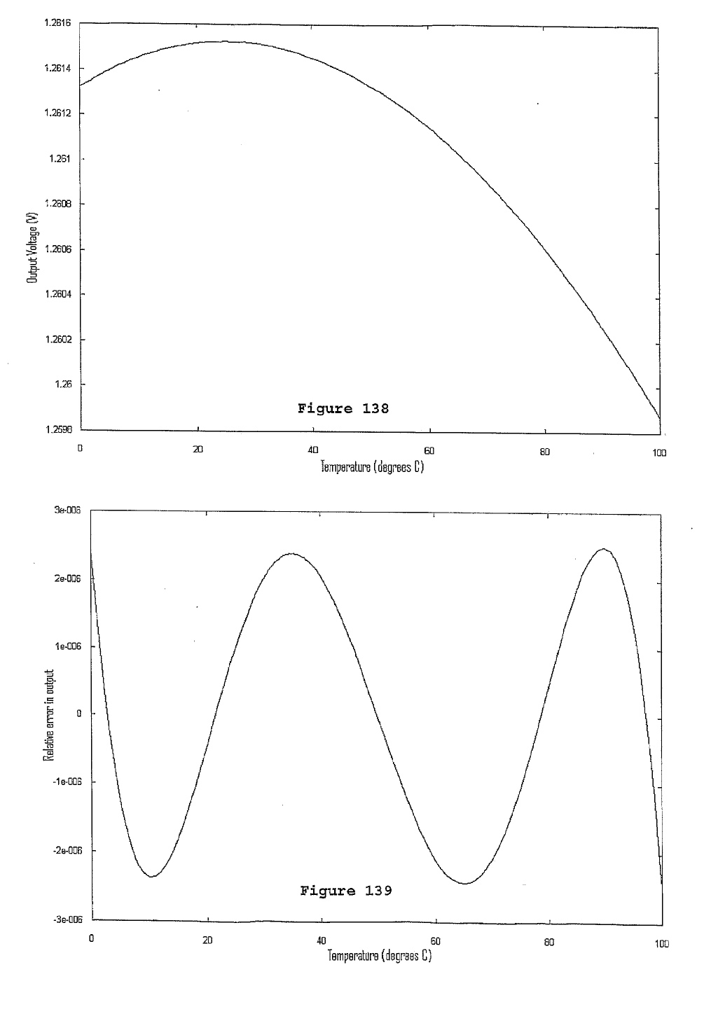

FIG. 138 shows the output voltage Vsrc of a bandgap voltage reference sub-circuit versus temperature.

FIG. 139 shows a plot of relative error in Vout versus temperature, for an embodiment based on FIG. 136, where Vsrc is a bandgap reference as per FIG. 138.

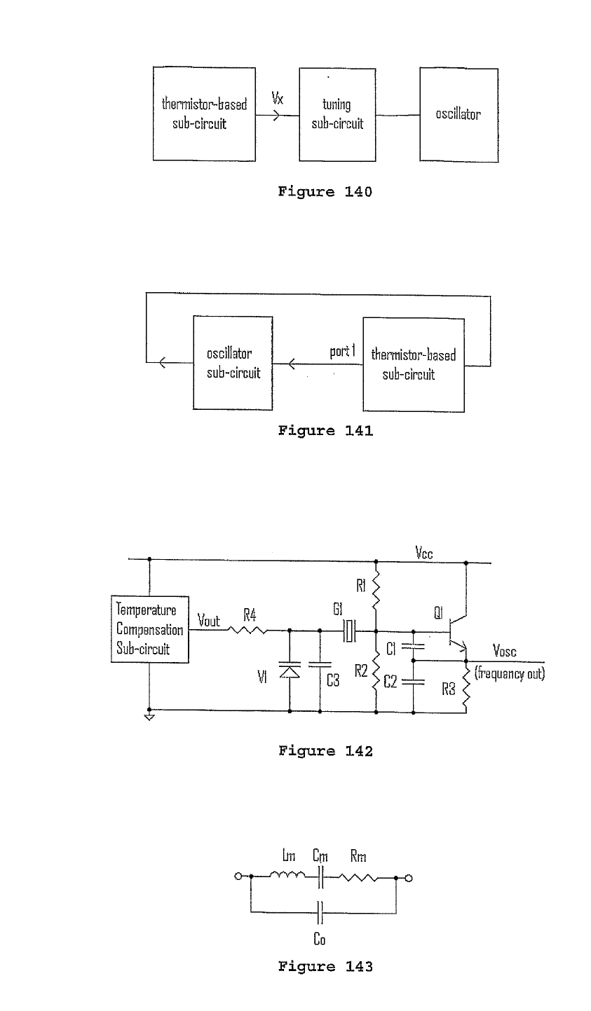

FIG. 140 shows a general method for temperature compensating a frequency source.

FIG. 141 shows another general method for temperature compensating a frequency source.

FIG. 142 shows a prior art oscillator circuit, with a temperature compensating sub-circuit.

FIG. 143 shows a prior art electrical circuit model of a quartz crystal.

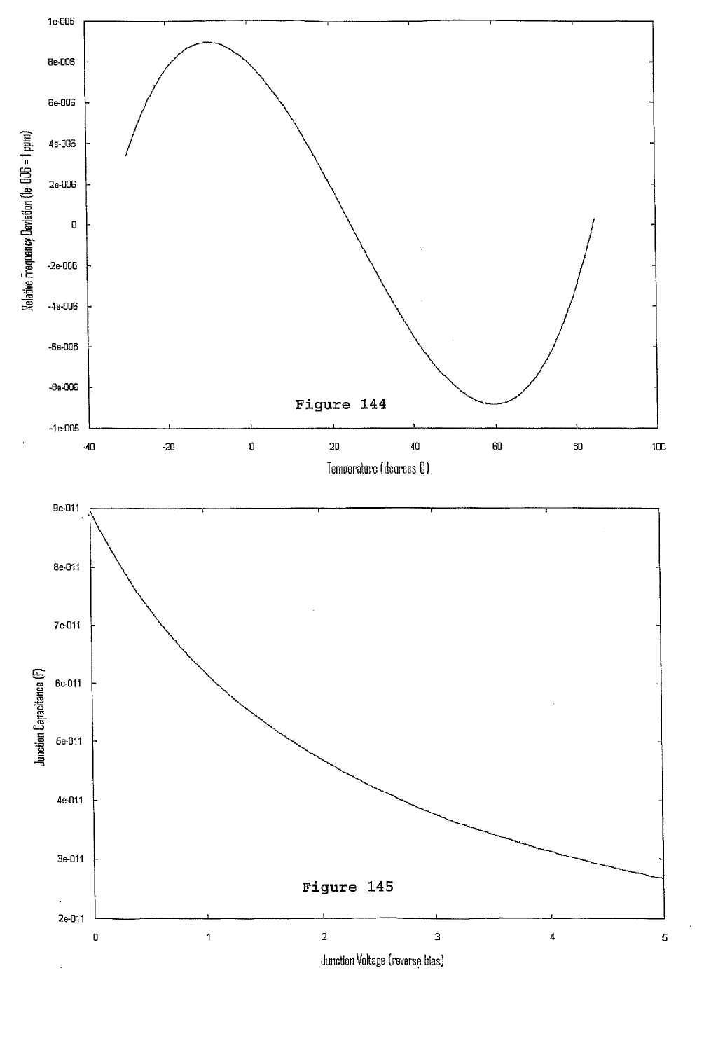

FIG. 144 graphs the variation with temperature of the series resonant frequency of an AT-cut quartz crystal.

FIG. 145 graphs the capacitance versus bias voltage characteristics of a varactor diode.

FIG. 146 graphs desired varactor capacitance versus temperature, for a device as per FIG. 145, when applied to the circuit of FIG. 142.

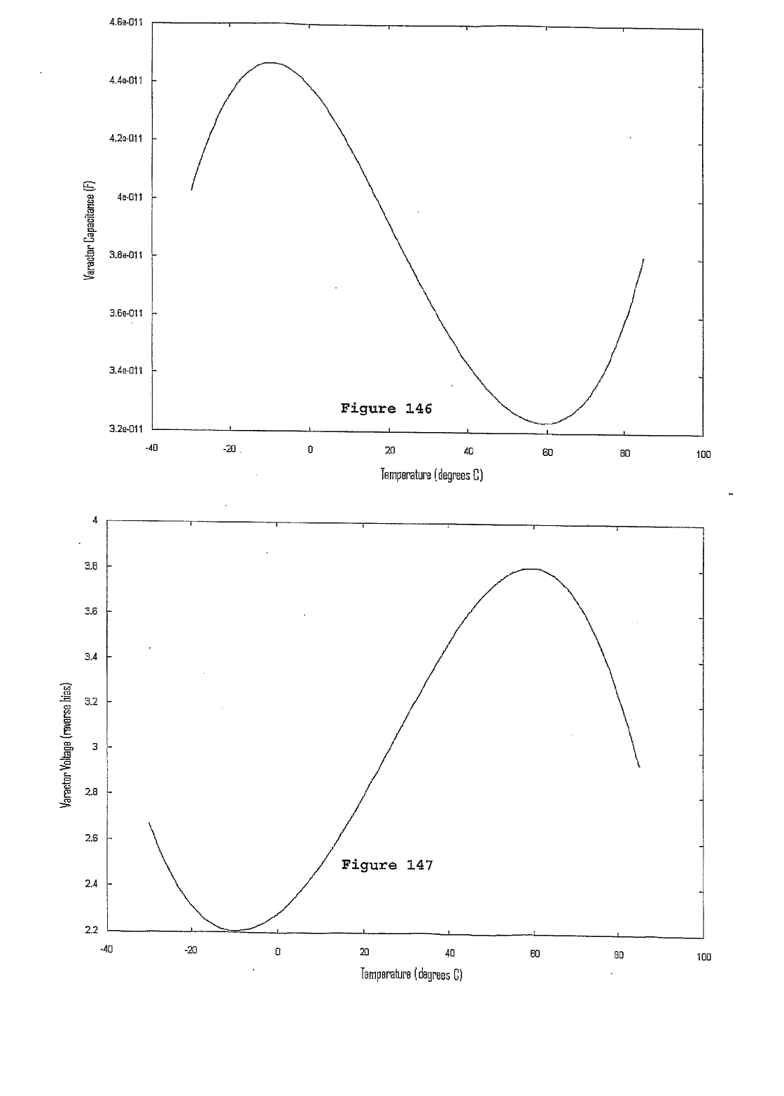

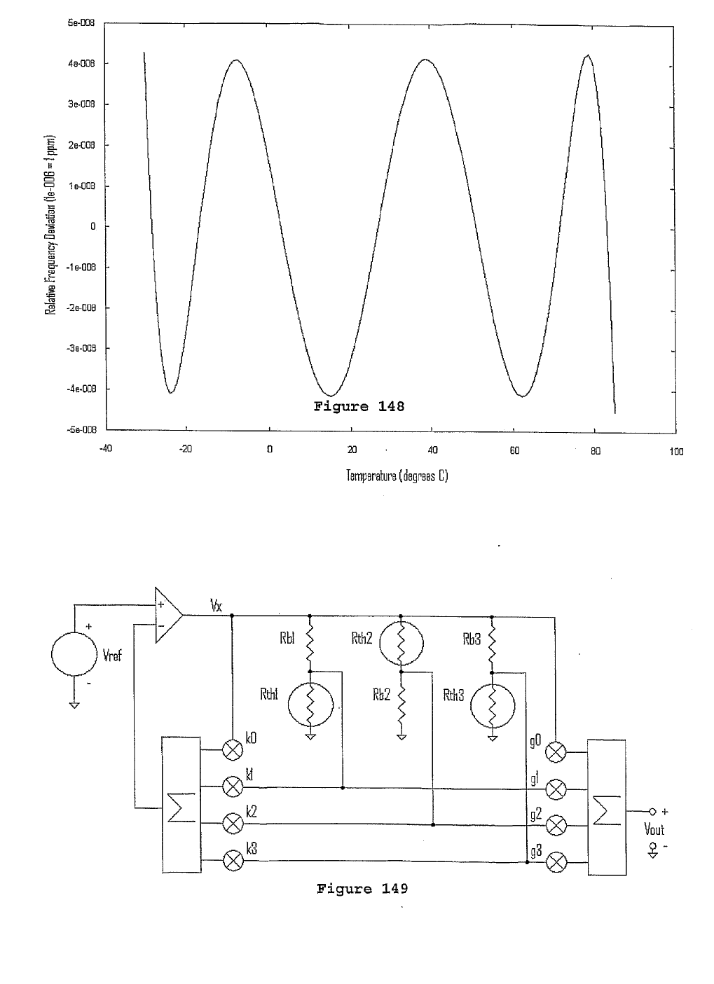

FIG. 147 graphs the varactor voltage, versus temperature, that corresponds to the graph of FIG. 146.

FIG. 148 graphs the relative deviation in output frequency, versus temperature, for an embodiment based on FIGS. 142 and 149.

FIG. 149 shows an embodiment based on FIG. 41.

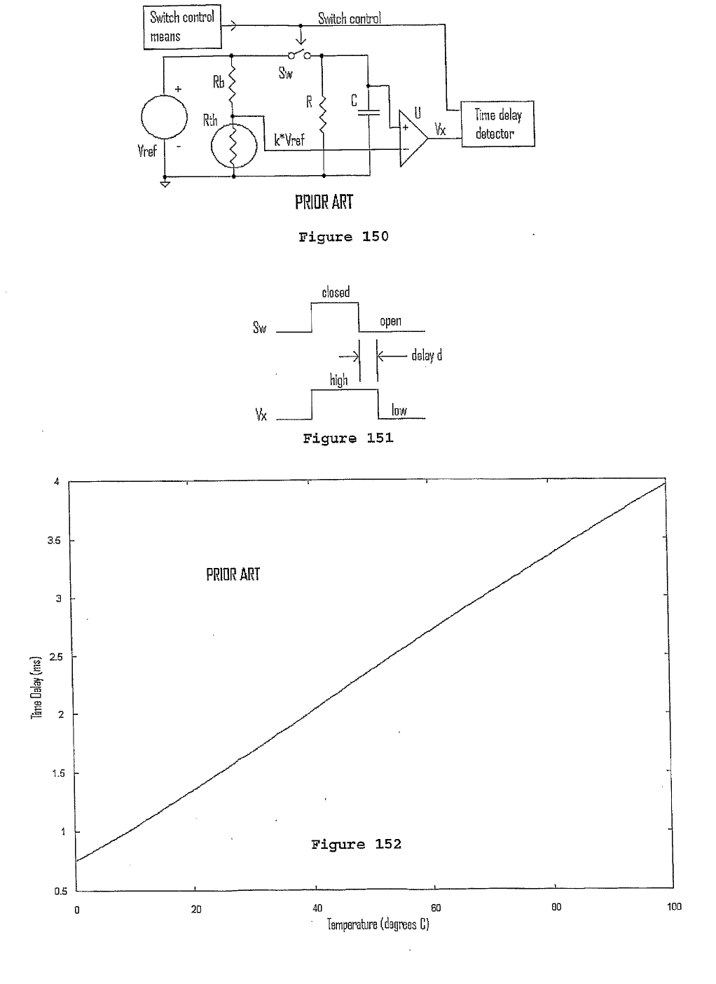

FIG. 150 shows a prior art circuit for generating a time-delayed output where the delay is responsive to temperature.

FIG. 151 shows a timing diagram for FIG. 150.

FIG. 152 graphs the output delay versus temperature for a prior art circuit based on FIG. 150.

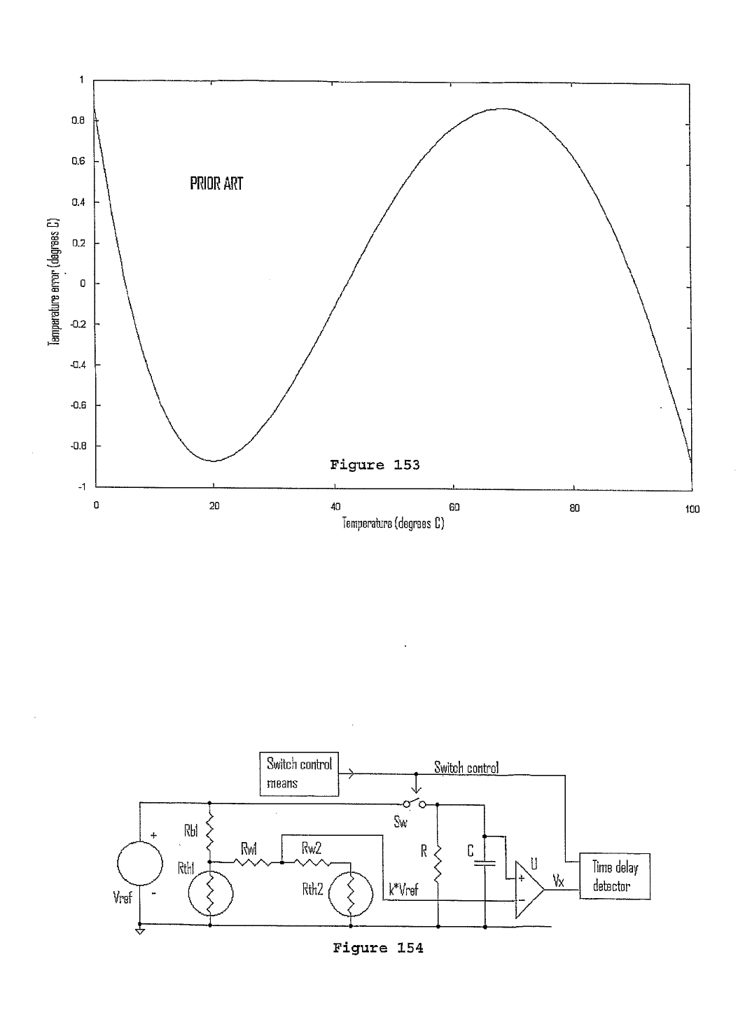

FIG. 153 graphs the temperature error versus temperature for a prior art circuit based on FIG. 150.

FIG. 154 shows an embodiment of the present invention for generating a time-delayed output where the delay is responsive to temperature.

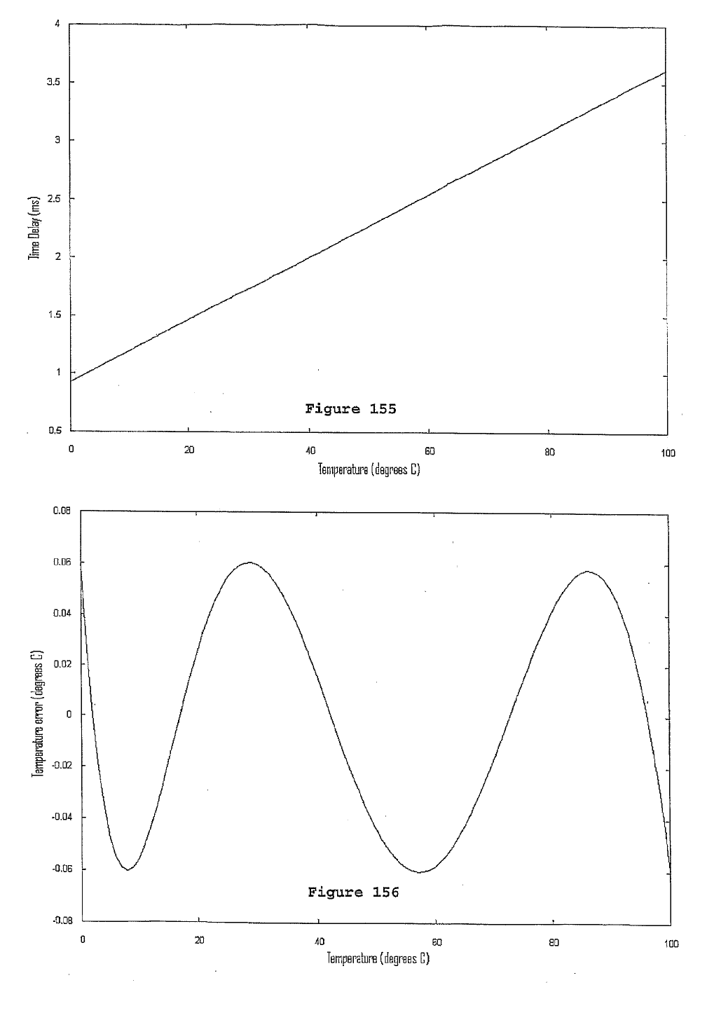

FIG. 155 graphs the output delay versus temperature for an embodiment based on FIG. 154.

FIG. 156 graphs the temperature error versus temperature for an embodiment based on FIG. 154.

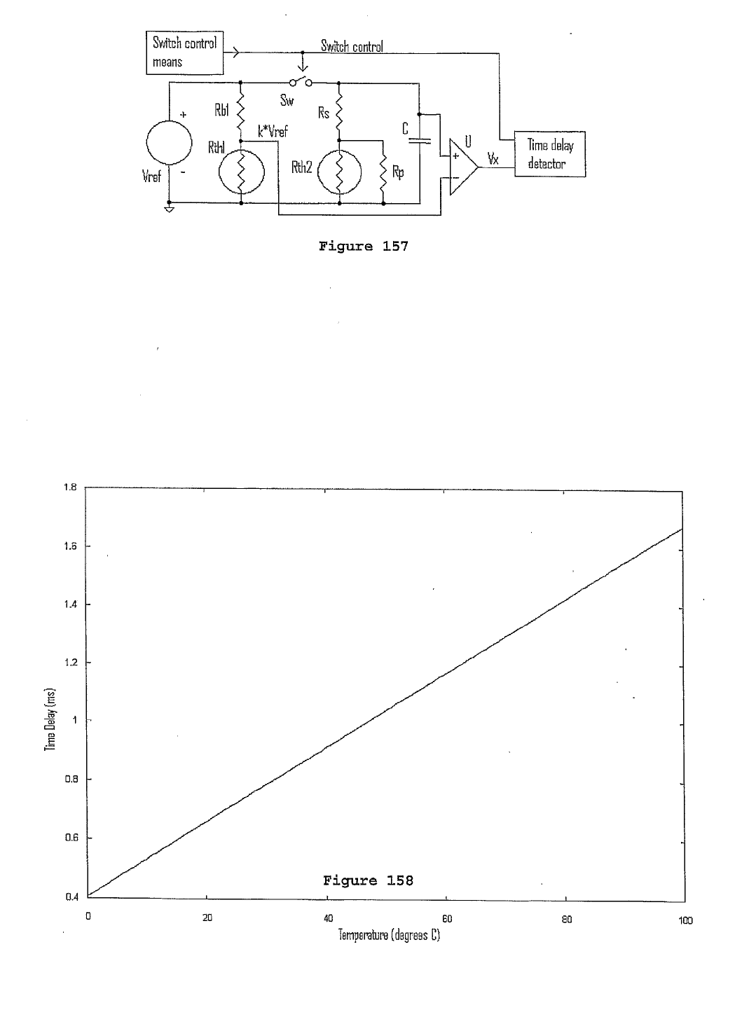

FIG. 157 shows an alternative embodiment derived from FIG. 154.

FIG. 158 graphs the output delay versus temperature for an embodiment based on FIG. 157.

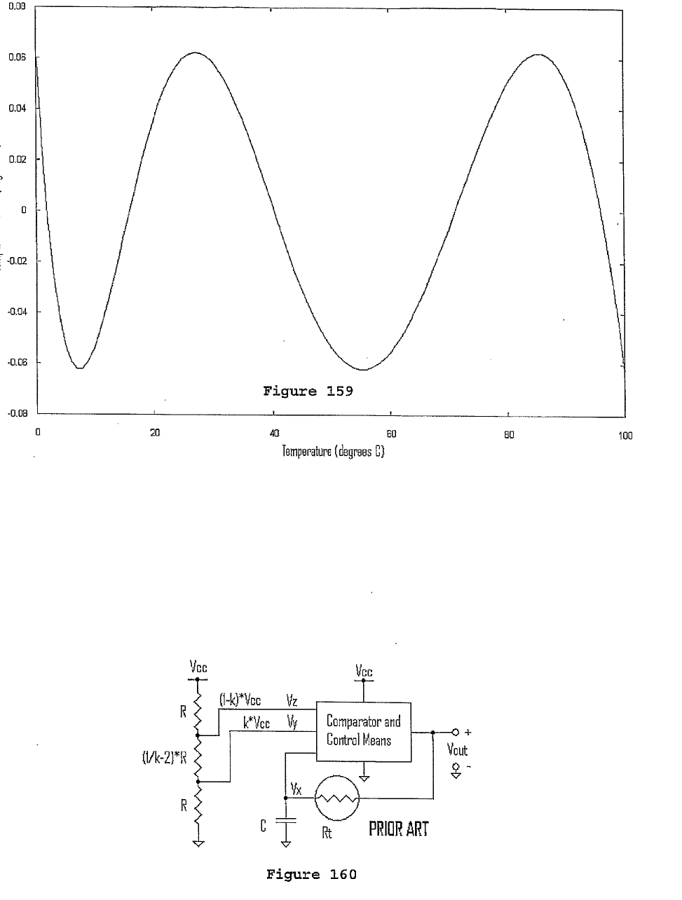

FIG. 159 graphs the temperature error versus temperature for an embodiment based on FIG. 157.

FIG. 160 shows a prior art circuit for generating an oscillating output where the output frequency is responsive to temperature.

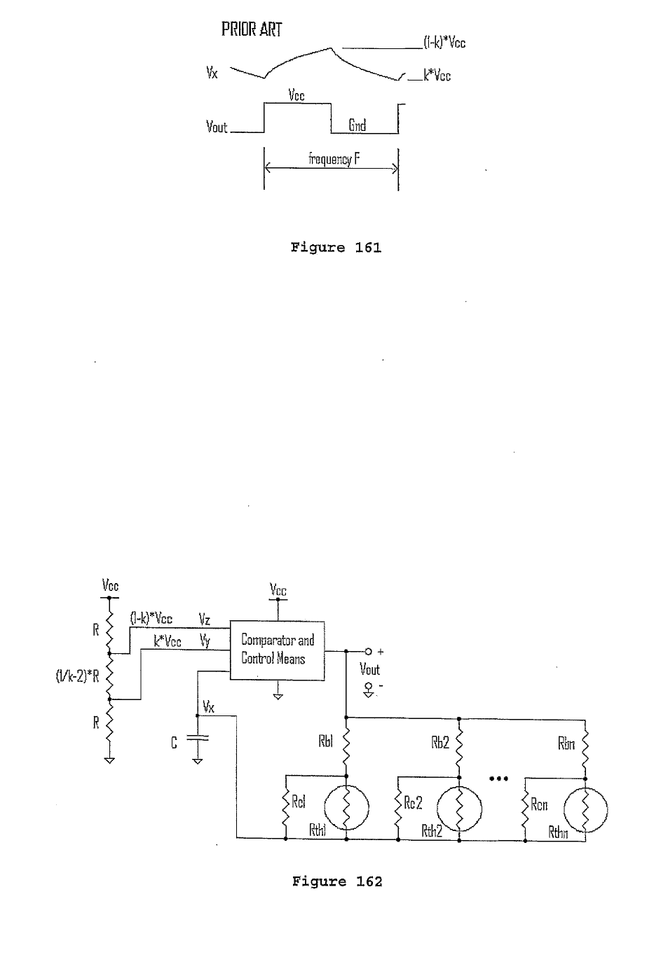

FIG. 161 shows a timing diagram for FIG. 160.

FIG. 162 shows an embodiment of the present invention for generating an oscillating output where the output frequency is responsive to temperature.

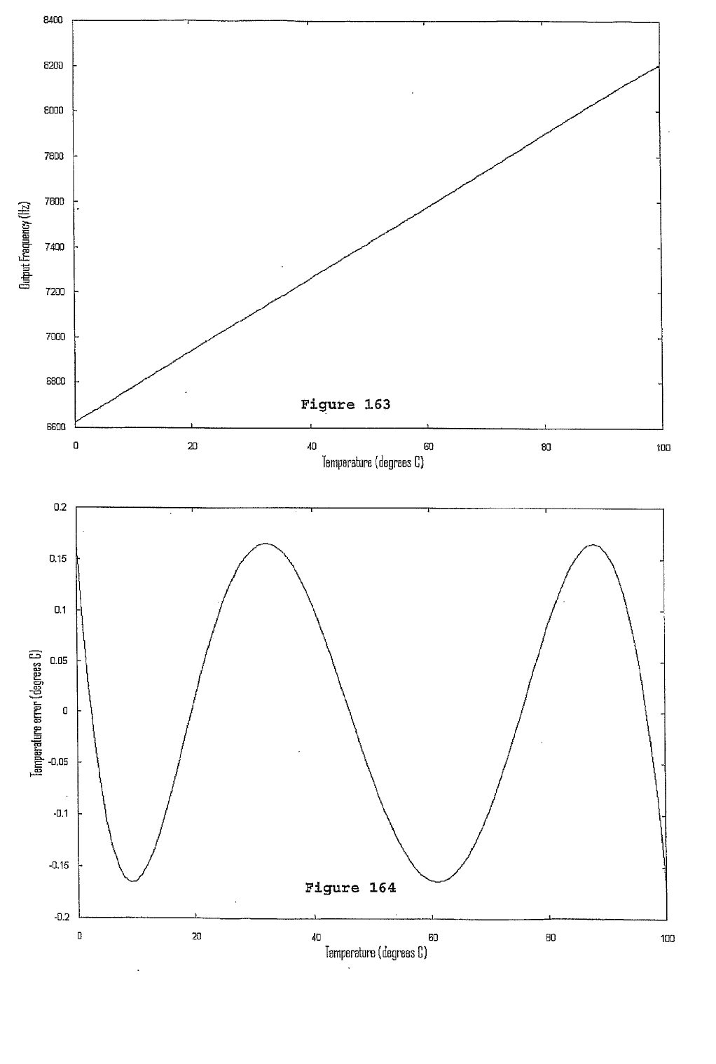

FIG. 163 graphs the output frequency versus temperature for an embodiment based on FIG. 162.

FIG. 164 graphs the temperature error versus temperature for an embodiment based on FIG. 162.

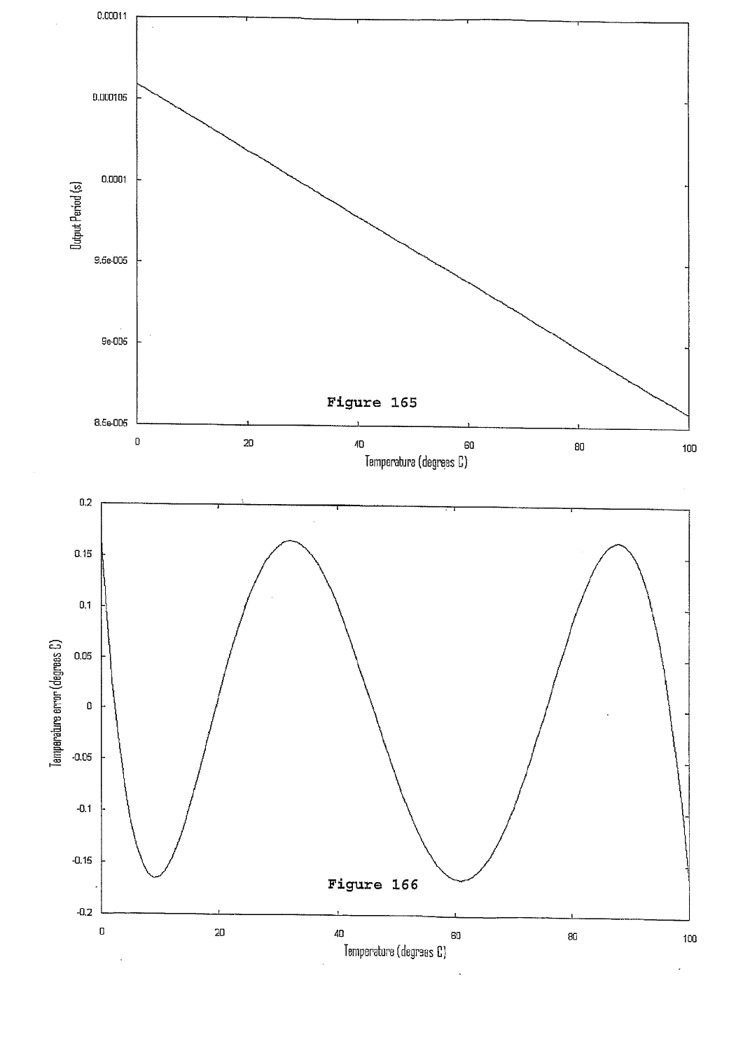

FIG. 165 graphs the output period versus temperature for another embodiment based on FIG. 162.

FIG. 166 graphs the temperature error versus temperature for another embodiment based on FIG. 162.

### DESCRIPTION OF SPECIFIC EMBODIMENTS

### Introduction

In a simple well-known prior art sensor circuit, there is included a resistive temperature sensor in the form of a thermistor, a power source, and a resistor which, in combination with the sensor, forms a voltage divider circuit. The voltage at the junction of the resistor and sensor is a function of the internal resistance of the sensor and the resistor. As the temperature of the sensor changes, the internal resistance of the sensor changes and so the output voltage also changes.

However, the relationship between temperature change and output voltage is not linear. In many applications, one desires a linear (or some other) relationship.

The present invention, in at least some embodiments, achieves the desired linearity by providing an electronic circuit for biasing and interfacing with a sensor such that the sensor's parameters or output signal varies with respect to a physical property P, where the output of the circuit can be expressed as a rational function (the ratio of two polynomials), in terms of the sensor's electrical parameters or output signal, and the rational function is a best or near-best approximation, in a minimax sense, to a linear function of the physical property.

In effect, the circuit performs “sensor linearization”—the circuit takes a signal from a nonlinear sensor and converts it into a signal that is linear (in property P). This will be described in more detail in the ensuing description.

In some other applications, one desires the circuit output to be a non-linear function of the physical property P (e.g. square root, logarithmic, reciprocal, etc). Embodiments of the present invention can also be used in such applications. In some embodiments of the invention, the relationship between physical property P and circuit cannot be expressed as a rational function, but rather as a non-linear (non-rational) function of circuit parameters. In these embodiments, the underlying concept remains the same.

In many applications, a circuit generates a desired output under certain conditions, but the output varies in an unwanted manner as some physical influence on the circuit (e.g. temperature) varies. Therefore, it is desirable to cancel the effects of the unwanted influence.

For example, a circuit may provide a stable, accurate output voltage if the ambient temperature of the circuit lies within a narrow range, say, 20 to 30 degrees Celsius. However, in a given application, the circuit may be subject to ambient temperatures beyond this narrow range, so compensation of the circuit for temperature variations is desired.

Embodiments of the present invention may be used to compensate circuits in a similar manner to the methodology used to linearize sensor outputs. In the subsequent examples, embodiments employing this concept will be described.

### Embodiments Including Thermistors

The present invention, in at least some embodiments, employs an electronic circuit that, in effect, combines several nonlinear functions of temperature to form a substantially linear function of temperature, so that the overall temperature characteristic of the circuit is highly linear.

FIG. 1 shows multiple thermistors Rth1, Rth2, . . . Rthn, each biased by a resistor (Rb1, Rb2, . . . Rbn respectively). The voltage at the junction of each resistor-thermistor combination is given by the general equation:

Vouti=Vref*Rthi/(Rthi+Rbi), i=1 . . . n

In FIG. 1, the circuit multiplies voltages Vouti, i=1 . . . n, by constant factors ki, i=1 . . . n respectively and forms the sum Vout. The circuit effectively varies the voltage ratio Vout/Vref in a linear or substantially linear manner with thermistor temperature.

The voltage ratio Vout/Vref is given by the equation:

Vout/Vref=k1*Vout1/Vref+k2*Vout2/Vref+ . . . +kn*Voutn/Vref

Let:

S=Vout/Vref

Let:

Si=Vouti/Vref, for i=1 . . . n

So that:

S=k1*S1+k2*S2+ . . . +kn*Sn=k1*Rth1(Rb1+Rth1)+k2*Rth2/(Rb2+Rth2)+ . . . +kn*Rtbn/(Rbn+Rthn)

The ratio S depends on temperature and equals a weighted sum of ratios, namely S1, S2, . . . Sn, that depend on temperature.

S is a transfer function of the circuit. A plot of the ratio S against thermistor temperature T, calculated over the range 0 to 100 degrees Celsius (C), is given at FIG. 2. The plot is taken from the circuit of FIG. 1, when the circuit has two thermistors (that is, n=2) and the circuit components have the following values:
two identical thermistors, type YSI 45008
Rb1=2.1272E+3
k1=6.22617E−1
Rb2=5.14029E+4
k2=3.77383E−1

In the calculations for FIGS. 1 and 2, the thermistor resistance is given by the following Steinhart-Hart equation:

1/T=A+B*(ln(R))+C*(ln(R))̂3

where:
T=temperature in Kelvin (K)
R=thermistor resistance, Ohms
A=0.000940952
B=0.000220124
C=1.31269E−07

In the above equation, the reciprocal of temperature is given by a polynomial in terms of ln(R). If necessary, as is known in the art, additional terms, such as a second-order term, may be used in the polynomial to improve its accuracy.

In FIG. 2, S is approximately given by the following linear relationship:

S=m*T+c

where m=−5.33875E−03/K,
c=8.54522E−01

Using this approximate relationship, the temperature Test estimated by the circuit's transfer function S can be written as:

Test=(S−c)/m

The error in this estimate—in other words, the linearity error—is given by Test-T. FIG. 3 graphs the calculated temperature error Test-T versus temperature T. Over the range 0-100 C, the peak error is approximately 168 mK.

FIG. 4 depicts a calculated plot of S versus thermistor temperature T for the circuit of FIG. 1, when it has three identical thermistors (n=3) and the following circuit values:
Thermistor type YSI 45008
Rb1=9.57E+02
k1=5.19359E−01
Rb2=1.16211E+04
k2=2.38695E−01
Rb3=1.242754E+05
k3=2.41946E−01

In FIG. 4, S is approximately given by the following linear relationship:

S=m*T+c,

where m=−4.36474E−03/K,
c=8.31527E−01

Using this approximate relationship and rearranging the equation above gives the thermistor temperature Test estimated by the circuit's transfer function S:

Test=(S−c)/m

FIG. 5 graphs the calculated error, namely Test-T, versus temperature T. Over the range 0-100 C, the peak error is approximately 9 mK.

The two examples above demonstrate that by employing multiple thermistors, the circuit of FIG. 1 can produce near-linear temperature characteristics. The linearity of the circuit may be further improved by employing more thermistors. Furthermore, in these examples, the linear temperature characteristics are produced by using identical thermistors.

From the examples given above, and in particular, when examining the error curves in FIGS. 3 and 5, it can be seen that linearity is improved where circuit values and parameters are selected so that the error curve for the circuit has the following characteristics:
for a circuit with n thermistors, the error curve has a total of at least 2*n+2 maxima and minima;
the maxima and minima of the error curve have equal or substantially equal absolute magnitudes and have opposite sign;
the error curve alternates in value, from a maximum to a minimum to a maximum, etc.

The error curve in FIG. 3, for example, applies to a two-thermistor circuit. FIG. 3 has a total of 2*2+2=6 maxima and minima, as desired. The maxima and minima have near-equal absolute magnitudes but opposite signs, and alternate. In other words, as temperature T increases, the error curve alternates. In FIG. 3, the error curve has 6 alternations.

Similarly, the error curve in FIG. 5 applies to a circuit with 3 thermistors, and has 8 alternations. Furthermore, as the number of thermistors in the circuit is increased, the error is decreased and the linearity is also correspondingly increased.

Generalising from the specific examples, it may be seen that if the error curve has 2*n+2 alternations, then it has 2*n+1 roots. Therefore, in a circuit according to some embodiments of the invention, the circuit parameters can be selected to locate each root so that the maxima and minima have the same absolute magnitude.

However, to have independent control over each root requires at least 2*n+1 degrees of freedom in the choice of circuit parameters.

This may be achieved by providing an additional 2 degrees of freedom for each thermistor added to a circuit.

Returning to FIG. 1, with n thermistors, n degrees of freedom arise from the use of n resistors Rb1, Rb2, . . . Rbn, and another n degrees of freedom arise from the k factors k1, k2, . . . kn.

Two additional degrees of freedom arise in the choice of m and c (namely scale factor and offset) in the overall temperature characteristic.

In other words, the circuit of FIG. 1 provides the necessary degrees of freedom, of at least 2*n+1.

Comparison with a Prior Art Circuit

The principle outlined above is best illustrated by comparing a prior art circuit with a circuit in accordance with an embodiment of the present invention.

FIG. 6 shows a prior art circuit. The thermistors in FIG. 6 have the following values:
Rth1=thermistor T2 of YSI part number 44018;
Rtb2=thermistor T1 of YSI part number 44018;
Rb1=5700 ohms;
Rb2=12000 ohms.

This circuit corresponds to the voltage-mode circuit recommended by the manufacturer when utilising the YSI Thermilinear® component 44018, for the temperature range −5 C to +45 C.

FIG. 7 shows a calculated plot of S (S=Vout/Vref) versus T for the prior art circuit of FIG. 6 with these values.

In FIG. 7, S is approximately given by the following linear relationship:

S=m*T+c,

where m=−5.6846E−03/K,
c=8.05858E−01

The values for m and c are those specified by the manufacturer. Rearranging the equation gives the thermistor temperature Test estimated by the prior art circuit:

Test=(S−c)/m

The error in this estimate equals Test-T. FIG. 8 graphs the calculated temperature error versus temperature T. Over the range −5 C to 45 C, the peak error is approximately 65 mK. The error curve for the prior art circuit has a total of 5 minima and maxima, and 4 roots.

This may be compared with an embodiment of the invention as shown in FIG. 9, using the same thermistors. FIG. 10 shows a calculated plot of S versus T when the circuit of FIG. 9 has the following values:
Rth1=thermistor T1 of YSI part number 44018;
Rth2=thermistor T2 of YSI part number 44018;
Rb1=1.5149E+03;
Rw1=4.87397E+04;
Rw2=8.43383E+04.

In FIG. 10, S is approximately given by the following linear relationship:

S=m*T+c,

where m=−6.78784E−03/K,
c=7.25287E−01

Rearranging the equation gives the thermistor temperature Test estimated by the circuit:

Test=(S−c)/m

The error in this estimate equals Test-T. FIG. 11 graphs the calculated temperature error versus temperature T. Over the range −5 to 45 C, the peak error is approximately 12 mK. The error curve in FIG. 11 has a total of 6 maxima and minima; it also has 5 roots, one more than in FIG. 8 (prior art). The extra root in the error curve of FIG. 11 makes possible a reduction in the error across the temperature range, providing approximately five times better linearity than the prior art circuit.

Note that the embodiment of FIG. 9, discussed above, uses thermistors that have substantially different characteristics.

As demonstrated, some embodiments may be considered to provide a circuit which, in effect, forms a weighted sum of several functions of temperature. The functions are combined so that the circuit's overall temperature characteristic is highly linear. This is referred to as the weighted summing technique.

Another way of regarding at least some embodiments of the invention is described below.

In FIG. 1, the ratio S=Vout/Vref is given by the following equations:

$$\begin{matrix}S = k 1 * S 1 + k 2 * S 2 + … + kn * Sn \\ = k 1 * Rth 1 / ( Rb 1 + Rth 1 ) + k 2 * Rth 2 / ( Rb 2 + Rth 2 ) \\ + … + kn * Rthn / ( Rbn + Rthn )\end{matrix}$$

If the thermistors are identical, then:

Rth1=Rth2= . . . =Rthn=R

where R is a function of temperature. This simplifies the equation for S to:

S=k1*R/(Rb1+R)+k2*R/(Rb2+R)+ . . . +kn*R/(Rbn+R)

S can be expressed as the ratio of two polynomials in R:

S=P(R)/Q(R)

where P(R) and Q(R) have degree n. For example, for n=2, we have:

P(R)=(Rb1*k2+Rb2*k1)*R+(k1+k2)*R̂2

Q(R)=Rb1*Rb2+(Rb1+Rb2)*R+R̂2

The various circuit parameters Rb1, k1, Rb2, k2, etc are ideally selected so that S is approximately linear with temperature T. That is:

P(R)/Q(R)=c+m*T

for some constants c and m.

Temperature T can be regarded as a function of thermistor resistance, say f(R). Substituting, we have:

P(R)/Q(R)=c+m*f(R).

The right-hand side of the preceding equation is a non-linear function of thermistor resistance R; the left-hand side is a rational function (the ratio of two polynomials) in R. The problem of approximating a non-linear function by a rational function is known as rational approximation. The rational function P(R)/Q(R) has a numerator of degree n and a denominator of degree n. For many non-linear functions, the rational function of numerator degree n and denominator degree n which best approximates the non-linear function in a “minimax” sense has a particular property, namely that the approximation error in the rational function has at least 2*n+2 alternations.

In other words, where identical or near-identical thermistors are used, the n-thermistor circuit should be designed so that the error curve has at least 2*n+2 alternations. This design principle, referred to hereafter as the 2*n+2 alternation principle, also applies when the circuit's thermistors are not identical, as in the example of FIG. 9 discussed above.

In other words, for a circuit with the properties of FIG. 1, (that is, with n thermistors), appropriate design parameters may be chosen so that the circuit's output:
can be expressed as a rational function of the thermistor resistances;
varies in a highly linear manner with temperature; and
has an error curve with at least 2*n+2 alternations.

Designing a circuit in this manner allows the use of thermistors that have substantially similar temperature characteristics, or thermistors that have substantially different temperature characteristics, or a combination thereof.

It will be understood that there exist a large number of circuits that can embody the principles outlined above. It will be understood that the principles outlined above may be applied to many types of sensors other than thermistors.

The choosing of values of components and circuit parameters may also be approached as an optimization problem, where the objective is to minimise the error (“approximation error”) between a transfer function of the circuit and a desired mathematical relationship.

The transfer function is the relationship between an input and an output of the circuit, under the influence of a physical property P that influences the sensor or sensors employed in the circuit. The approximation error may be minimised over a desired range of values of the physical property P.

It is possible to optimize the transfer function, and thereby optimize the values of circuit components and circuit parameters, by using numerical optimization methods that are known in the art.

One such method is the Remez exchange algorithm, also known as the Remez Second Exchange algorithm, which is commonly used to optimize a rational function so that it approximates a second function in a minimax sense. The Remez First Exchange algorithm may also be used. Another suitable optimization method is the Nelder-Mead simplex algorithm.

In the examples described above, the approximation error—that is, the difference between the transfer function and the desired mathematical relationship—is optimized in a minimax sense. In other words, the nominal transfer function is chosen so that the maximum absolute approximation error is at a minimum or near-minimum. The detailed description in this document concentrates on embodiments of this type.

Many other methods of optimizing the approximation error are possible. The best method depends on the particular application. For instance, the nominal transfer function may be chosen so that the approximation error is optimized in a least squares sense. Alternatively, the weighted absolute value of the relative error in the output may be optimized in a minimax sense. These and other alternatives will be apparent to those skilled in the art.

In at least some embodiments, the approximation error over a certain range (“primary range”) of values, of sensed physical property P, may be of highest importance; outside that range, the approximation error of the circuit may have significantly less importance. The detailed description in this document concentrates on embodiments of this type.

In such cases, it is advantageous to locate the roots of the error curve, via suitable choice of circuit parameters, so that the roots lie within the primary range of interest. This reduces the approximation error within the primary range. In FIG. 3, for example, all five roots of the error curve are located within the temperature range 0 to 100 C.

In the examples described above, the desired mathematical relationship between the physical property and the output is a linear variation in the output as the physical property changes.

Many other mathematical relationships are possible, and are desirable in certain applications. For example, the output may be a logarithmic function of the physical property, or the square root of the physical property; or the reciprocal of the output may be a linear function of the physical property. These minor variations and alternatives will be apparent to those skilled in the art.

The desired mathematical relationship may be defined via various methods known in the art.

For example, the relationship may be defined symbolically, in the form of an equation or set of equations.

As a second example, the relationship may be defined as a curve of best fit, to a set of data. The relationship may be a function that interpolates the data. The data may come from measurements taken on a physical system (empirical data), or from the results of numerical simulation, or from a combination of empirical and simulated data.

These and other methods will be apparent to those skilled in the art.

In some cases, the manner in which a sensor is energised can affect the sensor's characteristics. A thermistor, for example, can be subject to self-heating, as is well-known in the art. If great enough, the self-heating induced by the excitation current can cause a thermistor to have a temperature that differs significantly from the environmental temperature that it is intended to sense.

Those skilled in the art will be familiar with many techniques to reduce such effects to negligible levels, while preserving the essential characteristics of the circuit at hand.

For example, in the case of self-heating effects in a thermistor sub-circuit, one such technique is to reduce the supply voltages and other energising sources in the thermistor sub-circuit by appropriate factors, and then increase the sub-circuit's output by a compensating gain factor (e.g. via an amplifier).

A second such technique is to energise the sub-circuit only for short periods of time, at given intervals, thereby limiting any temperature rise in the circuit's components. Still other techniques involve changes to the physical mounting or packaging of sensors.

In some applications, some components in the circuit, other than the sensors, may respond to a physical property P. For example, a thermistor-based embodiment of the invention, where a property P is temperature, may use fixed-value resistors and capacitors that have small but non-zero temperature coefficients.

A resistor, for example, may have a temperature coefficient of 100 parts per million, or 0.0001 percent, per degree C. By contrast, a thermistor's resistance may change by a few percent per degree C.

In many embodiments, these effects are negligible. However, if desired, these small effects can be accommodated by embodiments of the invention. Using optimization algorithms, such as the Nelder-Mead simplex algorithm, it is possible to include these effects in the algorithm's model of the sensor sub-circuit.

These component effects become part of the characteristics that the embodiment linearizes or compensates. By including these effects, it is possible to further improve the linearity of the output by compensating for such undesirable effects.

In some embodiments, the essential character of a circuit is best described via a transfer function, that is, the relationship between an input and an output of the circuit or portion of the circuit.

FIG. 1, for example, can be characterized by the transfer function S, S=Vout/Vin. A change in amplitude of Vin, for example, affects Vout, but does not affect the linearity of the circuit.

The embodiment of FIG. 55, to give another example, is best characterized by an impedance function (the ratio Vref/Iout) of a one-port network.

More generally, some embodiments use a ratiometric technique, where the output equals the ratio of two quantities, such as circuit voltages, currents, or impedances. In these cases, again, the essential character of the circuit, for the purposes of carrying out the invention, is best described via a transfer function.

In some other embodiments, the output is independent or substantially independent of input signals. Some examples include circuits that output a constant or substantially constant signal, such as a reference voltage or a reference frequency. Mathematically speaking, in these cases, one can still define the output in terms of a transfer function, where the function uses an arbitrary input.

In connection with these latter cases, the terms “transfer function” and “output function” can be used interchangeably, to denote a function, in terms of circuit parameters and values, which characterizes the output.

Returning to the examples of FIGS. 9 to 11, FIG. 11 has five roots and FIG. 9 has three degrees of freedom in the selection of resistances Rb1, Rw1, and Rw2. Two further degrees of freedom come from the choice of slope m and offset c in the output characteristic.

The circuit of FIG. 9 has the minimum number of degrees of freedom in its non-sensor circuit values (resistance values), namely 2*n−1, to satisfy the 2*n+2 alternation principle, malting it a particularly economical embodiment of the invention.

In some applications, it is possible to gain practical advantages, such as low component count, cost, and space, by using embodiments that have the minimum number of degrees of freedom in its non-sensor circuit and component values.

We now describe one method of calculating suitable component values for the circuit of FIG. 9 so that it substantially provides a linear output in a minimax sense, when using thermistors of type YSI 45008, over the temperature range 0 to 100 degrees C.

In some embodiments, the desired transfer or output function is known beforehand. In these cases, it is straightforward for those skilled in the art to derive component values, using optimization algorithms known in the art.

However, in the case of FIG. 9, the values of slope m and offset c in the desired linear relationship must be optimized, so generally they cannot be specified explicitly beforehand. One way to proceed is as follows:
(1) Express the circuit's transfer function S, S Vout/Vin, in terms of circuit values and component parameters.
(2) Use Steinhart-Hart equations with suitable coefficients to relate each thermistor's temperature to its resistance. The coefficients may come from the device manufacturer or from measurement data.
(3) From an initial starting point for vector x, use the Nelder-Mead simplex algorithm to minimise the following objective function F, for p=2:

F(x,p)=1/|a|*sum(|(S(|x|,T)−fit(S(|x|,T)))|̂p)̂(1/p)
where:
x is a vector of circuit and component values to be optimized, in this case [Rb1,Rw1,Rw2];
T is a suitably large vector of thermistor temperature values, in this case [0, 1, 2, . . . , 100] degrees C.;
S(x,T) is a vector of the circuit's transfer function values, evaluated at T;
fit(S) is the straight line of best fit to S in a least squares sense: fit(S)=a*T+b, for some a and b;
∥ denotes absolute value;
sum(v) equals the sum of elements in vector v.

In words, step (3) involves finding component values so that the difference, between transfer function S(|x|) and the linear temperature function that best fits S(|x|), is small.

In step (3), the right-hand-side expression for F is divided by |a|, a being the slope of the most recent line of best fit. This is to force the algorithm away from an unwanted solution in which the slope is zero or near zero.

Also in step (3), the expression for F uses |x| rather than x. This forces the circuit's resistance values to equal or exceed zero, which is necessary in this case.
(4) Calculate the error function S(|x|,T)−fit(S). Check that this function has at least 2*n+1 roots (in this case 5 roots), and has maxima and minima of alternating sign. If not, then return to step (3), using the current solution x as the starting point.
(5) Starting with the most recent solution x from step (4), repeat steps 3 and 4, but in step 3 use p=4.
(6) Starting with the most recent solution x from step (5), repeat steps 3 and 4, but in step 3 use p=8.
(7) Starting with the most recent solution x from step (6), repeat steps 3 and 4, except in step 3 use p=16.
(8) Using the most recent solution x from step (7), calculate the line of best fit to S(|x|,T) in a minimax sense. Check that the approximation error in S(|x|,T), to this line, satisfies or substantially satisfies the 2*n+2 alternation principle.

The solution to the problem comprises the final value of |x|, plus the slope and offset parameters of the minimax line of best fit, from step (8).

The sequence of values p=2, 4, 8, 16 encourages the algorithm to minimize the absolute maximum error; the higher the value of p, the stronger the encouragement.

Often it is possible to estimate a suitable starting point for x, for example [1E4, 1E4, 1E4], or use trial and error. A solution to the same circuit but using fewer thermistors can also suggest suitable initial values.

Those skilled in the art will be able to devise alternative methods to the above.

### Embodiments Using or Derived from Weighted Sum Technique

FIG. 12 depicts an embodiment similar to FIG. 1. In FIG. 12, the circuit applies factors c1, c2, . . . cn to the input voltage V-ref, and factors d1, d2, . . . dn to the voltages Vout1, Vout2, . . . Voutn.

The circuit of FIG. 12 is similar to FIG. 1, provided that:

ki=ci*di, for i=1 . . . n

FIG. 13 depicts an embodiment that is based on FIG. 1. The circuit sums the weighted thermistor voltages. In FIG. 13, the summing means of FIG. 1 is implemented by an operational amplifier (“op-amp”). The weights applied to the thermistor voltages are determined by resistors Ra1 . . . Ran, Rc1 . . . Rcn, and the op-amp feedback resistor Rf. Due to the negative gain configuration of the op-amp, the output has a positive slope (that is, the output increases with increasing temperature) when the circuit employs NTC thermistors.

FIG. 14 depicts an embodiment that uses an op-amp as a summing point. This embodiment is based on FIG. 12. In FIG. 14, the circuit sums the thermistor currents. Resistors Ra1 . . . Ran and Rc1 . . . Rcn divide down the reference voltage; together with feedback resistor Rf, these resistors determine the weighting factors. Due to the negative gain configuration of the op-amp, the output has a negative slope (when the circuit employs NTC thermistors).

FIG. 15 depicts an embodiment in which the summing point is at the junction of resistors Rw1 . . . Rwn. The circuit sums the weighted thermistor voltages. Resistors Rw1 . . . Rwn determine the weights. The op-amps buffer the junction of each bias resistor Rb1 . . . . Rbn and its thermistor Rth1 . . . Rthn respectively. Due to the configuration of the op-amps, the output has a negative slope (when the circuit uses NTC thermistors).

FIG. 16 depicts a preferred embodiment in which the summing point is at the junction of resistors Rc1 . . . Rcn. Optionally, the summing point may have a load resistance, shown as RL in FIG. 17.

In FIGS. 16 and 17, resistors Rc1 . . . Rcn, that combine the thermistor voltages, also load the thermistor voltages. However, in FIGS. 16 and 17, the value of S=Vout/Vref can still be expressed as the ratio of two polynomials in thermistor resistances, and therefore the alternation principle applies.

As shown in FIGS. 13 to 17, the sub-circuit that performs the weighting and summing functions can take a variety of forms. FIGS. 18 to 20 show some embodiments that employ further means for performing the weighting and summing functions.

In FIG. 18, the summing function is performed by digital means. FIG. 18 is similar to FIG. 12. In FIG. 18, resistances Ra1 . . . Ran and Rc1 . . . Rcn perform the weighting function, and a digital sub-system performs the summing function.

In FIG. 18, the digital sub-system measures the ratios V1/Vref, V2/Vref, . . . Vn/Vref via a multi-channel analog-to-digital converter (“ADC”) sub-system and adds the measurements. Signal Vref is the reference voltage of the ADC subsystem. An example of such an ADC is the LTC2418 from Linear Technology. The LTC2418 has 24-bit resolution. The embodiment also includes an input multiplexer, allowing the ADC to measure several inputs. The multiplexer may be part of the ADC, as in the case of the LTC2418.

The digital subsystem may take a variety of other forms including, but not limited to, a microprocessor, a Field Programmable Gate Array (FPGA) or an Application Specific Integrated Circuit (ASIC).

In some embodiments based on FIG. 18, the digital subsystem may incorporate the ADC subsystem and the voltage reference Vref. FIG. 19 shows one example.

FIG. 19 may use, for example, a C8051F124 microprocessor, from Silicon Laboratories, as the digital subsystem. One of the processor's digital-to-analog converters (“DAC”) provides a reference voltage, Vref, both for the thermistors and for the ADC.

FIG. 20 shows a preferred embodiment based on FIG. 1. In FIG. 20, digital means performs both the weighting and the summing functions. In FIG. 20, the digital subsystem uses the ADC subsystem to measure the voltage ratios V1/Vref, V2/Vref, . . . Vn/Vref. The digital subsystem multiplies each reading Vi/Vref by a factor ki and sums the products.

An example of a suitable ADC sub-system is the LTC2418 from Linear Technology. An example of a suitable digital sub-system is the C8051F124 microprocessor from Silicon Laboratories.

FIG. 21 shows a preferred two-thermistor embodiment. FIG. 22 shows an embodiment based on FIG. 21, but with 2*n thermistors. FIG. 22 also has constant weights c1, c2, . . . , c2n applied to the input voltage Vref. FIG. 22 has, in effect, n stages, each stage comprising two thermistors and two resistors. A weighted summing network combines two voltages from each stage to form the output Vout.

To simplify the circuit of FIG. 22, the circuit may be designed so that as many as possible of the input weights c1, c2, . . . c2n equal 1 or 0. However, in some circumstances, it is advantageous to make one or more of the input weights have a value between 0 and 1. In these cases, the bias resistor Rbi and weight ci are generally implemented with a Thevenin-equivalent circuit, as shown in FIG. 23.

Compared with FIGS. 1 and 12, the embodiments in FIGS. 21 and 22 offer a practical advantage in that it is possible to increase the lowest resistance value and decrease the highest resistance value in the circuit.

If the resistors used in the circuit are low, for example a few hundred ohms, then the parasitic series resistances, in the thermistor leads and other circuit connections, can lead to significant measurement errors. To reduce these parasitic effects to a negligible level, the circuit may be designed so that the minimum resistance of resistors and thermistors used in the circuit is much higher than these parasitic resistances. For example, if the thermistor wiring has a value of, say, about 0.1 ohms, one might design the circuit so that the thermistors and the resistors connected to them have a minimum-resistance 10000 times higher (1000 ohms) over the temperature range of interest.

If the resistors used in the circuit are high, for example, 10 Mohms, then significant parasitic leakage resistances may occur in the circuit. For example in the wiring, printed circuit board (PCB) and component insulation. The parasitic leakages may cause significant errors in the estimated temperature. To reduce these leakage effects to a negligible level, the circuit may be designed so that the maximum resistance of the thermistors and resistors used in the circuit is much less than any leakage resistances. For example, if the insulation of the PCB between the thermistor connections has a resistance of, say, 10 Gohms, then one might design the circuit so that the thermistors and resistors connected to them have a maximum resistance of 10000 times lower (1 Mohms) over the temperature range of interest.

In addition, it may be desirable to keep the ratio of highest resistance value to lowest resistance value to a moderate value, for example less than 100, to make the circuit easier to implement in an integrated circuit or in a hybrid circuit. This ratio is termed the “resistance spread”.

Thus, in some circumstances, practical benefits such as increased accuracy and ease of implementation are realised using an embodiment that uses only a moderate range of resistance values.

In at least some embodiments that use the circuit shown in FIG. 21, the two NTC thermistors are nearly identical and the value of Rb1 is much less than the value of Rb2.

At high temperatures, when the thermistor resistance is low, Rb2 will have little effect on the circuit. Under those conditions, Rb1 is effectively connected to two thermistors in series. Hence, with double the thermistor resistance, Rb1 should equal roughly double its value in FIG. 1.

At low temperatures, when the thermistor resistance is high, Rb1 will have little effect on the circuit. Under those conditions, Rb2 is effectively connected to impedance approximately equal to two thermistors in parallel. With half the thermistor resistance, the value of Rb2 should equal roughly half its value in FIG. 1.

Therefore, it is possible to reduce the resistance spread by approximately 4 times. This is explained in more detail in the example below.

FIG. 24 shows a calculated plot of S (S=Vout/Vref) versus thermistor temperature T when the circuit of FIG. 21 has the following component values:
two identical thermistors, type YSI 45008
Rb1=4.4564E+03,
k1=1.55434E−01,
Rb2=2.45369E+04,
k2=8.44566E−01,

In FIG. 24, S is approximately given by the following linear relationship:

S=m*T+c

where m=−5.33878E−03/K,
c=8.54522E−01

Rearranging the equation gives the thermistor temperature Test estimated by the circuit:

Test=(S−c)/m

FIG. 25 graphs the calculated error in this estimate, Test-T versus temperature T. Over the range 0 to 100 C, the peak error is approximately 168 mK.

Compared with the two-thermistor embodiment of FIGS. 1, 2, and 3, the embodiment in FIG. 21 has similar temperature characteristics and similar peak linearity error, but has a lower resistance spread as expected:
the lower value resistor Rb1 has increased in value from about 2.1 kohms to about 4.5 kohms;
the higher value resistor Rb2 has decreased in value from about 51.4 kohms to about 24.5 kohms;
the resistor spread has decreased by over four times.

FIG. 26 shows an embodiment using n thermistors. This circuit is a generalization of FIG. 21.

FIG. 27 shows an embodiment using n thermistors. The weighting and summing subsystems may take a variety of forms, including those shown in previous figures.

FIG. 28 shows an embodiment based on FIG. 27 where the combined weighted and summing subsystems take the form of a network of resistors Rw1, Rw2, . . . Rwn.

FIG. 29 shows a two-thermistor embodiment based on FIG. 28. FIG. 29 has four resistors. FIG. 9, discussed earlier, shows a preferred embodiment derived from FIG. 29, in which the four resistors have been reduced to three. In FIG. 9, the resistors Rw1, Rw2 serve two functions: they supply current to thermistor Rth2, and they form a weighted sum of the voltages across the two thermistors.

In some applications, there is a need to excite the circuit using a current source and to have an output voltage of the circuit vary in a linear manner with temperature.

FIG. 30 shows one embodiment with current source input and a voltage output. FIG. 30 uses a Norton equivalent circuit of the input source used in FIG. 27.

FIG. 31 shows another embodiment. FIG. 31 is based on FIG. 1.

FIG. 32 uses a Thevenin equivalent circuit of the input source used in FIG. 31.

FIG. 33 shows a preferred embodiment based on FIG. 31 where the weighting and summing functions are performed by a resistor network.

FIG. 34 shows a calculated plot of S (where S=Vout/Iref) versus thermistor temperature T when the circuit of FIG. 31 has two thermistors (n=2) and the following component values:
two identical thermistors, type YSI 45008
Rref=6.691E+02,
Rb1=1.4672E+03,
k1=6.36246E−01,
Rb2=5.07247E+04,
k2=3.63754E−01.

FIG. 34, S is approximately given by the following linear relationship:

S=m*T+c,

where m=−3.57217 ohm/K,
c=5.71761E+02 ohms

Rearranging the preceding equation gives the thermistor temperature Test estimated by the circuit:

Test=(S−c)/m

FIG. 35 graphs the calculated error in this estimate, Test-T, versus temperature T. Over the range 0 to 100 C, the peak error is approximately 168 mK.

FIG. 36 shows an embodiment where the weighting and summing functions are performed by an op-amp's feedback network. In this embodiment, the circuit's output comes directly from the op-amp.

From FIG. 36 we have:

$$Vout * ( k 0 + k 1 * U 1 + … * kn * Un ) = Vref$$

$$where Ui = Rbi / ( Rbi + Rthi ) , i = 1 …n$$

$$Or , \\ \begin{matrix}S = Vout / Vref \\ = 1 / ( k 0 + k 1 * U 1 + … + kn * Un ) )\end{matrix}$$

If the thermistors are identical, then S is a rational polynomial in thermistor resistance Rth, with numerator degree n and denominator degree n. The 2*n+2 alternation principle therefore applies.

FIG. 37 shows a circuit similar to FIG. 36, except that FIG. 37 has the thermistors Rth1 . . . Rthn and bias resistors Rb1 . . . Rbn interchanged.

FIG. 38 shows a calculated plot of S (S=Vout/Vref) versus thermistor temperature T when the circuit of FIG. 37 has two thermistors (n=2) and the following component values:
Rth1, Rtb2=identical thermistors, type YSI 45008
k0=0.2,
Rb1=4.1328E+03
k1=1.789960E−01,
Rb2=1.322893E+05
k2=6.21004E−01

In FIG. 38, S is approximately given by the following linear relationship:

S=m*T+c,

where m=2.1355E−02/K,
c=1.58191

Rearranging the preceding equation gives the thermistor temperature Test estimated by the circuit:

Test=(S−c)/m

The error in this estimate equals Test-T. FIG. 39 graphs the calculated temperature error versus temperature T. Over the range 0 to 100 C, the peak error is approximately 168 mK.

In FIG. 37, the op-amp acts as an error amplifier: the op-amp senses the difference between the reference voltage and the summing subsystem's output, and multiplies the difference by the op-amp's open-loop gain.

FIG. 40 shows an embodiment that is similar to FIG. 19. In FIG. 40, the digital subsystem implements the error amplifier function and the weighted summing function. Comparing FIG. 37 with FIG. 40, one can see that FIG. 40 provides another way of implementing FIG. 37.

In FIG. 40, the digital subsystem can implement the op-amp of FIG. 37 as well as the weighted summing function. Under this arrangement, the output signal in FIG. 40 appears at the DAC output (Vx).

As shown, many embodiments have a single weighting and a single summing network, which combines various voltages and/or currents to form an output that varies nearly linearly with temperature. Embodiments that contain two weighting and summing networks are possible and useful. Such embodiments can provide a reduction in resistance spread.

FIG. 41 shows an embodiment that employs more than one weighted summing network. FIG. 41 depicts a similar circuit to the circuit shown in FIG. 37. In FIG. 41, one network, with weights k0, k1, . . . kn, feeds back a weighted sum of thermistor voltages to the operational amplifier. A second weighted summing network, with weights g0, g1, . . . , gn, forms the output.

The equations governing the circuit are:

Vx*(k0+k1*S1+ . . . *kn*Sn)=Vref

Vx*(g0+g1*S1+ . . . gn*Sn)=Vout

where Si=Rthi/(Rbi+Rthi), i=1 . . . n

Defining:

S=Vout/Vref

Then:

S=(g0+g1*S1+ . . . gn*Sn)/(k0+k1*S1+ . . . *kn*Sn)

If the thermistors are identical, then S can be expressed as a rational polynomial in thermistor resistance R, with numerator degree n and denominator degree n. The 2*n+2 alternation principle therefore applies.

FIG. 42 shows a calculated plot of S (S=Vout/Vref) versus thermistor temperature T when the circuit of FIG. 41 has the following component values:
Rth1, Rth2=identical thermistors, type YSI 45008
k0=0.1
g0=0
Rb1=8.32686E+04
k1=4.42729E−01
g1=7.19471E−01
Rb2=1.31316E+04
k2=4.57271E−01
g2=2.80529E−01

In FIG. 42, S is approximately given by the following linear relationship:

S=m*T+c,

where m=−5.33877E−03/K,
c=8.54522E−01

Rearranging the preceding equation gives the thermistor temperature Test estimated by the circuit:

Test=(S−c)/m

The error in this estimate equals Test-T. FIG. 43 graphs the calculated temperature error versus temperature T. Over the range 0 to 100 C, the peak error is approximately 168 mK.

Once again, the implementation has similar temperature characteristics and similar peak linearity error, but has a lower resistance spread. The two-thermistor implementation of FIG. 1 discussed above has a resistance spread of about 24 times; the implementation of FIG. 41 discussed here has a resistance spread of about 6.4 times.

FIG. 44 shows a two-thermistor circuit derived from FIG. 41. In FIG. 44, the feedback weight k2 is zero and the output weight g1 is zero, which simplify the circuit.

FIG. 45 shows an embodiment based on FIG. 44, where the weighting and summing functions in both feedback and output paths are performed by resistor networks.

FIG. 46 is a preferred embodiment which is based on the circuit shown in FIG. 45. In FIG. 46, each resistor network has been reduced from three resistors to two resistors.

FIG. 47 shows an embodiment derived from FIGS. 40 and 41. In FIG. 47, digital means performs the op-amp function plus the summing and weighting functions of both the feedback and output weighted summing networks. The digital sub-system has two independent DAC outputs, Vx and Vout.

The digital sub-system continually adjusts Vx and Vout so that the following equations hold, hereafter referred to as the governing equations:

Vx*(k0+k1*S1+ . . . *kn*Sn)=Vref

Vx*(g0+g1*S1+ . . . gn*Sn)=Vout

where:

Si=Rthi/(Rbi+Rthi), i=1 . . . n.
Vref is a constant

These are the same equations that govern the embodiment of FIG. 41. FIG. 47 provides an alternative way to implement embodiments like FIG. 41, but using digital means.

One way in which FIG. 47 may operate is as follows. To adjust Vx, the digital subsystem takes ADC readings r0, r1, r2, . . . rn where:

ri=Vx*Si, i=1 . . . n

r0=Vx

The digital sub-system temporarily stores the readings, and calculates a weighted sum Sb given by:

Sb=k0*r0+k1*r1+ . . . *kn*rn

The digital sub-system iteratively adjusts Vx, takes new readings r0, r1, . . . , rn, and recalculates Sb, so that following equation holds:

Sb=Vref

Concurrently, the digital sub-system re-uses the most recently stored readings of r0, r1, . . . rn to calculate the weighted sum Sa given by:

Sa=g0*r0+g1*r1+ . . . *gn*rn

The digital sub-system adjusts Vout so that following equation holds:

Sa=Vout

The digital sub-system continually performs these steps; in so doing, it continually implements the governing equations.

In FIG. 47, the ADC has access to signals Vx and Vout. If the DAC outputs are sufficiently accurate, then an embodiment derived from FIG. 47 may dispense with readings of signals Vx and Vout, and use their calculated values instead. By allowing a reduction in the number of ADC inputs, such an alternative embodiment may be easier and more economical to implement.

FIG. 48 shows an embodiment derived from FIGS. 37 and 40. In FIG. 48, digital means performs the op-amp function plus the summing and weighting function. The digital sub-system uses one independent DAC output, Vout.

The digital sub-system continually adjusts Vout so that the following equation holds, hereafter referred to as the governing equation:

Vout*(k0+k1*S1+ . . . *kn*Sn)=Vref

where:

Si=Rthi/(Rbi+Rthi), i=1 . . . n.
Vref is a constant

This is the same equation that governs the embodiment of FIG. 37. FIG. 48 provides an alternative way to implement embodiments like FIG. 37, but using digital means.

One way in which FIG. 48 may operate is as follows. To adjust Vout, the digital subsystem takes ADC readings r0, r1, r2, . . . rn where:

ri=Vout*Si, i=1 . . . n

r0=Vout

The digital sub-system temporarily stores the readings, and calculates a weighted sum Sb given by:

Sb=k0*r0+k1*r1+ . . . *kn*rn

The digital sub-system then adjusts Vout so that following equation holds:

Sb=Vref

The digital sub-system continually performs these steps; in so doing, it implements and maintains the governing equation.

In FIG. 48, the ADC has access to signal Vout. If the DAC output is sufficiently accurate, then an embodiment derived from FIG. 48 may dispense with readings of signal Vout, and use its calculated values instead. By allowing a reduction in the number of ADC inputs, such an alternative embodiment may be easier and more economical to implement.

As described, a large variety of embodiments use the weighted summing technique or can be derived from embodiments that use it. The weighted summing technique provides a convenient way of implementing a rational function of thermistor resistances with the desired properties.

Not all embodiments require this particular implementation technique. For example, FIG. 49 shows an embodiment excited by a current source, Iref. The circuit can be thought of as having n sub circuits, where each sub-circuit i, i=1 . . . n, comprises a thermistor Rthi plus resistors Rbi and Rci. The output of the circuit is the voltage Vout, which appears across all sub-circuits.

FIG. 50 shows a calculated plot of S (where S=Vout/Iref) versus temperature T, when the circuit of FIG. 49 has two thermistors (n=2) and the following component values:
Rth1, Rth2=identical thermistors, type YSI 45008
Rc1=2.207E+03
Rb1=6.5978E+03
Rc2=2.732027E+05
Rb2=5.44118E+04

In FIG. 50, S is approximately given by the following linear relationship:

S=m*T+c

where m=−1.43617E+01 ohm/K,
c=8.18302E+03 ohms

Rearranging the preceding equation gives the thermistor temperature Test estimated by the circuit:

Test=(S−c)/m

The error in this estimate equals Test-T. FIG. 51 graphs the calculated temperature error versus temperature T. Over the range 0 to 100 C, the peak error is approximately 168 mK.

FIG. 52 shows a preferred embodiment derived from FIG. 49, in which the resistor that parallels the last thermistor Rthn, namely Rcn, is absent.

FIG. 53 shows a calculated plot of S (S=Vout/Iref) versus temperature T, when the circuit of FIG. 52 has two thermistors (n=2) and the following component values:
Rth1, Rth2=identical thermistors, type YSI 45008
Rc1=2.2318E+03
Rb1=4.9581E+03
Rc2 is absent
Rb2=4.41643E+04

In FIG. 53, S is approximately given by the following linear relationship:

S=m*T+c,

where m=−1.4591E+01 ohm/K,
c=6.79216E+03 ohms

Rearranging the preceding the equation gives the thermistor temperature Test estimated by the circuit:

Test=(S−c)/m

The error in this estimate equals Test-T. FIG. 54 graphs the calculated temperature error versus actual temperature T. Over the range 0 to 100 C, the peak error is approximately 167 mK.

The two circuits depicted in FIGS. 49 and 52 have similar linearity and error curves. However, the FIG. 52 example has two advantages: reduced component count, and reduced resistor spread.

FIG. 55 shows an embodiment where the output is the current Iout. The circuit has n sub-circuits in parallel, where sub-circuit i, i=1 . . . n, comprises Rbi, Rthi, and Rci. The circuit is designed so that the admittance ratio S=Iout/Vref is linear with respect to temperature.

A preferred embodiment based on FIG. 55 has resistance Rbn equal to 0.

FIG. 56 shows an embodiment where the output is the voltage Vout. The circuit has n sub-circuits in series, where sub-circuit i, i=1 . . . n, comprises Rbi, Rthi, and Rci. The circuit is designed so that the impedance ratio S=Vout/Iref is linear with respect to temperature. A preferred embodiment based on FIG. 56 has resistance Rbn equal to 0.

FIG. 57 shows an embodiment where the output is the current Iout. The circuit has n sub-circuits in series, where sub-circuit i, i=1 . . . n, comprises Rbi, Rthi, and Rci. The circuit is designed so that the admittance ratio S=Iout/Vref is linear with respect to temperature. A preferred embodiment based on FIG. 57 has resistance Rcn absent.

The embodiments presented above use resistor values or weighting factors to provide the desired degrees of freedom.

Other embodiments that alter the effective thermistor resistances as seen by the circuit are also possible. In these embodiments, each thermistor resistance is effectively multiplied by a factor (“scaling factor”).

The thermistor scaling factors provide extra degrees of freedom. By judicious choice of scaling factors, it is possible to convert a sub-optimal prior art circuit into an embodiment in accordance with the present invention.

FIGS. 58 to 65 depict circuits that perform the scaling function. It will be understood that a person skilled in the art will be able to derive other practical circuits.

FIG. 58 shows a circuit for scaling up a grounded thermistor. On the left-hand side of FIG. 58, the ratio Vin/Iin is given by:

Vin/Iin=Rth/k, where k lies in the range 0 . . . 1

The right-hand side of FIG. 58 shows an equivalent circuit.

FIG. 59 shows a circuit for scaling down a grounded thermistor. On the left-hand side of FIG. 59, the ratio Vin/Iin is given by:

Vin/Iin=Rth/(1+k), where k>0

The right-hand side of FIG. 59 shows an equivalent circuit.

FIG. 60 shows a circuit for providing a scaled down grounded thermistor plus series resistor. On the left-hand side of FIG. 60, the ratio Vin/Iin is given by:

Vin/Iin=(Rth+Rb)/(1+Rb/Rc)

The right-hand side of FIG. 60 shows an equivalent circuit.

FIG. 61 shows a circuit for providing a scaled up grounded thermistor plus series resistor. On the left-hand side of FIG. 61, the ratio Vin/fin is given by:

Vin/Iin=Rb+Rth*(1+Rb/Rc)

The right-hand side of FIG. 61 shows an equivalent circuit.

FIG. 62 shows a circuit for providing a scaled down grounded thermistor plus parallel resistor. On the left-hand side of FIG. 62, the ratio Vin/ Iin is given by:

Vin/Iin=Rb∥(Rth/(1+c)), where c>=0

The right-hand side of FIG. 62 shows an equivalent circuit.

FIG. 63 shows a circuit for providing a parallel resistor plus scaled up grounded thermistor. On the left-hand side of FIG. 63, the ratio Vin/In is given by:

Vin/Iin=Rb∥(Rth/(1−c))

where c lies in the range 0 . . . 1

The right-hand side of FIG. 63 shows an equivalent circuit.

FIG. 64 shows a circuit, derived from FIG. 60, for providing a series resistor plus scaled-down thermistor. On the left-hand side of FIG. 64, the ratio Vin/Iin is given by:

Vin/Iin=(Rth+Rb)/(1+Rb/Rc)

The circuit employs an n-channel FET (Field Effect Transistor). The right-hand side of FIG. 64 shows an equivalent circuit. Whereas FIG. 60 implements a scaled thermistor that is grounded, FIG. 64 implements a scaled thermistor that is floating.

FIG. 65 shows a circuit, derived from FIG. 63, for providing a parallel resistor plus scaled-up thermistor. On the left-hand side of FIG. 65, the ratio Vin/Iin is given by:

Vin/Iin=Rb∥(Rth/(1−c))

where c lies in the range 0 . . . 1

The circuit employs an n-channel FET. The right-hand side of FIG. 65 shows an equivalent circuit. Whereas FIG. 63 implements a scaled thermistor that is grounded, FIG. 65 implements a scaled thermistor that is floating.

FIGS. 64 and 65 show circuits that implement floating scaled thermistors. The floating one-port equivalent networks, as opposed to grounded one-port networks, provide added flexibility in implementing circuits with the desired temperature characteristics. This flexibility comes at the cost of using additional devices, such as FETs.

However, for some applications, it is possible and desirable to implement the analog circuitry partly or wholly in an Integrated Circuit. In many cases, the cost of using a few extra devices in the IC is negligible, malting the scaling techniques of FIGS. 64 and 65 particularly advantageous.

FIG. 66 shows a circuit where scaling factors k1 and k2 are applied to thermistors Rth1 and Rth2 respectively. That is, the left-hand thermistor has resistance k1*Rth1, and the right-hand thermistor has resistance k2*Rth2.

Without scaling, this circuit is the prior art circuit of FIG. 6. With appropriate scaling, FIG. 66 becomes a circuit in accordance with the present invention.

The following example shows how scaling may be used to transform a sub-optimal prior art circuit into an embodiment of the invention with superior linearity.

FIG. 67 shows a calculated plot of S (where S=Vout/Vref) versus temperature T, when the circuit of FIG. 66 has the following component values and scaling factors:
Rth1=thermistor T1 of YSI part number 44018;
Rth2=thermistor T2 of YSI part number 44018;
Rb1=1.23278E+04,
k1=1 (unscaled)
Rb2=2.32678E+04,
k2=2.719210E−01 (scaled down)

S is approximately given by:

S=m*T+c

where m=−6.78401E−03/K;
c=7.2408E−01

Rearranging the preceding equation gives the temperature Test estimated by the circuit:

Test=(S−c)/m

The error in this estimate equals Test-T. FIG. 68 graphs the calculated temperature error versus temperature T. Over the range −5 to 45 C, the peak error is approximately 12 mK. This provides approximately 5 times better linearity than the prior art circuit.

FIG. 69 shows an embodiment of the invention that is a transformation of FIG. 66. In FIG. 69, an op-amp plus resistor Rc2 scale down thermistor Rth2. This circuit uses the scaling method of FIG. 60. The component values in FIG. 69 are:
Rth1=thermistor T1 of YSI part number 44018
Rth2=thermistor T2 of YSI part number 44018
Rb1=1.23278E+04
Rb2=8.55682E+04
Rc2=3.19577E+04

FIG. 70 shows a variation on FIG. 69. T1 FIG. 70, the second thermistor Rth2 is scaled up.

In FIG. 71 each thermistor Rthi, i=1 . . . n, has a scaling factor ki. Without scaling, this circuit is known in the art. With appropriate scaling, the circuit becomes an embodiment of the present invention.

To transform the circuit into a circuit which embodies the principles of at least one aspect of the present invention, the scaling factors are set to appropriate values, and the scaled circuit is implemented using techniques shown in FIGS. 58 to 65. This change, in combination with the choice of scaling factors, produces a smaller error than the prior art circuit.

FIG. 72 shows one possible transformation of FIG. 71, according to the present invention. FIG. 72 scales up all thermistors, but uses one op-amp.

A variation on FIG. 72 is to have one or more thermistors unscaled: thermistor n, for example, can be unsealed by omitting resistor Rcn.

FIG. 73 shows another possible transformation of FIG. 71. FIG. 73 scales down all thermistors, but uses one op-amp. Still other transformations of FIG. 71 are possible.

A variation on FIG. 73 is to have one or more thermistors unsealed: thermistor n, for example, can be unsealed by omitting resistor Rcn.

FIG. 74 shows a two-thermistor circuit based on FIG. 71, where the two thermistors Rth1 and Rth2 have scaling factors 1 and k2 respectively.

FIGS. 75 and 76 show possible transformations of FIG. 74 when k2>1. The circuits of FIGS. 75 and 76 scale up thermistor Rth2.

FIGS. 77 and 78 show possible transformations of FIG. 74 when k2<1. The circuits of FIGS. 77 and 78 scale down thermistor Rth2.

In embodiments derived from FIG. 71, it is advantageous to design the circuit so that one of the resistors Rbi, i=1 . . . n, equals 0. Doing so increases the temperature sensitivity, and eliminates one resistor.

It can also be advantageous to design the circuit so that at least one of the thermistors has a unity scaling factor.

FIG. 79 shows a calculated plot of S (S=Vout/Iref) versus temperature T, when the circuit of FIG. 71 has two thermistors (n=2) and the following component values:
Rth1, Rth2=identical thermistors, type YSI 45008
Ra=1.7423+04
Rb1=0
k1=5.21708
Rb2=3.28771E+04
k2=1

In FIG. 79, S is approximately given by the following linear relationship:

S=m*T+c

where m=−9.30385E+01 ohm/K,
c=1.48849E+04 ohms

Rearranging the preceding equation gives the temperature Test estimated by the circuit:

Test=(S−c)/m

The error in this estimate equals Test-T. FIG. 80 graphs the calculated temperature error versus temperature T. Over the range 0 to 100 C, the peak error is approximately 167 mK.

In this example, thermistor Rth2 has unity scaling, and Rth1 is scaled up. FIG. 81 shows one possible circuit solution. So as to have the characteristics shown in FIGS. 79 and 80, the circuit of FIG. 81 has the following values:
Rth1, Rth2=identical thermistors, type YSI 45008
Ra1+Ra2=1.7423E+04
(Ra1+Ra2)/Ra1=5.21708
Rb2=3.28771E+04

Consequently, given a set of values such as those for FIG. 79, the impedance values in the circuit may be scaled up or down, to meet other constraints on component values. Then, any scaled thermistors may be implemented using the techniques shown above (e.g. as in FIGS. 58 to 65).

A further consequence is that the same techniques, of sensor and impedance scaling, may be applied to other embodiments of the invention.

In some applications, the sensors' physical dimensions and characteristics may be controlled during manufacture. An example is where the sensors are implemented in an Integrated Circuit (IC).

In such cases, additional scaling methods may be used.

In a first such method, a sensor may be scaled by altering its physical dimensions. For example, in the case of an IC that includes resistive sensors in the layout, a sensor's impedance may be scaled by changing the sensor's length, or width, or thickness.

In a second such method, a sensor may be scaled by connecting several sensing elements in series and/or parallel combinations to form one composite sensor.

For example, in the case of an IC that includes capacitive sensors in the layout, two or more identical sensing elements may be connected in parallel to form a composite sensor with two or more times the original capacitance. In this example, the capacitive characteristics of a single sensing element, including fringing field effects that may not scale with some dimensional changes, are scaled by an integer factor.

These and other variations will be apparent to those skilled in the art.

### Embodiments Using or Derived from Product Technique

The circuit shown in FIG. 82 consists of a number of stages. Each stage multiplies the reference voltage Vref by a temperature dependent factor, Rthi/(Rthi+Rbi), and adds a constant fraction of Vref; the resulting sum forms the input to the next stage.

In FIG. 82, the last stage (the right-most stage) does not add a constant fraction of Vref to the output Vout. To do so would not change the linearity of the circuit. However, in some applications, an embodiment might add such a constant fraction for other reasons, e.g. to make the output have a desired offset value.

In FIG. 82:

Vout1=Vref*S1+k1*Vref

Vout2=Vout1*S2+k2*Vref

Vout3=Vout2*S3+k3*Vref

where:

Si=Rthi/(Rthi+Rbi), i=1 . . . n)

For a circuit of n thermistors, the ratio S=Vout/Vref is given by:

S=( . . . ((S1+k1)*S2+k2) . . . )*Sn

For a circuit of n thermistors, the ratio Vout/Vref can be expressed as a rational polynomial of degree (n, n). Therefore the 2*n+2 alternation principle applies.

FIG. 83 shows a calculated plot of S (S=Vout/Vref) versus temperature T, when the circuit of FIG. 82 has two thermistors (n=2) and the following component values:
Rth1, Rth2=identical thermistors, type YSI 45008
Rb1=5.15081E+04;
k1=1.76464;
Rb2=2.1316E+03

In FIG. 83, S is approximately given by the following linear relationship:

S=m*T+c

where m=−1.47631E−02/K,
c=2.36191

Rearranging the preceding equation gives the temperature Test estimated by the circuit:

Test=(S−c)/m

The error in this estimate equals Test-T. FIG. 84 graphs the calculated temperature error versus actual temperature T. Over the range 0 to 100 C, the peak error is approximately 167 mK.

In FIG. 82, each stage contains one thermistor. However, each stage may use more than one thermistor. Each stage may use one or more weighted summing networks. That is, each stage may itself resemble another embodiment of the invention.

### Switched Impedance Embodiments

As discussed above, FIG. 1 shows a multi-thermistor circuit that uses the weighted summing technique. Each thermistor Rth1 . . . Rthn has a bias resistor Rb1 . . . Rbn.

The embodiments of this section change the effective bias resistance from moment to moment, under the control of digital means, so that the circuit uses a single thermistor but acts like one that has several thermistors. The circuit changes the effective bias resistance by switching selected bias resistances in or out of the circuit. FIGS. 85 to 90 illustrate embodiments of this type.

FIG. 85 shows an embodiment derived from FIG. 1 that uses a single thermistor. In FIG. 85, bias resistors Rb1, Rb2, . . . , Rbn connect to thermistor Rth. Digital means, such as a microprocessor (uP), reads the voltage Vx across the thermistor via an Analog to Digital Converter (ADC). Each bias resistor is associated with a buffer amplifier that has shutdown control. The uP uses the shutdown control of each amplifier to enable or disable the amplifier.

When disabled, an amplifier acts as an open-circuit; virtually no current flows through the associated bias resistor into or out of the amplifier's disabled output. When enabled, the amplifier has a low-impedance output (ideally zero ohms) and outputs a voltage equal to (or substantially equal to) the amplifier's input voltage Vref.

By default each amplifier is disabled. The uP enables each amplifier in turn, one at a time, and reads the thermistor voltage while the amplifier is enabled. The uP then forms a weighted sum of the readings.

In this way, FIG. 85 implements the weighted summing technique sequentially, using a single thermistor.

A suitable amplifier is the LMV715, made by National Semiconductor. Each amplifier acts as a switch that can switch a bias resistor in or out of the circuit. Other embodiments may use other switching means.

FIG. 86 shows an embodiment based on FIG. 85 where the weighting function is performed outside the uP, at the input of each amplifier.

The weights k1, k2, . . . , kn shown in FIG. 86, apply to the reference voltage Vref. One way of implementing these weights is to use a resistive ladder between Vref and ground, with a tap for each amplifier input.

With a suitable choice of weights k1 . . . kn, the uP in FIG. 86 need not perform the weighting function.

By moving the weighting function outside the uP, FIG. 86 allows the use of an uP (or equivalent digital means) that has lower performance and therefore, potentially, smaller die area, lower power consumption, and lower cost. In some applications, one can gain practical advantages by implementing the weighting function outside the uP.

FIG. 87 shows an embodiment that uses two digitally controlled potentiometers (“pots”) or resistance networks. The two pots are controlled by the uP. Pot P1 applies a variable weight to the reference voltage Vref. Pot P2 is connected as a variable resistance; it varies the bias resistance connected to the thermistor Rth. The uP measures the thermistor voltage several times, each time setting P1 and P2 to the desired settings. The uP combines the readings to form the output.

If pot P1 implements the weighting function entirely, then the uP may simply sum the readings. Otherwise the uP calculates a weighted sum of the readings.

FIG. 88 shows an embodiment derived from FIG. 87. In FIG. 88, pot P1 applies a variable weight to the buffered thermistor voltage, at the input of the ADC.

FIG. 89 shows an embodiment based on FIG. 85 where the weighting function is performed partly or wholly by a Digital to Analog Converter (DAC). The DAC is controlled by the uP.

FIG. 90 shows an embodiment where both the summing and weighting functions are performed partly or wholly outside the uP. In FIG. 90, the circuit is excited by a constant current source Iref. A digitally controlled resistance VR is connected in parallel with the thermistor. An amplifier buffers the thermistor voltage and applies it to a low-pass filter at the amplifier's output.

In FIG. 90 the filter takes the form of an R-C filter, but it may take other forms.

In FIG. 90 the variable resistance VR may take several forms. For example, it may take the form of a number of resistors in parallel, with each resistor switched in or out of the circuit under digital control. As another example, it may take the form of a digitally controlled potentiometer, connected as a variable resistance.

During an excitation cycle, the uP in FIG. 90 sets the digitally controlled resistance to implement the desired bias resistance. The uP maintains that setting for a predetermined duration—the duration is proportional or substantially proportional to the desired weighting factor. The uP continuously repeats this step with each desired bias resistance and its associated duration (weight). When the uP has applied each desired bias resistance for the desired duration, the excitation cycle completes. The uP immediately applies another excitation cycle, so that the circuit is excited continuously and repetitively.

The average value at the filter output, at the ADC input, forms the desired weighted sum. While it controls the variable resistance VR to excite the circuit, the uP concurrently calculates the average value of signal Vx at the ADC input.

The uP may perform this calculation in many ways; we describe two. One way to perform this calculation is to have the uP sample the filter output periodically, several times per excitation cycle, and apply a digital filtering algorithm to the samples. The output of the digital filter is the desired output of the circuit. As an example, the digital filter may take the form of a moving average filter—that is, a Finite Impulse Response (FR) filter with identical non-zero coefficients.

Another way to perform this calculation is to have the amplifier's output filter attenuate AC components sufficiently well so that the uP need only sample the filter output periodically, once every excitation cycle. The ADC reading is the desired output of the circuit.

The techniques described herein may be applied to other embodiments of the invention, in this section and in other sections of this document.

Note also that in some applications, other digital means, such as an FPGA; EPLD; or ASIC may replace the uP.

### Switched Amplifier Gain Embodiments

The embodiments of this section change the effective bias resistance, from moment to moment, by changing the gains of amplifiers used in the circuit. FIGS. 91 to 94 illustrate embodiments of this type. FIG. 91 shows an embodiment that uses two instrumentation amplifiers with high-impedance inputs. In FIG. 91, each amplifier is shown as comprising two elements, a difference amplifier of gain 1, followed by a digitally controlled gain element.

The instrumentation amplifiers have digitally set gains, A and B, under the control of the uP. A feedback loop operates so that the sum of the two amplifier outputs equals reference voltage Vref.

During an excitation cycle, the uP in FIG. 91 sets the two instrumentation amplifier gains, A and B, then samples the output of one amplifier as shown. The uP then changes the amplifier gains to the next pair of desired values, samples the ADC input again, and so on. The uP forms a weighted sum of the samples for that cycle, then repeats the cycle. The sequence of weighted sums, one sum for each excitation cycle, is the desired output.

In more detail, current Ith flows through the resistance Rb and through thermistor Rth (see FIG. 91).

Therefore:

Vref=Ith(Rb*B+Rth*A)

Vx=Ith*Rth*A

Combining:

$$\begin{matrix}Vx / Vref = Rth * A / ( Rb * B + Rth * A ) \\ = Rth / ( Rth + Rb * B / A )\end{matrix}$$

The ratio of the ADC input voltage to the reference voltage has the form:

Rth/(Rth+Rbias)

where:

Rbias=Rb*B/A

In FIG. 91, the effective bias resistance Rbias is controlled by the ratio of the two amplifier gains. By changing this gain ratio, the uP can adjust the value of Rbias to a desired value. By applying a suitable sequence of amplifier gains and weighting factors, the uP can implement the weighted summing technique in a sequential manner.

Many variations of this switched gain technique are possible.

FIG. 92 has two instrumentation amplifiers with fixed gains. In FIG. 92 the gains are both unity, but in general they need not be. A suitable instrumentation amplifier is the INA121, made by Texas Instruments.

In FIG. 92, the two amplifier outputs are combined by a digitally controlled potentiometer or resistance network. The uP can set the potentiometer ratio k. The uP performs the weighting and summing functions. From FIG. 92:

$$Vref = Ith ( Rb * B + Rth * A )$$

$$Where \text{:}$$

$$B = k , A = 1 - k , k in the range 0 … 1$$

$$Vx = Ith * Rth$$

$$Combining \text{:}$$

$$\begin{matrix}Vx / Vref = Rth / ( Rb * B + Rth * A ) \\ = ( 1 / A ) * Rth / ( Rth + Rb * B / A )\end{matrix}$$

$$Where \text{:}$$

$$1 / A = 1 / ( 1 - k )$$

$$B / A = k / ( 1 - k )$$

By controlling the potentiometer ratio k, the uP can control the effective bias resistance Rb*B/A, and so implement the weighted summing technique sequentially. The circuit applies a weight of 1/(1−k) to the expression Rth/(Rth+Rbias). In FIG. 92, the uP must compensate for this weight where necessary.

FIG. 93 shows an embodiment that uses a single operational amplifier (“op-amp”). The circuit uses a digitally controlled potentiometer with potentiometer ratio k. From FIG. 93:

Vref=Ith(Rth+k*Rb)

Vx=Ith*Rth

Combining:

Vx/vref=Rth/(Rth+k*Rb)

By controlling the potentiometer ratio k, the uP can control the effective bias resistance Rb*k, and so implement the weighted summing technique sequentially.

Although FIG. 93 uses only one amplifier, the circuits of FIGS. 91 and 92 have practical advantages in some applications. By using instrumentation amplifiers, FIGS. 91 and 92 permit the use of 4-wire (Kelvin) connections to the thermistor and resistor Rb. 4-wire connections greatly reduce the effects of parasitic lead resistances. Such circuits make it practical to use a thermistor and/or resistance Rb that have relatively low impedance values, such as a few hundred ohms or less.

In FIG. 94, thermistor Rth and resistor Rb are driven via p-channel FET Q, which acts as a voltage-controlled current source. Such an arrangement increases the circuit's rejection of signals induced into the thermistor connections by external interfering sources. In most other respects, FIG. 94 and FIG. 92 behave similarly.

As FIG. 94 shows, some embodiments can excite the thermistor indirectly, via a controlled source. The thermistor may be excited in a way that enhances some other aspect of the circuit's performance, e.g. electromagnetic immunity (EMI), and still achieve the desired temperature linearity.

### Other Embodiments Using Scaling

The embodiments of this section change the effective bias resistance or thermistor resistance, from moment to moment, by using scaling techniques presented earlier. FIGS. 96 to 106 illustrate embodiments of this type. FIG. 95 shows a circuit similar to FIG. 63. In FIG. 95:

$$\begin{matrix}Vx / Iref = Rb ‖ ( Rth / ( 1 - k ) ) \\ = Rb * Rth / ( Rth + Rb ( 1 - k ) )\end{matrix}$$

The effective thermistor impedance seen by the circuit equals Rth/(1−k); the potentiometer ratio k alters the effective thermistor impedance.

Another way in which to view this result is that the effective bias resistance equals Rb(1−k); the potentiometer ratio k alters the effective bias resistance, and applies a weight factor 1/(1−k) to Vx.

This second interpretation relates to the weighted summing technique.

FIG. 96 shows an embodiment of the invention derived from FIG. 95. In FIG. 96, during an excitation cycle, the uP applies a sequence of potentiometer ratio settings. For each setting, the uP measures the signal Vx. At the completion of the sequence, the uP repeats the cycle. For each cycle, the uP calculates a weighted sum of the thermistor readings. As for FIG. 95, the uP must take into account the weight factor 1/(1−k), discussed above, that the circuit applies to Vx.

By applying a suitable sequence of potentiometer settings and weighting factors, the uP can implement the weighted summing technique in a sequential manner.

FIG. 97 shows an embodiment of the invention derived from FIG. 96. FIG. 97 implements the potentiometer and op-amp functions via an ADC and DAC, controlled by the uP. The ADC can measure the voltage Vx across resistor Rb, and the voltage Vy at the DAC output.

To implement the potentiometer and op-amp functions, the uP continually adjusts the DAC output so that:

Vy=Vx*k

where k equals the desired potentiometer ratio.

In FIG. 97, during an excitation cycle, the uP applies a suitable sequence of potentiometer settings k, adjusts the DAC output for each setting, and measures Vx for each setting. The uP calculates a weighted sum of the measurements Vx for each excitation cycle.

By applying a suitable sequence of potentiometer settings and weighting factors, the uP in FIG. 97 can implement the weighted summing technique in a sequential manner.

FIG. 98 shows an embodiment derived from FIG. 97. In FIG. 98, resistor Rb and thermistor Rth have four-wire connections. The ADC can measure the voltage Vx between the sense wires of resistor Rb, and the voltage Vz between the sense wires of the thermistor.

To implement the potentiometer and op-amp functions, the uP continually adjusts the DAC output so that, similar to FIG. 97:

Vx−Vz=Vx*k

Vz=Vx*(1−k)

where k equals the desired potentiometer ratio.

In FIG. 98, during an excitation cycle, the uP applies a suitable sequence of potentiometer settings k, adjusts the DAC output for each setting, and measures Vx for each setting. The uP calculates a weighted sum of the measurements Vx for each excitation cycle.

By applying a suitable sequence of potentiometer settings and weighting factors, the uP in FIG. 98 can implement the weighted summing technique in a sequential manner.

The circuit shown in FIG. 98 has practical advantages in some applications. The use of 4-wire connections greatly reduces the effect of parasitic lead resistances in the resistor Rb and in the thermistor Rth; 4-wire connections allow Rb and/or Rth to have low resistance values such as a few hundred ohms or less.

FIG. 99 shows an embodiment derived from FIG. 97. In FIG. 99, the ADC measures only the voltage Vx across Rb. The DAC is accurate enough that the uP can simply set the DAC output and need not measure it.

FIG. 100 shows a circuit that is related to FIG. 95. In FIG. 100, the voltage Vx across thermistor Rth is given by:

$$\begin{matrix}Vx / Iref = Rth ‖ Rb ‖ ( Rc / ( 1 - k ) ) \\ = Rth ‖ Rbias \\ = Rbias * Rth / ( Rth + Rbias )\end{matrix}$$

Where:

Rbias=Rb∥(Rc/(1−k))

FIG. 101 shows an embodiment derived from FIG. 100. In FIG. 101, resistor Rc and thermistor Rth have four-wire connections. The ADC can measure the voltage Vx between the sense wires of thermistor Rth, and the voltage Vz between the sense wires of resistor Rc.

To implement the potentiometer and op-amp functions, the uP continually adjusts the DAC output so that:

Vz=Vx*(1−k)

where k equals the desired potentiometer ratio.

The voltage Vx is then given by:

$$\begin{matrix}Vx / Iref = Rth ‖ ( Rc / ( 1 - k ) ) \\ = Rbias * Rth / ( Rth + Rbias )\end{matrix}$$

Where;

Rbias=Rc/(1−k)

In FIG. 101, during an excitation cycle, the uP applies a suitable sequence of potentiometer settings k, adjusts the DAC output for each setting, and measures Vx for each setting. The uP calculates a weighted sum of the measurements Vx for each excitation cycle.

By applying a suitable sequence of potentiometer settings and weighting factors, the uP in FIG. 101 can implement the weighted summing technique in a sequential manner.

FIG. 102 shows an embodiment derived from FIG. 100. FIG. 102 has an extra resistance Ra in parallel with the grounded thermistor. FIG. 103 is an embodiment that uses a Thevenin equivalent circuit of the input source used in FIG. 102. As FIG. 103 shows, some embodiments can use the sequential weighted summing technique with a voltage reference source instead of a current reference source.

FIG. 104 shows an embodiment derived from FIG. 103. In FIG. 104, the DAC implements the potentiometer function. The ADC can measure the voltage Vx across the thermistor, and the voltage Vy at the DAC output.

FIG. 105 shows an embodiment derived from FIG. 104. In FIG. 105, the DAC implements the functions of resistor Ra and voltage reference Vref, in addition to the potentiometer function.

In FIG. 104, the thermistor current Ith is given by:

$$\begin{matrix}Ith = ( Vref - Vx ) / Ra + ( Vy - Vx ) / Rc \\ = ( Vref - Vx ) / Ra - ( 1 - k ) * Vx / Rc\end{matrix}$$

where: k=potentiometer ratio

To make FIG. 105 equivalent to FIG. 104, the thermistor currents must be the same in both circuits. Therefore, in FIG. 105, the uP must control the DAC so that:

Ith=(Vref−Vx)/Ra−(1−k)*Vx/Rc

In FIG. 105, the thermistor current passes through resistor Rc. So:

Ith=(Vy−Vx)/Rc

Combining the previous two equations gives (for FIG. 105):

(Vy−Vx)/Rc=(Vref−Vx)/Ra−(1−k)*Vx/Rc

Rearranging:

Vy=Vref*Rc/Ra+Vx*(1−Rc/Ra−(1−k))

That is, in FIG. 105, during a measurement cycle, the uP controls the DAC output so that the preceding equation holds, for each potentiometer setting k in turn.

In some applications, a weighting factor, w, may be applied to the voltage reference Vref for a given potentiometer setting:

Vy=w*Vref*Rc/Ra+Vx*(1−Rc/Ra−(1−k))

If Vref and Ra become infinite while the ratio Vref/Ra=Iref stays constant, the combination Vref and Ra becomes a current source, in which case:

Vy=w*Iref*Rc+Vx*k

That is, if the uP in FIG. 105 controls the DAC output so that the preceding equation holds, for each potentiometer setting k, and weight factor w, then the circuit of FIG. 105 behaves like the circuit of FIG. 101, which has a current source.

FIG. 106 shows an embodiment that has 4-wire connections to the thermistor and to resistor Rc. The DAC in FIG. 106 implements both the potentiometer function and the current (or voltage) signal reference function.

The previous equation for FIG. 105 can be rewritten in a form that suits FIG. 106:

$$\begin{matrix}Vz = Vx - Vy \\ = - w * Iref * Rc + Vx * ( 1 - k )\end{matrix}$$

Or,

−Vz=w*Iref*Rc−Vx*(1−k)

That is, the circuit of FIG. 106 can behave in the same manner as the circuit of FIG. 101, if the uP controls the DAC output so that the preceding equation holds, for each potentiometer setting k and weight factor w. With a suitable sequence of weights w and potentiometer settings k, the circuit of FIG. 106 can implement the weighted summing technique in a sequential manner.

FIGS. 105 and 106 illustrate how some embodiments may be implemented economically, with digital means and a single sensor. In FIGS. 105 and 106, digital means (uP+DAC+ADC) performs the weighting, summing, sensor biasing, and sensor excitation functions.

### Embodiments Using Product Technique

As discussed above, FIG. 82 shows an embodiment of a multi-thermistor circuit that uses the product technique. Each thermistor Rth1 . . . Rthn has a bias resistor Rb1 . . . Rbn. Each of the first n−1 thermistors also has a weight k1, k2, k3 . . . that applies to Vref.

The ratio Vout/Vref in the circuit can be expressed as a rational function in terms of thermistor resistances and other component values.

The circuit components provide 2*n−1 degrees of freedom: n from the bias resistors, n−1 from the weights. The choice of scale factor m and offset c, in the output characteristic, provide another two degrees of freedom, malting a total of 2*n+1.

The circuit has enough degrees of freedom to satisfy the 2*n+2 alternation principle.

The technique underlying FIG. 82 can be implemented in a sequential manner, using embodiments of the present invention.

FIG. 89, for example, can implement the product technique as follows. During a measurement cycle, the uP, or other suitable digital means, enables each amplifier, one at a time, to switch in the desired bias resistor. Only one amplifier is enabled at any one time.

In FIG. 89, during a measurement cycle, the uP first sets the DAC output to a reference value, enables Rb1, and measures Vx.

The uP adds a constant k1 to the Vx reading to form Vout1, then sets the DAC output to equal Vout1.

The uP then enables only Rb2, and measures Vx. The uP adds a constant k2 to the latest Vx reading, to form Vout2, then sets the DAC output to equal Vout2.

The uP then enables only Rb3, and measures Vx. The uP adds a constant k3 to the latest Vx reading, to form Vout3, then sets the DAC output to equal Vout3.

In the last stage of each measurement cycle, the uP enables only Rbn, and measures Vx. This latest Vx reading equals the desired output of the circuit. The uP then performs another measurement cycle.

Comparing these operations with the circuit of FIG. 82, one can see that the circuit of FIG. 89 can implement the product technique of FIG. 82 in a sequential manner, by applying suitable sequences of bias resistances Rbi and weights ki.

### Embodiments Using Ratio Action of ADC

The embodiments in the following section implement the weighted summing technique using the ratio action of an ADC. FIGS. 107 to 110 illustrate embodiments of this type.

As discussed earlier, FIG. 1 shows a multi-thermistor circuit that uses the weighted summing technique. Each thermistor Rth1 . . . Rthn has a bias resistor Rbi . . . . Rbn. The circuit forms the sum S, where:

$$\begin{matrix}S = Vout / Vref \\ = k 1 * S 1 + k 2 * S 2 + … + kn * Sn \\ = k 1 * Rth 1 / ( Rb 1 + Rth 1 ) + k2 * Rth 2 / ( Rb 2 + Rth 2 ) + … + \\ kn * Rthn / ( Rbn + Rthn )\end{matrix}$$

The equation for ratio S has expressions of the form x/(x+A), where x is the electrical resistance of a sensor (thermistor) and A is the parameter of a linear circuit component (resistance value).

Expressions of the form x/(A+x) arise from the potential dividing action of impedances placed in series.

In some applications, it is desirable to linearize the output of a sub-circuit, using the output value only. It is possible to generate expressions of the form x/(A+x) under these circumstances, and so use the weighted summing technique.

FIG. 107 shows a sub-circuit, connected to an Analog-to-Digital Converter (ADC), under the control of a microprocessor (uP). The sub-circuit generates an output, with value Vx. Vx varies in a non-linear manner under the influence of some physical property P, such as temperature.

Output Vx is connected to an ADC input. The ADC reference input is connected to a Digital-to-Analog Converter (DAC), which operates under uP control. The output of the DAC equals Vy. The circuit connects Vx+Vy to the ADC's reference input.

When it reads the ADC input the uP receives the value Vx/(Vx+Vy)—the ADC's analog input is scaled by the ADC's reference input. The uP can implement the weighted summing technique by setting DAC output Vy to a sequence of values, reading the ADC after each DAC setting, and then calculating a weighted sum of the readings.

FIG. 108 shows a variation on FIG. 107, where the circuit sums terms of the form Vx/(Vy−Vx).

FIG. 109 shows a variation on FIG. 107, where the circuit can sum terms of both forms, Vx/(Vy−Vx) and Vx/(Vy+Vx). Under uP control, a multiplexer connects either Vy−Vx or Vy+Vx to the ADC reference input, as required.

FIG. 110 shows an embodiment based on FIG. 107. In FIG. 110, the uP applies a signal to the ADC reference input that depends on recent ADC readings. During a measurement cycle, the uP first sets the DAC output to a reference level Vr0, then reads the ADC. The ADC will return value Vx1/Vr0.

For the second reading, the uP sets the DAC output to level Vx1+Vr1, where Vr1 is a predetermined constant, then reads the ADC. The ADC will return value:

Vx2/(Vx1+Vr1)

For the third reading, the uP sets the DAC output to Vx1+Vr2, where Vr2 is a predetermined constant, then reads the ADC. The ADC will return value:

Vx3/(Vx1+Vr2)

After taking a suitable number of readings, the uP calculates a weighted sum of the second and subsequent readings. If the value Vx is unchanged or substantially unchanged during a measurement cycle, then the sum S calculated by the uP is given by:

S=k1*S1+k2*S2+ . . . +kn*Sn

where: Si=Vx/(Vx+Vri), i=1 . . . n

In this way, the uP can implement the weighted summing technique. With a suitable choice of weights k1 . . . kn and offsets Vr1 . . . Vrn, S is a rational function of Vx and has the desired approximation properties.

In some applications, such as temperature measurement in some industrial processes, the process changes relatively slowly. In such cases, the measured values change very little during a single measurement cycle, allowing the application of embodiments such as FIG. 110 described above.

The embodiment of FIG. 110 conveniently allows a variation, where the ratio S includes terms of the form Vx/(Vri−Vx). For example, for the second reading, the uP sets the DAC output to level Vr1−Vx1, where Vr1 is a predetermined constant, then reads the ADC. The ADC will return the value Vx2/(Vr1−Vx1).

In this way, the embodiment of FIG. 110 conveniently allows S to contain terms of the form Vx/(Vri−Vx) and/or Vx/(Vri+Vx).

### Embodiments Using Output Amplitude and Multi-Frequency Excitation

In FIG. 1, as previously discussed, the circuit forms the sum S, where:

$$\begin{matrix}S = Vout / Vref \\ = k 1 * S 1 + k 2 * S 2 + … + kn * Sn \\ = k 1 * Rth 1 / ( Rb 1 + Rth 1 ) + k2 * Rth 2 / ( Rb 2 + Rth 2 ) + … + \\ kn * Rthn / ( Rbn + Rthn )\end{matrix}$$

It is possible and practical for the weights k1, k2, . . . kn and other circuit parameters to be complex-valued, so that the transfer function is the ratio of two polynomials with complex coefficients. In such cases, weights with imaginary components give rise to phase shifts within the circuit.

It is possible and practical for some of the circuit parameters to be frequency-dependent. If the input signal comprises several frequencies, the output may combine the circuit response at each frequency, so that the output responds in a highly linear way to the sensed temperature.

In FIG. 111, a reference signal source Vref comprises one or more frequencies. A two-port network N1 couples the reference signal to a thermistor network N2, and a two-port network N3 couples the signal from N2 to a detector. Networks N1, N2, N3 may have frequency-dependent attenuation and phase shifts. The detector combines each frequency component of the signal at its input to form an output. The detector output provides a measure of the thermistor temperature.

Each part of the system—signal source, N1, N2, N3, detector—may take many forms. We present a few embodiments below.

FIG. 112 shows an embodiment based on FIG. 111. In FIG. 112, the input coupling network N1 is a frequency-dependent impedance Z(s), comprising resistors R1, R2, and capacitor C. The thermistor network N2 comprises a shunt thermistor with resistance Rth. The output coupling network N3 is a straight-through connection. The detector is a high-impedance root-mean-square (rms) measuring circuit. The output of the detector, Vout, is a reading or signal equal to the rms voltage at the detector's input.

The input signal Vref has one or more frequencies w1, w2, . . . wn with relative rms amplitudes k1, k2, . . . kn respectively. The mean-square signal at the detector input, Vx, is given by:

|Vx/Vref|̂2=|S1|̂2+|S2|̂2+ . . . +|Sn|̂2

where:

Sp=kp*Rth/(Rth+Z(sp)), p=1 . . . n

Z(s)=R2∥(R1+1/(sp*C))
   |x|̂2 denotes the square absolute magnitude of x, x may be complex
sp=j*wp, imaginary frequency
k1̂2+k2̂2+ . . . +kn̂2=1

Then S=|Vout/Vref| is given by:

S=(|S1|̂2+|S2|̂2+ . . . +|Sn|̂2)̂0.5

The circuit of FIG. 112 forms the square root of a weighted sum, where each term of the sum is the square absolute magnitude of a frequency-dependent complex value. The weights are the squares of the relative rms amplitudes k1, k2, . . . , kn.

FIG. 113 shows a calculated plot of S (S=Vout/|Vref|) versus thermistor temperature T, over the range 0 to 100 C, when the circuit of FIG. 112 has the following component values:
thermistor type YSI 45008
Vref comprises two frequencies w1 and w2 with rms amplitudes k1/|Vref| and k2/|Vref| respectively
R1=2.8256E+03
R2=3.2231 E+04
C=1 uF
w1=1E+04 rad/s
k1=6.85296E−01
w2=0 rad/s
k2 7.28264E−01

In FIG. 113, S is approximately given by the following linear relationship:

S=m*T+c

where m=−5.55955E−03/K,
c=8.61594E−01

By rearranging the previous equation for S, one can express the estimated thermistor temperature Test in terms of S:

Test=(S−c)/m

The error in this estimate equals Test-T. FIG. 114 graphs the calculated temperature error versus temperature T. Over the range 0 to 100 C, the peak error is approximately 226 mK.

FIG. 115 shows a calculated plot of S (S=Vout/|Vref|) versus thermistor temperature T, over the range 0 to 100 C, when the circuit of FIG. 112 has the following component values:
thermistor type YSI 45008;
Vref comprises three frequencies w1, w2, w3 with rms amplitudes k1/Vref|, k2/|Vref|, k3/|Vref| respectively;
R1=1.6479E+03
R2=5.1359E+04
C=1 uF
w1=E+04rad/s
k1=6.21857E−01
w2=7.30707E+01 rad/s
k2=4.1011E−01
w3=0 rad/s
k3=6.67161E−01

In FIG. 115, S is approximately given by the following linear relationship:

S=m*T+c,

where m=4.86832E−03/K,
c=8.43759E−01

Rearranging the preceding equation for S gives the estimated thermistor temperature Test:

Test=(S−c)/m

The error in this estimate equals Test-T. FIG. 116 graphs the calculated temperature error versus temperature T. Over the range 0 to 100 C, the peak error is approximately 29 mK.

The two examples above demonstrate that by exciting a single thermistor with a plurality of frequencies, the circuit of FIG. 112 can produce near-linear temperature characteristics. The linearity of the circuit may be further improved by employing more excitation frequencies.

As shown above, one of the excitation frequencies may be 0 radian/s.

### Embodiments Using Output Phase and Multi-Frequency Excitation

FIG. 117 shows a circuit based on FIG. 111. FIG. 117 has an AC voltage reference Vref, series capacitor C, thermistor Rth, and a phase detector. Vref contains one or more frequency components w1, w2, . . . wn. The phase detector measures the phase of each frequency component in signal Vx, relative to the phase of the same frequency component in signal Vref. A weighted summing network forms the weighted sum S of the phase measurements. The weights k1, 12, . . . , kn have units V/rad. FIG. 118 shows a calculated plot of S (S=Vout) versus thermistor temperature T, over the range 0 to 100 C, when the circuit of FIG. 117 has the following component values:
thermistor type YSI 45008;
Vref comprises three frequencies w1, w2, w3;
the detector applies weights k1, k2, k3 (V/rad) to the measured phase of frequency components w1, w2, w3 respectively;
C=100 nF;
w1=5.29596E+03 rad/s
k1=4.93405E−01
w2=8.02158E+02 rad/s
k2=2.38212E−01
w3=1.2857E+02 rad/s
k3=2.68383E−01

In FIG. 118, S is approximately given by the following linear relationship:

S=m*T+c,

where m=8.90084E−03 V/K,
c=2.24924E−01 V

Rearranging the preceding equation for S gives the estimated thermistor temperature Test:

Test=(S−c)/m

The error in this estimate equals Test-T. FIG. 119 graphs the calculated temperature error versus temperature T. Over the range 0 to 100 C, the peak error is approximately 52 mK.

In FIG. 117, the phase detector uses signal Vref as a reference. This is convenient but not necessary. In alternative embodiments, the phase detector may use another signal or signals as phase references.

### Embodiments Using Capacitive Sensors

The methods and circuits broadly described above also find use in linearising the output from capacitive sensors. Capacitive sensors find broad application in industry as non-contact sensors. Some of their uses are in the measurement of:
the level of liquids;
displacement of metallic or dielectric objects;
thickness of films;

imperfections in the shape of parts;
gas pressure;
gas concentration (e.g. CO2, NO);
relative humidity.

Capacitive sensors in the form of microphones and hydrophones are widely used to record and analyse sound (pressure) waves.

### Multiple Sensors, Multiple Bias Capacitors

FIG. 120 shows a multi-capacitor circuit based on FIG. 1. In FIG. 120, the circuit has n capacitive sensors Ct1, Ct2, . . . Ctn which are responsive to a physical property P such as displacement, or temperature, or pressure, etc.

The capacitive sensors may have identical characteristics, or distinct characteristics, or a combination thereof.

In FIG. 120, each capacitive sensor Ct1, Ct2, . . . Ctn is associated with a bias capacitor Cb1, Cb2, . . . Cbn. Physical property P has little or no influence on the bias capacitors.

Each capacitive sensor is also associated with three switches. For Ct1, these switches are Sw1, Sw2, Sw3.

Normally all switches are open. During a measurement cycle, the circuit first discharges each capacitive sensor, by closing the appropriate switches (Sw1 for Ct1). The circuit then opens those switches.

Simultaneously, the circuit charges the bias capacitors to Vref, by closing the appropriate switches (Sw2 for Ct1). The circuit then opens those switches.

The circuit then transfers charge from each bias capacitor to its associated capacitive sensor, by closing the appropriate switches (Sw3 for Ct1). The circuit then opens those switches.

The last step of the measurement cycle is the readout phase: the circuit forms the weighted sum of the voltages across the capacitive sensors. The weighted sum is the desired output of the circuit.

The circuit then performs another measurement cycle.

During the readout phase, the voltage across each capacitive sensor Cti is given by:

Vouti=Vref*Cbi/(Cti+Cbi) i=1 . . . n

In FIG. 120, the circuit multiplies voltages Vouti, i=1 . . . n, by factors ki, i=1 . . . n respectively and forms the sum Vout. In a linearization application, the object of the circuit is to make the transfer ratio Vout/Vref respond in a linear manner as physical property P varies.

The transfer ratio Vout/Vref is given by:

Vout/Vref=k1*Vout/Vref+k2*Vout2/Vref+ . . . +kn*Voutn/Vref

For purposes of discussion, we define:

S=Vout/Vref

Si=Vouti/Vref, i=1 . . . n

Therefore:

$$\begin{matrix}S = k 1 * S 1 + k 2 * S 2 + … + kn * Sn \\ = k 1 * Cb 1 / ( Ct 1 + Cb 1 ) + k2 * Cb 2 / ( Ct 2 + Cb 2 ) + … + \\ kn * Cbn / ( Ctn + Cbn )\end{matrix}$$

which can be written as:

S=k1+k2+ . . . kn−[k1*Ct1/(Ct1+Cb1)+k2*Ct2/(Ct2+Cb2)+ . . . +kn*Ctn/(Ctn+Cbn)]

The right-hand side of the preceding equation has two parts: a constant term k1+k2+ . . . kn; and the expression:

[k1*Ct1/(Ct1+Cb1)+k2*Ct2/(Ct2+Cb2)+ . . . +kn*Ctn/(Ctn+Cbn)]

S can be expressed as a rational function in terms of sensor capacitances Ct1 . . . Ctn. If Ct1 . . . Ctn are identical, then the preceding expression is a rational polynomial in terms of sensor capacitance Ct:

S=k1+k2+ . . . kn+A(Ct)/B(Ct)

The rational polynomial A(Ct)/B(Ct) has numerator degree n and denominator degree n. The 2*n+2 alternation principle applies.

In linearization applications, the various circuit parameters Cb1, k1, Cb2, k2, etc. are selected so that S is approximately linear with the sensed physical property P. That is:

A(Ct)/B(Ct)=c+m*P

for constants c and m.

Property P can be regarded as a function of sensor capacitance, say f(Ct). Substituting:

A(Ct)/B(Ct)=c+m*f(Ct)

The right-hand side of equation is a non-linear function of sensor capacitance Ct; the left-hand side is a rational function of Ct.

If the sensors are substantially identical and in a best or near-best rational approximation, polynomial B(Ct) has negative real roots, then one can use the circuit of FIG. 120 to form a best or near-best rational approximation. In linearization applications, for many types of sensors, one can obtain a highly linear circuit for sensing property P, with the error curve having at least 2*n+2 alternations.

In practice, as discussed earlier, the 2*n+2 alternation principle also applies to embodiments using non-identical sensors—for best linearity, the error curve should have at least 2*n+2 alternations.

In FIG. 120, the weighting and summing may be performed in a wide variety of ways. The switches can be implemented by FET devices and controlled by digital means.

### Single Sensor, Multiple Bias Capacitors

FIG. 121 shows an embodiment derived from FIG. 120 that uses a single capacitive sensor Ct. FIG. 121 mimics FIG. 120 when the latter has identical sensors.

FIG. 121 has n bias capacitors Cb1, Cb2, . . . Cbn. Each bias capacitor Cb1, Cb2 . . . Cbn is associated with a weight factor k1, k2 . . . , kn. Each bias capacitor is associated with two switches—for Cb1 these are Sw1 and Sw2. The circuit uses switch Swg to discharge the sensor capacitance.

Normally, all switches are open. During a measurement cycle, the circuit first discharges the capacitive sensor, by closing then opening switch Swg.

The circuit progresses through the following steps using capacitor Cb1:
charges bias capacitor Cb1 to k1*Vref (by closing then opening switch Sw1);
a transfers some of this charge to the sensor Ct (by closing then opening switch Sw2);
measures the voltage Vout1 across Cb1;
discharges the capacitive sensor, by closing then opening switch Swg.

The circuit then performs similar steps using capacitors Cb2, . . . Cbn in turn, using the capacitors' associated switches, voltages, and weights.

The circuit then forms the sum of the individual capacitor measurements Vout1, Vout2, . . . Voutn. The weighted sum is the desired output of the circuit.

The circuit then performs another measurement cycle. From FIG. 121:

$$\begin{matrix}S = Vout / Vref \\ = k 1 * S 1 + k 2 * S 2 + … + kn * Sn\end{matrix}$$

$$where \text{:}$$

$$\begin{matrix}Si = Vouti / Vref , i = 1 … n \\ = Cbi / ( Ct + Cbi )\end{matrix}$$

$$Therefore \text{:}$$

$$\begin{matrix}S = k 1 * Cb 1 / ( Ct + Cb 1 ) + k2 * Cb 2 / ( Ct + Cb 2 ) + … + \\ = kn * Cbn / ( Ct + Cbn )\end{matrix}$$

$$which can be written as \text{:}$$

$$S = k 1 + k 2 + … + kn - [ k 1 * Ct / ( Ct + Cb 1 ) + k 2 * Ct / ( Ct + Cb 2 ) + … + kn * Ct / ( Ct + Cbn ) ]$$

The equation has two components, a constant part k1+k2+ . . . +kn and an expression that is a rational polynomial in sensor capacitance Ct. The circuit of FIG. 121 behaves as FIG. 120 when the latter has identical sensors.

In FIG. 121, the circuit applies weighting factors k1, k2, . . . kn to the reference voltage Vref. FIG. 122 shows an embodiment based on FIG. 121. In FIG. 122, the uP performs both weighting and summing functions.

The weighting and summing functions may be performed in numerous ways.

### Singe/Multiple Sensors, A/D Linearization Technique

In the discussion of FIGS. 120 and 121 above, the expressions for the transfer function S contain terms of the form A/(A+x).

In the context of FIGS. 120 and 121, A is a capacitance; the sensor capacitance x varies in a non-linear manner in response to some physical property P, such as pressure. Expressions of the form A/(x+A) arise from the charge dividing action of capacitances placed in parallel.

It is possible to generate expressions of the form x/(x+A) and/or x/(x−A). FIG. 123 shows an embodiment that uses an ADC, under the control of a uP. The circuit has capacitive sensor Ct and a reference capacitor Cb. As in embodiments discussed already, the circuit discharges Ct, then charges Cb, then transfers some of the charge to Ct. The circuit generates signal Vx where:

Vx/Vref=Cb/(Cb+Ct)

In FIG. 123, signal Vx is connected to an ADC input. The ADC reference input is connected to a summing point. The uP may select gains g and h.

In some embodiments based on FIG. 123 the uP may select positive and negative values for gain g. In some embodiments, one of the gains, either g or else h, may be fixed, to simplify the circuit.

In FIG. 123, the ADC reference input voltage equals

h*Vref+g*Vx

The uP receives the value Vz when it reads the ADC output, where Vz is given by:

$$\begin{matrix}Vz = Vx / ( h * Vref + g * Vx ) \\ = ( Vx / Vref ) / ( h + g * Vx / Vref )\end{matrix}$$

Substituting for Vx/Vref and rearranging:

$$\begin{matrix}Vz = Cb / ( Cb + Ct ) / [ h + g * Cb / ( Cb + Ct ) ] \\ = Cb / [ h * ( Cb + Ct ) + g * Cb ] \\ = Cb / [ h * Ct + Cb * ( h + g ) ] \\ = ( 1 / h ) * Cb / [ Ct + Cb * ( 1 + g / h ) ] \\ = 1 / ( h + g ) * Cb * ( 1 + g / h ) / [ Ct + Cb * ( 1 + g / h ) ] \\ = 1 / ( h + g ) * {Cb}^{′} / ( Ct + {Cb}^{′} )\end{matrix}$$

$$where \text{:} {Cb}^{′} = Cb * ( 1 + g / h )$$

Vz has the form k*A/(x+A), with k and A determined by circuit parameters Cb, g, and h. The uP can implement the weighted summing technique by forming signal Vx, setting gain g and/or gain h to a sequence of values, reading the ADC after each setting, and then calculating a weighted sum of the ADC readings.

FIG. 124 shows an embodiment based on FIG. 123. In FIG. 124, the uP applies a signal to the ADC reference input that depends on recent ADC readings. During a measurement cycle, the uP first sets the DAC output to a reference level Vr0, then reads the ADC. The ADC will return value Vx1/Vr0.

For the second reading, the uP sets the DAC output to level Vr1+Vx1, where Vr1 is a predetermined constant, then reads the ADC. The ADC will return value Vx2/(Vr1+Vx1).

For the third reading, the uP sets the DAC output to Vr2+Vx1, where Vr2 is a predetermined constant, then reads the ADC. The ADC will return value Vx3/(Vr2+Vx1).

After taking a suitable number of readings, the uP calculates a weighted sum of the second and subsequent readings. If the value Vx is unchanged or substantially unchanged during a measurement cycle, then the sum S calculated by the uP is given by:

S=k1*S1+k2*S2+ . . . +kn*Sn

where: Si=Vx/(Vri+Vx), i=1 . . . n

In this way, the uP can implement the weighted summing technique. With a suitable choice of weights k1 . . . kn and DAC settings Vr1 . . . Vrn, S is a rational function of Vx with the desired approximation properties.

Each term Si has the form Vx/(Vri+Vx). The uP may also form terms Vx/(Vri+di*Vx) by a minor change to the measurement process. The multiplication factor di may be positive or negative.

For example, for the second reading of a cycle, instead of setting the DAC output to Vr1+Vx1, the uP may set it to Vr1+d1*Vx1, so that the ADC returns a value of Vx2/(Vr1+d1*Vx1). Assuming that Vx1 and Vx2 are equal or substantially equal, then this value has the form Vx/(Vri+di*Vx).

### Single/Multiple Sensors, Frequency Domain Technique

FIG. 125 shows a general scheme for linearizing one or more sensors. In FIG. 125, a reference signal source Vref comprises one or more frequencies. A two-port network N1 couples the reference signal to a sensor network N2, and a two-port network N3 couples the signal from N2 to a detector. Networks N1, N2, N3 may have frequency-dependent attenuation and phase shifts. The detector combines each frequency component of the signal at its input to form an output. The detector output provides a measure of the physical property sensed by the sensor network.

Each part of the system—signal source, N1, N2, N3, detector—may take many forms.

The embodiments may involve non-linear approximation rather than rational approximation. In embodiments involving rational approximation, the circuit's output can be expressed as the ratio of two polynomials, in terms of some parameter or physical property P.

For some embodiments using frequency domain techniques, it may not be possible to express the circuit's output in this manner: the output may be a non-linear function in terms of some parameter or physical property P. However, in practice, the 2*n+2 alternation principle still applies to embodiments involving non-linear approximation—one best matches the desired output characteristic, in a minimax sense, when the error curve has at least 2*n+2 alternations.

Where the circuit uses a single sensor and multiple frequencies, then n equals the number of frequencies. Where the circuit uses p sensors and q frequencies, then n=p*q.

For both frequency- and time-domain embodiments, it can be convenient to make the non-zero excitation frequencies integral multiples of some fundamental frequency. This makes for convenient generation, detection, and filtering, especially by digital or digitally controlled means.

The fundamental frequency may or may not be an excitation frequency. In some applications, it is useful for the excitation signal Vref to have a zero-frequency (DC) component, as discussed above.

An embodiment's detector may use digital or analog filters to extract each frequency component at the detector's input, and then measure each component's phase and/or amplitude. Such extraction and measurement makes for a convenient implementation of certain detectors useful in various embodiments of the invention; for example, detectors that calculate:
weighted sum of amplitudes of frequency components;
weighted sum of phases of frequency components.

### Single/Multiple Sensors, Time Domain Technique

FIG. 126 shows a scheme derived from FIG. 125. In FIG. 126, the detector measures the phase of each frequency component in Vx, at the detector input. The circuit's output equals a weighted sum of the phase measurements.

These embodiments may involve non-linear approximation.

A capacitive pressure sensor with the following characteristics is known in the art:

Ct=C0/sqrt(x)*a tan h(sqrt(x))

where:
Ct=capacitance of sensor
C0=zero-pressure capacitance of the sensor
x=P/Pm
P=applied pressure
Pm=pressure which will cause maximum possible deflection of the sensor's diaphragm
a tan h( )=inverse hyperbolic tangent function
sqrt( )=square root function

In the examples below that employ a capacitive pressure sensor, the capacitive pressure sensor has the characteristics above.

FIG. 127 shows a plot of normalised capacitance Ct/C0 versus normalised pressure P/Pm over the range 0.01 to 0.6. A typical value for C0 is 50 pF.

### Frequency Domain Example for Single Capacitive Sensor

FIG. 128 is derived from FIG. 125. In FIG. 128, source Vref and network N1 have been replaced by a Thevenin-equivalent one-port network, comprising voltage source Vin and impedance Zin. The sensor network N2 is a single capacitive sensor, grounded at one terminal. The output coupling network N3 is a straight-through connection.

The detector is a root-mean-square (rms) detector. The output of the detector, Vout, is a reading or signal equal to the rms voltage at the detector's input. To promote noise immunity, the detector in FIG. 128 may be frequency-selective, measuring only the frequencies of interest.

When designing an embodiment of the invention using FIG. 125 and FIG. 128, the following method may be used:
design a circuit based on FIG. 128 to give the desired characteristics;
derive a second circuit, based on FIG. 125, that has the same characteristics.

In more detail:
calculate the desired resistive and reactive values for Zin, in FIG. 128, assuming 1 rad/s and C0=1 F;
calculate the weight factors k1 . . . kn;
scale the resistances and reactance's for the actual value of C0;
design a two-port network N1, in FIG. 125, that provides the desired Thevenin-equivalent output impedance values at frequencies convenient for the application.

After implementing the circuit of FIG. 125, various parts of the circuit—such as source Vref, network N1, network N3, the detector—may change the signal amplitudes at the excitation frequencies, compared with the initial design for FIG. 128; calculate and implement new weights k1, k2, . . . , kn, to compensate for any such gain distortion.

Ideally, in linearization applications, for example linearization of a pressure sensor, S is highly linear with pressure P:

S=m*x+c

where:
S=Vout/|Vref|
x=P/Pm, normalized pressure
m, c are constants

FIG. 129 shows a calculated plot of S (S=Vout/|Vin|) versus x when the circuit of FIG. 128 has the following component values:
capacitive pressure sensor as above;
Vin comprises two frequencies, w1 and w2, with amplitudes k1/|Vref| and k2/|Vref| respectively;
rms detector;
source impedance Zin:
2.333574E−01+j*1.207632E+00 ohms at w1,
3.335434E−01+j*9.856334E−01 ohms at w2;
k1=8.187493E−01,
k2=5.741512E−01;
assuming sensor impedance=−j ohms at w1 and at w2

In FIG. 129, S is approximately given by the following linear relationship:

S=m*x+c

where m=−2.562333E+00,
c=3.135061E+00

Rearranging the previous equation for S, the estimated normalised pressure xest is given by:

xest=(S−c)/m

The error in this estimate equals xest-x. FIG. 130 graphs the calculated error, xest-x, versus normalized pressure x. Over the normalised pressure range 0.01 to 0.6, the peak error is approximately 8E−6.

In the example above, the detector is an rms detector. Another convenient type of detector is one that forms the weighted sum of the absolute magnitude of the frequency components at the detector input.

### Time Domain Example for Single Capacitive Sensor

FIGS. 131 and 132 show embodiments of the invention based on FIG. 126, and using a single capacitive sensor.

In FIG. 131, source Vref comprises one or more frequencies w1, w2, . . . wn. The sensor network N2 is a single capacitive sensor. The output coupling network N3 is a straight-through connection. The phase detector measures the phase of each frequency component in signal Vx, relative to the phase of the same frequency component in signal Vref. The output of the circuit equals a weighted sum of phase measurements at each component frequency w1, w2, . . . , wn. The weights k1, k2, . . . , kn have units V/rad.

FIG. 132 is similar to FIG. 131. In FIG. 132, the signal source Vref and input network N1 are replaced by a Thevenin-equivalent one-port network, comprising voltage source Vin plus complex impedance Zin.

These embodiments may involve non-linear approximation.

In FIGS. 131 and 132, the phase detector uses input signals Vref and Vin respectively as phase references. This is convenient but not necessary. In alternative embodiments, the phase detector may use another signal or signals as phase references. When designing an embodiment of the invention using FIGS. 131 and 132, the following method may be used:
design a circuit based on FIG. 132 to give the desired characteristics;
derive a second circuit, based on FIG. 131, that has the same characteristics.

In more detail:
calculate the desired resistive and reactive values for network Zin, assuming 1 rad/s and C0=1 F;
calculate the weight factors k1 . . . kn;
scale the resistances and reactances for the actual value of C0;
design a two-port network N1 that provides the desired Thevenin-equivalent output impedance values Zin at frequencies convenient for the application.

After implementing the circuit of FIG. 131, various parts of the circuit—such as source Vref, network N1, network N3, the detector—may introduce non-zero but constant phase shifts at the excitation frequencies; if so, recalculate the line (or curve) of best fit, to take into account these additional phase shifts.

Ideally, in linearization applications, for example linearization of a pressure sensor, S is highly linear with pressure P:

S=m*x+c

where:
S=Vout
x=P/Pm, normalized pressure
m, c are constants

FIG. 133 shows a calculated plot of S versus P when the circuit of FIG. 132 has the following component values:
capacitive pressure sensor as above;
Vin comprises two frequencies, w1 and w2;
the detector applies weights k1 and k2 (V/rad) to frequency components w1 and w2 respectively;
detector measures phase of each frequency component and forms weighted sum;
source impedance Zin:
3.364186E−01+8.561095E−01 ohms at w1;
3.099528E-01+1.17107E+00 ohms at w2;
k1=2.375504E−01;
k2=7.624496E−01;
   assuming sensor impedance=−j ohms at w1 and at w2

In FIG. 133, S (S=Vout) is approximately given by the following linear relationship:

S=m*x+c,

where m=−8.278918E−01 V,
c=−1.859297E+00 V

By rearranging this equation, one can express the estimated normalized pressure xest in terms of S:

xest=(S−c)/m

The error in this estimate equals xest-x. FIG. 134 graphs the calculated error, xest-x, versus normalized pressure x. Over the normalised pressure range 0.01 to 0.6, the peak error is approximately 4E-6.

For FIG. 134, n=2. According to the 2*n+2 principle, the number of alternations in the minimax error curve should equal or exceed 2*n+2. In many embodiments, as already shown, the number of alternations equals 2*n+2.

FIG. 134 shows that, in some embodiments of the invention, the number of alternations can exceed 2*n+2. FIG. 130, discussed above, provides a further example.

In the time- and frequency-domain examples above, the signal source applies all of the frequency components simultaneously. In at least some alternative embodiments, the signal source applies excitation signals sequentially; that is, the signal source repeatedly applies a sequence of signals, where each signal comprises one or more frequency components, and the detector takes a reading for each signal in the sequence, then combines the readings to form an output value, one for each repetition of the sequence. The sequence of output values forms the output signal of the circuit.

For example, each signal in the sequence may comprise exactly one frequency component, with the detector being an absolute magnitude detector, and the detector outputting a weighted sum of the readings, the output signal comprising the sequence of weighted sums.

These and other minor variations will be apparent to those skilled in the art.

### Embodiments for Circuit Compensation

As discussed in the introduction, embodiments of the present invention may also be used to compensate for undesirable changes in output when a circuit is affected by a physical property, such as temperature, pressure, and so on.

In linearization applications, the desired relationship between circuit output and sensed property is typically a linear function of the sensed property. In compensation applications, the desired relationship is typically a constant function—that is, the output of interest is preferably independent of changes in the sensed property.

Therefore, the principles applied in linearizing a circuit output are similar to the principles which can be utilised to compensate for changes in the output of a circuit.

FIG. 135 shows a general method for temperature compensating a voltage source. In FIG. 135, a voltage source generates signal Vsrc. This signal is applied to a sub-circuit that employs temperature sensors. In FIG. 135, the sensors are thermistors.

Vsrc is combined with signals from the sensor sub-circuit to form output signal Vout. The circuit is designed so that Vout has the desired temperature characteristics.

FIG. 136 gives an example of this method. In FIG. 136, signal Vsrc is a DC voltage. In this example, Vsrc is proportional to absolute temperature (PTAT). PTAT voltage and current sources are widely used in other voltage and current reference circuits. Methods for generating PTAT voltages and currents are well known to those skilled in the art.

In FIG. 136, signal Vsrc is applied to a thermistor sub-circuit. The particular thermistor sub-circuit shown in FIG. 136 is just one of many possible sub-circuits according to an embodiment of the invention.

In a compensation application, the thermistor sub-circuit is such that Vout is substantially independent of temperature. From FIG. 136, we have:

Vout=Vsrc*(k0+k1*S1+k2*S2+ . . . +kn*Sn)

where: Si=Rthi/(Rthi+Rbi) for i=1 . . . n

Vsrc is a function of temperature T. In this particular case:

Vsrc=m*T, m is a constant

Assume that the thermistors are identical, that the thermistors all sense the temperature of the voltage source. Then temperature T can be regarded as a function G of thermistor resistance Rth:

T=G(Rth)

So:

Vsrc=m*G(Rth)

Vout=m*G(Rth)*f(Rth)

Where:

f(Rth)=k0+k1*S1+k2*S2+ . . . +kn*Sn

Ideally, Vout will equal a constant c:

Vout=m*G(Rth)*f(Rth)=c

That is:

f(Rth)=c/(m*G(Rth))

In the equation given above, the left-hand-side expression is a rational function of thermistor resistance Rth. The right-hand-side expression is a non-linear function of Rth.

The thermistor sub-circuit in FIG. 136 is designed so that the left-hand side is a best or near-best approximation to the right-hand-side. In this way, rational approximation has application to temperature compensation. The 2*n+2 alternation principle applies.

When the thermistors are not identical, then the task of designing the circuit becomes one of non-rational approximation. The 2*n+2 alternation principle also applies.

When using n thermistors, the thermistor sub-circuit in FIG. 136 has 2*n+1 degrees of freedom: n degrees of freedom come from the choice of bias resistors Rb1 . . . Rbn; n+1 degrees of freedom come from the choice of weights k0, k1, . . . , kn. The circuit provides enough degrees of freedom so that the error curve has 2*n+2 alternations.

FIG. 137 shows a calculated plot of the error in Vout versus temperature, when the circuit of FIG. 136 has the following component values, and uses two thermistors (n=2):
c=nominal output voltage=1
Vsrc=1+T/273.15, temperature Tin degrees C.
Rth1, Rth2 are type YSI 45008
k0=6.327244E−01
Rb1=3.0113E+03
k1=2.26599E−01
Rb2=6.86074E+04
k2=2.53582E−01

Over the range 0 to 100 C, the peak error in. FIG. 137 is approximately 0.5 mV. As desired for a 2-thermistor circuit, the error curve has six alternations.

The more thermistors used, the better the temperature compensation.

Bandgap voltage reference circuits have a well-known temperature characteristic. The output reference voltage is given by:

Vx=Vgo+VT*(γ−α)*(1+ln(T0/T))

Where:
VT=k*T/q (thermal voltage)
k=Boltmann's constant
q=electron charge
T=temperature in Kelvin
γ=circuit parameter, typically 3.2
α=circuit parameter, typically 0 or 1
T0=circuit parameter
Vgo=bandgap voltage of Si at 0 Kelvin=1.205 V

Detailed information on bandgap voltage references may be found, for example, in “Analysis and Design of Analog Integrated Circuits”, second edition, Paul Gray and Robert Meyer, ISBN 0-471-81454-7, 1984.

In the following example, again based on FIG. 136, Vsrc is a bandgap voltage source. The thermistor sub-circuit shown in FIG. 136 is designed so that Vout is substantially independent of temperature.

The thermistor sub-circuit shown of FIG. 136 illustrates only one of many possible embodiments according to the invention. For this example:

γ=3.2

α=1

T0=25 degrees C.

FIG. 138 shows the calculated output voltage Vsrc of the bandgap sub-circuit versus temperature. The nominal output voltage Vout equals 1.205 V.

FIG. 139 shows a calculated plot of relative error in Vout versus temperature, when the circuit of FIG. 136 has the following component values, and uses two thermistors:
c=nominal output voltage=1.205
Vsrc as given by the preceding equations
Rth1, Rth2 are type YSI 45008
k0=9.59922E−01
Rb1=9.118E+02
k1=−5.0237E−03
Rb2=3.792599E+05
k2=2.02701E−03

Over the range 0 to 100 C, the peak error in FIG. 139 is about 3 parts per million. As expected for a 2-thermistor circuit, the error curve has six alternations.

FIG. 140 shows a general method for compensating a frequency source. In FIG. 140, a sub-circuit employing temperature sensors generates a control signal Vx. In FIG. 140, the temperature sensors are thermistors. Signal Vx is applied to a frequency tuning element or tuning sub-circuit within an oscillator circuit. As Vx varies with temperature, Vx causes a variation in the tuning element or sub-circuit, thereby affecting the oscillator frequency.

Ideally, Vx varies in such a way that the oscillator frequency has the desired temperature characteristics.

In some applications, the ideal is to vary Vx so as to make the oscillator frequency independent of temperature, over a wide temperature range e.g. −30 degrees C. to +85 degrees C.

In some applications, such as oscillators in mobile phone handsets, the allowed frequency variation over the operating temperature range may be only one or two parts per million (ppm).

The frequency tuning mechanism in FIG. 140 may take many forms. For example, in a temperature-compensated quartz crystal oscillator circuit, control voltage Vx may adjust the effective capacitance of a capacitive element, known in the art as a varactor, and thereby alter the frequency of oscillation.

As another example, control voltage Vx may adjust the supply voltage applied to an oscillator circuit, such as a ring oscillator circuit, thereby altering the frequency of oscillation.

FIG. 141 shows another method for compensating a frequency source. In FIG. 141, the oscillator signal passes through the thermistor sub-circuit. The thermistor sub-circuit acts as a temperature-dependent attenuation and/or phase-shift network.

In some embodiments based on FIG. 141, as the temperature varies, the signal at port 1 varies in phase and/or amplitude in such a way that the oscillator output has the desired temperature characteristics.

FIG. 142 shows a temperature-compensated quartz crystal oscillator (TCXO) circuit that uses the compensation method shown in FIG. 140. This oscillator circuit configuration is well-known in the art as a common-collector Colpitts oscillator.

In FIG. 142, a temperature compensation circuit produces an output Vout, which reverse-biases a varactor diode V1. As Vout changes in response to temperature, the capacitance of V1 changes, thereby changing the load impedance that resonates with crystal G1.

FIG. 142 has the following circuit values:

R1=15 k

R2=20 k

R3=2 k

R4=100 k

C1=100 pF

C2=220 pF

C3=22 pF

Q1=2N3904

The series resonant frequency of crystal G1 changes with temperature. In this example, the temperature compensation sub-circuit changes the load impedance applied to G1 so that the parallel resonant frequency of G1 is constant or substantially constant with temperature and equals 20 MHz.

FIG. 143 shows an electrical model of a crystal known in the art. The crystal has the following characteristics:
motional capacitance Cm=12.5E−15 F
static capacitance Co=3E−12 F
fundamental resonant frequency=20 MHz with
external 32 pF load at 25 deg. C.
equivalent series resistance Rm=4 ohms

The crystal has an AT cut. FIG. 144 shows the calculated relative change in series resonant frequency with temperature, given by the following equation:

Fs(T)=a0*(T−T0)+a1*(T−T0)̂2+a2*(T−T0)̂3

where:
Es(T)=relative change in series resonant frequency fs
T=crystal temperature in deg. C.
T0=reference temperature, 25 deg. C.
a0=−0.386E−6;
a1=0.038E−9;
a2=109E−12;

As shown in FIG. 144, over the temperature range of −30 to +85 C, the series resonant frequency varies by approximately +/−9 ppm.

In FIG. 142, the varactor diode V1 is an Alpha Industries type SMV1147. FIG. 145 shows the capacitance characteristics of the varactor diode when reverse-biased, given by the following equation:

Cj=Cjo*/(1+V/Vj)̂M

where:
Cj=varactor diode capacitance
Cjo=89.52E−12 F, zero-bias varactor diode capacitance;
V=varactor bias voltage
Vj=2.5 V, junction potential
M=1.1, grading coefficient

FIG. 146 shows a graph of the calculated varactor junction capacitance Cjx versus temperature, required to maintain a constant oscillation frequency of 20 MHz in FIG. 142, given by the following equations:

1/Cm+1/(Co+Cext)=(1/Cm+1/(Co+Cnom))/(1+Fs(T))̂2

Cjx=Cext−(1/(1/C1+1/C2)+C3)

where:
Cext=ideal load capacitance external to crystal (incorporates C1, C2, C3, Cj);
Cm and Co are crystal parameters, given above;
Fs(T) is the temperature characteristic of the crystal, given above and shown in FIG. 144;
Cnom is the crystal's nominal or calibrated load capacitance, given above;
C1, C2, C3 are given above and shown in FIG. 142.

FIG. 147 shows a graph of the calculated ideal varactor diode voltage Vjx versus temperature, for the circuit of FIG. 142, given by the equation:

Vjx=Vj*((Cjo/Cjx)̂(1/M)−1)

where:
Vj, Cjo, M are varactor parameters, given above;
Cjx=ideal varactor junction capacitance, given above and shown in FIG. 146.

FIG. 148 shows a graph of the calculated relative frequency deviation from 20 MHz, of signal Vosc in FIG. 142, when the temperature compensation sub-circuit in FIG. 142 has the form of FIG. 149 with the following components and values:
Vref=1 V
Rth1, Rth2, Rth3 are identical thermistors, type YSI 45008
Rb1=1E+03
Rb2=5E+04
Rb3=1E+06
k0=1
g0=−4.16998
k1=3.35063E−01
g1=5.91608
k2=−1.01413
g2=5.502261E−01
k3=−1.25096
g3=1.37029

In this example, signal Vout in FIG. 149 corresponds to signal Vout in FIG. 142. FIG. 149 is similar to the embodiment shown in FIG. 41.

As shown in FIG. 148, over the temperature range of −30 to +85 C, the calculated output frequency deviates from 20 MHz by about +/−0.046 ppm. The deviation (or error) curve has 7 roots, in accordance with the 2*n+2 alternation principle.

Compared with the crystal's characteristics (FIG. 144), the temperature compensation circuit described above reduces the relative frequency variation versus temperature by almost 200 times.

As already noted, some embodiments of the invention such as FIGS. 41 and 149 have two weighted summing networks: one for generating a feedback signal, and one for generating the output signal. The summing network weights themselves—k0, k1, k2, . . . , kn and g0, g1, . . . , gn—can provide enough degrees of freedom to satisfy the design principle, thereby allowing some latitude in the choice of bias impedances Rb1, . . . . Rbn.

In the example discussed above and shown in FIGS. 142 to 149, the impedances Rb1, Rb2, Rb3 were chosen to be convenient values. Then the network weights were optimised to realize the desired output characteristics.

Embodiments with many degrees of freedom, such as FIGS. 41, 149, and 47, can provide practical benefits, such as ease of implementation, in linearization, compensation, and other applications of the invention.

### Embodiments with Frequency, Period, Duty Cycle, Pulse Duration Outputs

In some of the embodiments presented above, the circuit's output quantity of interest takes the form of a signal amplitude or signal phase, or a function of signal amplitudes or phases.

It is possible and practical for the output quantity of interest, in an embodiment of the invention, to take the form of a signal frequency, or period, or duty cycle, or pulse duration.

FIG. 150 shows a prior art circuit that converts temperature to a time interval. In FIG. 150, comparator U compares two analog signals and outputs a digital signal. A potential divider comprising resistor Rb and thermistor Rth biases the negative input of U at a voltage equal to k*Vref, where k is given by:

k=Rth/(Rth+Rb)

and Vref is constant.

The signal at the positive input of U equals the voltage across capacitor C and resistor R.

The circuit operates as follows. Switch control means closes switch Sw, to charge capacitor C to Vref. During this time, comparator U's output is high. Switch Sw is then opened, to allow the capacitor to discharge through resistor R.

FIG. 151 shows a timing diagram. Some time d after the switch is opened, the voltage across the capacitor falls below k*Vref, causing the comparator's output to change state. Detector means in FIG. 150 measures the time delay d, shown in FIG. 151, from the opening of the switch to the change in state of signal Vx.

Time delay d gives a measure of the thermistor temperature T. Delay d is given by:

$$exp ( - d / ( R * C ) ) = k$$

$$\begin{matrix}d = R * C * ln ( 1 / k ) \\ = R * C * ln ( 1 + Rb / Rth )\end{matrix}$$

Ideally, in this example, the delay d varies in a linear manner with temperature. FIG. 152 shows a calculated plot of delay d versus temperature T, over the temperature range 0 to 100 C, when the circuit of FIG. 150 has the following values:
Rth=thermistor type YSI 45008
R=1E+06
C=1E−09
Rb=1.061359E+05

In FIG. 152, the relationship between delay d and temperature T is approximately given by:

d=m*T+c

where m=3.26289E−02 s/K,
c=7.22847E−01 s

Using this approximate relationship, the temperature Test estimated by delay d is given by:

Test=(d−c)/m

The error in the estimate equals Test-T. FIG. 153 shows a calculated plot of the error versus temperature T. The peak error is about +/−0.87 deg. C.

FIG. 154 operates in a similar manner to prior art FIGS. 150 and 151. However,

FIG. 154 is an embodiment according to the invention, using a thermistor arrangement similar to FIG. 9. FIG. 155 shows a calculated plot of delay d versus thermistor temperature T when FIG. 154 has the following components and values:
Rth1, Rth2=identical thermistors, type YSI 45008
R=1E+05
C=1E−08
Rb1=1.1738E+04
Rw1=1.447239E+05
Rw2=2.99248E+04

In FIG. 155, the relationship between delay d and temperature T is approximately given by:

d=m*T+c

where m=2.69545E−05 s/K,
c=9.23506E−04 s

Using this approximate relationship, the temperature Test estimated by delay d equals:

Test=(d−c)/m

The error in the estimate equals Test-T. FIG. 156 shows a calculated plot of the error versus temperature T. The peak error is about +/−60 mK. Compared to the prior art circuit discussed above, this particular two-thermistor embodiment of the invention reduces the linearity error by about 14 times.

FIG. 157 shows another embodiment of the invention. FIG. 157 operates in a similar manner to FIG. 154 and uses two thermistors. However, in FIG. 157, one thermistor influences the voltage at the comparator's negative input, and the second thermistor influences the rate at which timing capacitor C discharges (when the switch S is open).

In FIG. 157, delay d is given by:

$$\begin{matrix}d = Req * C * ln ( 1 / k ) \\ = Req * C * ln ( 1 + Rb 1 / Rth 1 )\end{matrix}$$

$$where Req = Rs + Rp ‖ Rth 2$$

FIG. 158 shows a calculated plot of delay d versus thermistor temperature T when FIG. 157 has the following components and values:
Rth1, Rth2=identical thermistors, type YSI 45008
C=1E−08
Rb1=5.50029E+04
Rs=4.84707E+04
Rp=6.97941E+04

In FIG. 158, the relationship between delay d and temperature T is approximately given by:

d=m*T+c

where m=1.27056E−05 s/K,
c=4.04936E−04 s

Using this approximate relationship, the temperature Test estimated by delay d equals:

Test=(d−c)/m

The error in the estimate equals Test-T. FIG. 159 shows a calculated plot of the error versus temperature T. The peak error is about 63 mK. Compared to the prior art circuit discussed above, this two-thermistor embodiment of the invention also reduces the linearity error by about 14 times.

As shown in FIGS. 157 to 159, in some embodiments of the invention that use multiple sensors, the multiple sensors may act in concert, from within functionally distinct areas of the circuit.

As discussed, the peak linearity error, in the example illustrated by FIGS. 154 to 156, is about 60 mK for a two-thermistor implementation. By contrast, the peak linearity error for the example illustrated by FIGS. 1 to 3 is about 168 mV, even though it uses the same thermistor type over the same temperature range.

This can be understood by examining the relationship being approximated by each circuit and the characteristics of the sensors involved. Where the sensor sub-circuit must approximate a function that is similar to the sensor's own characteristics, the approximation error will generally be lower than in the case of a dissimilar sensor type.

For FIGS. 154 to 156, as can be seen in the circuit equations for delay d, the thermistor network approximates a resistance function that is approximately exponential. It is well-known in the art that NTC thermistors typically have approximately exponential resistance characteristics.

Hence, by selecting appropriate sensor types that match circuit characteristics (and vice versa) higher accuracy may be achieved.

FIG. 160 shows a prior art circuit. In FIG. 160, ideally, the frequency is a linear function of temperature. FIG. 161 shows a timing diagram for FIG. 160.

The circuit of FIG. 160 works as follows. Output Vout has two states, Vcc (typically 5 V) and 0 V. In the Vcc state, output Vout equals supply voltage Vcc and charges capacitor C via thermistor Rt. Also, during that state, the comparator means in the circuit compares input Vx against input signal Vz, equal to (1−k)*Vcc in FIG. 160. When Vx equals Vz, output Vout switches state to 0 V.

In the 0 V state, Vout equals 0V and discharges capacitor C. Also, during the 0 V state, comparator means compares input Vx against input signal Vy, equal to k*Vcc in FIG. 160. When Vx equals Vy, output Vout switches state to Vcc.

Consequently, in FIG. 160, Vout oscillates between the Vcc and 0 V states. The frequency F of oscillation is given by:

F=1/(2*Rt*C*ln(1/k−1))

which is non-linear in Rt. A typical value for parameter k is ⅓.

FIG. 162 shows an embodiment of the invention based on FIG. 160. The thermistor-based impedance network in FIG. 162 is similar to that used in FIG. 55.

FIG. 163 shows a calculated plot of frequency versus thermistor temperature T when FIG. 162 has two thermistors (n−2) and the following components and values:
Rth1, Rth2=thermistor type YSI 45008
k=⅓
C=1E−08
Rb1=9.1189E+03
Rc1=2.7914E+03
Rb2=5.75348E+04
Rc2=4.95507E+05

In FIG. 163, the relationship between frequency F and temperature T is approximately given by:

F=m*T+c

where m=1.59087E+01 Hz/K,
c=6.62087E+03 Hz

Using this approximate relationship, the temperature Test estimated by frequency F equals:

Test=(d−c)/m

The error in the estimate equals Test-T. FIG. 164 shows a calculated plot of the error versus temperature T. The peak error is about 166 mK.

In a similar embodiment, the output period of oscillation can be made highly linear with temperature. FIG. 165 shows a calculated plot of output period versus thermistor temperature T when FIG. 162 has two thermistors and uses the following components and values:
Rth1, Rth2=identical thermistors, type YSI 45008
C=1E−08
k=⅓
Rb1=5.9476E+03
Rc1=2.2251E+03
Rb2=5.03732E+04
Rc2=4.271259E+05

In FIG. 165, the relationship between period A and temperature T is approximately given by:

A=m*T+c

where m=−2.01153E−07 s/K,
c=1.05903E−04 s

Using this approximate relationship, the temperature Test estimated by period A equals:

Test=(d−c)/m

The error in the estimate equals Test-T. FIG. 166 shows a calculated plot of the error versus temperature T. The peak error is about 167 mK.

It will be understood that the examples given in the preceding description are not limiting and that the techniques, algorithms and methodology described herein may be applied to sensors that are resistive, capacitive, or inductive. Such sensors may sense physical properties such as temperature, pressure, electromagnetic fields, strain, displacement, acceleration and velocity, among others.

It will be understood in the examples described above that the values of any components and component parameters and other quantities are in terms of SI base units and derived units, unless otherwise stated. In particular, unless otherwise stated, values and quantities of thermodynamic temperature, time, frequency, electric potential difference, electric current resistance, capacitance, and inductance are in units of Kelvin, second, hertz, volt, ampere, ohm, farad, and Henry respectively.

It will also be understood that many of the embodiments described herein may be varied while not departing from the scope of the invention. For example, the methodology utilised in embodiments which utilise only a single sensor may be applied to embodiments which utilise multiple sensors, in order to improve accuracy.

1. A circuit employing a plurality of n sensors, the circuit being arranged such that one of a transfer function or output function of the circuit approximates a desired mathematical relationship between a physical property measured by the sensors and the output of the circuit, the one of the transfer function or output function equaling the desired relationship at at least 2*n+1 points.

2. A circuit in accordance with claim 1, wherein at least one of non-sensor parameters of the circuit, an output scale factor and an output offset value are selectable to provide at least 2*n+1 degrees of freedom in determining the points of equality.

3. A circuit in accordance with claim 1, wherein at least two of the plurality of n sensors have substantially identical characteristics.

4. A circuit in accordance with claim 1, wherein the transfer function or output function is a rational function in terms of circuit parameters.

5. A circuit in accordance with claim 1, wherein the output of the circuit is a function of a weighted sum of signal measurements measurable at one or more given locations in the circuit.

6. A circuit in accordance with claim 5, wherein the signal measurements are one of signal amplitudes and signal phases.

7. (canceled)

8. A circuit in accordance with claim 1, wherein the desired mathematical relationship is a linear function between the output of the circuit and the sensed property.

9. A circuit in accordance with claim 1, wherein the sensors are one of one-port devices, temperature, sensors, resistive devices, thermistors and capacitive sensors.

10-13. (canceled)

14. A circuit in accordance with claim 1, wherein the sensors are devices with one of 3-wire and 4-wire Kelvin connections.

15. A circuit in accordance with claim 1, wherein all of the at least 2*n+1 points of equality occur within a defined range of values of a physical property measured by the sensors.

16. A circuit employing a sensor, the circuit being arranged such that one of a transfer function or output function of the circuit approximates a desired mathematical relationship between a physical property measured by the sensor and the output of the circuit, the one of the transfer function or output function equaling the desired relationship at least 2*n+1 points, n being an integer greater than 1, wherein the arrangement of the circuit provides at least 2*n+1 degrees of freedom in determining the points of equality.

17. A circuit in accordance with claim 16, wherein at least one of non-sensor parameters of the circuit, an output scale factor and an output offset value are selectable to provide the at least 2*n+1 degrees of freedom in determining the points of equality.

18. A circuit in accordance with claim 16, wherein for each of the signals used by the circuit to form the output value, the circuit establishes one of a bias and an excitation condition at the sensor, the points of equality being determined by the set of bias and excitation conditions established at the sensor.

19. A circuit in accordance with claim 16, wherein the circuit employs analog-to-digital converter means, the output of the circuit being a function of measurements derived from the analog-to-digital converter means, wherein for each measurement of a first signal one of a second signal and the sum of the first and second signals and the difference of the first and second signals is provided to the analog reference input of the analog-to-digital converter means in order to provide the predetermined transfer function or output function.

20. A circuit in accordance with claim 16, wherein the transfer function or output function is a rational function in terms of circuit parameters.

21. A circuit in accordance with claim 16, wherein the output is one of a function of a weighted sum of signal measurements measurable at one or more given locations in the circuit and a weighted sum of the square of signal measurements measurable at one or more given location in the circuit.

22. (canceled)

23. A circuit in accordance with claim 21, wherein the measurements are one of signal amplitudes and signal phases.

24. (canceled)

25. A circuit in accordance with claim 16, wherein the desired mathematical relationship between the output and the sensed property is a linear function.

26. (canceled)

27. A circuit in accordance with claim 16, wherein the sensor is one of a one-port device, temperature sensor, a resistive device, a thermistor and a capacitive device.

28-30. (canceled)

31. A circuit in accordance with claim 18, wherein the sensor is a device with one of 3-wire and 4-wire Kelvin connections.

32. A circuit in accordance with claim 16, wherein the circuit modifies the bias or excitation of the sensor by modifying one or more effective impedances used to bias or excite the sensor.

33. A circuit in accordance with claim 32, wherein the one or more effective impedances in the circuit are modified by changing the gain of at least one amplifying element used in the circuit to synthesize the effective impedances.

34. A circuit in accordance with claim 32, wherein the one or more effective impedances in the circuit are modified by changing the frequency content of a signal that passes through the effective impedances.

35. A circuit in accordance with claim 32, wherein one or more effective impedances are implemented by digital means.

36. A circuit in accordance with claim 1, wherein the approximation error is substantially minimised.

37. A circuit in accordance with claim 1, wherein the maximum absolute magnitude of the approximation error is substantially minimised.

38. A circuit in accordance with claim 16 wherein all of the at least 2*n+1 points of equality occur within a defined range of values of a physical property measured by the sensor.

39. A first circuit in accordance with claim 1, wherein the first circuit is capable of compensating the output of a second circuit for the effect of a physical property influencing the output of the second circuit.

40. A first circuit in accordance with claim 39, wherein the physical property is temperature.

41. A first circuit in accordance with claim 39, wherein the second circuit is one of an oscillator circuit and a voltage reference circuit.

42. (canceled)

43. A circuit capable of connection to m sensors, m being an integer not less than 1, the circuit, when connected to the m sensors, being arranged such that one of a transfer function or output function of the circuit approximates a desired mathematical relationship between a physical property measured by the sensor and the output of the circuit, the one of the transfer function or output function equaling the desired relationship at least 2*n+1 points, n being an integer both greater than 1 and not less than m, wherein the arrangement of the circuit provides at least 2*n+1 degrees of freedom in determining the points of equality.

44. A circuit in accordance with claim 43, wherein at least one of non-sensor parameters of the circuit, an output scale factor and an output offset value are selectable to provide the at least 2*n+1 degrees of freedom in determining the points of equality.

45. A circuit in accordance with claim 43, wherein for each of the signals used by the circuit to form the output value, the circuit establishes one of a bias and an excitation condition at the sensor, the points of equality being determined by the set of bias and excitation conditions established at the sensor.

46. A circuit in accordance with claim 43, wherein the transfer function or output function is a rational function in terms of circuit parameters.

47. A circuit in accordance with claim 43, wherein the output is one of a function of a weighted sum of signal measurements measurable at one or more given locations in the circuit and a weighted sum of the square of signal measurements measurable at one or more given locations in the circuit.

48. (canceled)

49. A circuit in accordance with claim 47, wherein the measurements are one of signal amplitudes and signal phases.

50. (canceled)

51. A circuit in accordance with claim 43, wherein the desired mathematical relationship between the output and the sensed property is a linear function.

52. A circuit in accordance with claim 43, wherein all of the at least 2*n+1 points of equality occur within a defined range of values of a physical property measured by the m sensors.

53. A circuit in accordance with claim 1, wherein the output takes the form of one of a signal frequency, signal period, signal duration and signal duty cycle.

54. A circuit in accordance with claim 1, wherein the output signal is one of a digital signal and a sequence of digital values.

55. An integrated circuit incorporating a circuit in accordance with claim 1.

56. A plurality of interrelated electrical components, wherein the interrelated components form a circuit in accordance with claim 1, when energized by a source of power.

57. An integrated circuit comprising the plurality of interrelated components in accordance with claim 56.
